(19) United States
(12) Patent Application Publication
(10) Pub. No.: US 2025/0035830 A1
(43) Pub. Date: Jan. 30, 2025

(54) FORMING METHOD, OPTICAL FILM, CHOLESTERIC LIQUID CRYSTAL LAYER, OPTICAL LAMINATE, AND PRODUCTION METHOD OF CURVED-SHAPED OPTICALLY FUNCTIONAL LAYER

(71) Applicant: FUJIFILM Corporation, Tokyo (JP)

(72) Inventors: Ryuji SANETO, Minamiashigara-shi (JP); Naoyoshi YAMADA, Minamiashigara-shi (JP); Yohei HAMACHI, Minamiashigara-shi (JP); Takehiro KASAHARA, Minamiashigara-shi (JP)

(73) Assignee: FUJIFILM Corporation, Tokyo (JP)

(21) Appl. No.: 18/890,877

(22) Filed: Sep. 20, 2024

Related U.S. Application Data
(63) Continuation of application No. PCT/JP2023/014900, filed on Apr. 12, 2023.

(30) Foreign Application Priority Data
Apr. 14, 2022 (JP) 2022-066739
Apr. 22, 2022 (JP) 2022-070725

(51) Int. Cl. G02B 5/30; B29D 11/00; B29K 105/00

(52) U.S. Cl. CPC G02B 5/3016; B29D 11/00644; B29D 11/0073; B29K 2105/0079

(57) ABSTRACT

An object of the present invention is to provide a forming method capable of obtaining an optical film in which occurrence of ghost can be suppressed in a case of being used in, for example, a virtual reality display apparatus; an optical film; a cholesteric liquid crystal layer; an optical laminate; and a production method of a curved-shaped optically functional layer. The object is achieved by a forming method including a heating step of heating an optical film, a forming step of pressing the optical film against a mold to deform the optical film, and a cutting step of cutting the optical film, in which the heating step is a step of heating the optical film by irradiating the optical film with infrared rays, and an irradiation amount of the infrared rays has a distribution in a plane of the optical film.

### CROSS-REFERENCE TO RELATED APPLICATIONS

This application is a Continuation of PCT International Application No. PCT/JP2023/014900 filed on Apr. 12, 2023, which claims priority under 35 U.S.C. § 119(a) to Japanese Patent Application No. 2022-066739 filed on Apr. 14, 2022 and Japanese Patent Application No. 2022-070725 filed on Apr. 22, 2022. Each of the above applications are hereby expressly incorporated by reference, in their entirety, into the present application.

### BACKGROUND OF THE INVENTION

### 1. Field of the Invention

The present invention relates to a forming method, an optical film, a cholesteric liquid crystal layer, an optical laminate, and a production method of a curved-shaped optically functional layer.

### 2. Description of the Related Art

A virtual reality display apparatus is a display device which can obtain a realistic effect as if entering a virtual world by wearing a dedicated headset on a head and visually recognizing a video displayed through a composite lens.

The virtual reality display apparatus generally includes an image display panel and a Fresnel lens, but a distance from the image display panel to the Fresnel lens is large, and thus a headset is thick and has poor wearability, which are problems.

Therefore, as disclosed in JP2020-519964A and U.S. Ser. No. 10/394,040B, a lens configuration of a composite lens called a pancake lens (reciprocal optical system or folded optical system) has been proposed, the lens configuration including an image display panel, a reflective type polarizer, and a half mirror, in which the entire thickness of a headset is reduced by reciprocating rays emitted from the image display panel between the reflective type polarizer and the half mirror.

The reflective polarizer herein is a polarizer having a function of reflecting one polarized light in incidence ray and transmitting the other polarized light. Reflected light and transmitted light due to the reflective polarizer are in a polarization state of being orthogonal to each other.

Here, the polarization state of being orthogonal to each other denotes a polarization state in which both lights are positioned at antipodal points on the Poincare sphere, and for example, linearly polarized lights orthogonal to each other or dextrorotatory circularly polarized light (clockwise circularly polarized light) and levorotatory circularly polarized light (counterclockwise circularly polarized light) correspond to the polarization state.

As the reflective type linear polarizer in which the transmitted light and the reflected light are linearly polarized, for example, a film in which a dielectric multi-layer film is stretched and a wire grid polarizer have been known. In addition, as a reflective type circular polarizer in which the transmitted light and the reflected light are converted into circularly polarized light, for example, a film having a light reflecting layer (cholesteric liquid crystal layer) obtained by immobilizing a cholesteric liquid crystalline phase has been known.

JP2020-519964A discloses a composite lens having a configuration of a pancake lens, including an image display panel, a reflective type linear polarizer, and a half mirror in this order, in which the reflective type linear polarizer is used as the reflective type polarizer. In a case of including the image display panel, the reflective type polarizer, and the half mirror in this order, it is necessary for the reflective type polarizer to have an action of a concave mirror with respect to a ray incident from the half mirror side. In order to impart the action of the concave mirror to the reflective type linear polarizer, a configuration in which the reflective type linear polarizer is formed into a curved shape is proposed.

In addition, U.S. Ser. No. 10/394,040B discloses a composite lens having a configuration of a pancake lens, including an image display panel, a half mirror, and a reflective type linear polarizer in this order, in which the reflective type linear polarizer is used as the reflective type polarizer. U.S. Ser. No. 10/394,040B proposes a configuration in which both the half mirror and the reflective type polarizer are curved to improve field curvature. In this case, it is necessary for the reflective type polarizer to have an action of a convex mirror.

In addition, as described above, the cholesteric liquid crystal layer which is a reflective type circular polarizer can also be used as the reflective type polarizer.

As is well known, the cholesteric liquid crystal layer has a helical structure in which the liquid crystal compound is helically turned and laminated. In the helical structure, a configuration in which the liquid crystal compound is helically rotated once (rotated by 360°) and laminated is set as one pitch, and the helically turned liquid crystal compounds are laminated a plurality of pitches.

The cholesteric liquid crystal layer selectively reflects specific circularly light in a predetermined wavelength range, and transmits other light. Therefore, such a cholesteric liquid crystal layer can be suitably used as a reflective type circular polarizer in the pancake lens.

Basically, the cholesteric liquid crystal layer has no phase difference. That is, the cholesteric liquid crystal layer has substantially no in-plane retardation.

However, according to the studies of the present inventors, it has been found that, in a case where the reflective polarizer using the cholesteric liquid crystal layer is formed into a curved shape as disclosed in JP2020-519964A and U.S. Ser. No. 10/394,040B, a helical axis is partially changed in the plane, and as a result, a phase difference occurs.

In the cholesteric liquid crystal layer having a phase difference, incidence ray cannot be properly reflected and transmitted. Therefore, in a case where such a cholesteric liquid crystal layer is used in a pancake lens constituting a virtual reality display apparatus, light is transmitted unnecessarily, increasing so-called ghost (light leakage), which results in observation of unnecessary images.

The present invention has been made in view of the above-described problems, and an object of the present invention is to provide a forming method capable of obtaining an optical film in which occurrence of ghost can be suppressed in a case of being used in, for example, a virtual reality display apparatus; an optical film; a cholesteric liquid crystal layer; an optical laminate; and a production method of a curved-shaped optically functional layer.

### SUMMARY OF THE INVENTION

As a result of intensive studies, the present inventors have found that, in a case where a cholesteric liquid crystal layer and a low retardation film (zero retardation film) are formed into an optical film having a curved shape, partial phase difference due to forming can be suppressed by performing the forming so as to selectively stretch a center.

In addition, as a result of intensive studies, the present inventors have found that, by imparting an in-plane phase difference in a predetermined pattern to the cholesteric liquid crystal layer in advance, it is possible to cancel out the occurrence of partial phase difference in a case of being formed into a curved shape.

In other words, it has been found that the above-described objects can be achieved by employing the following configurations.

A forming method of an optical film, comprising:
a heating step of heating an optical film;
a forming step of pressing the optical film against a mold to deform the optical film along a shape of the mold; and
a cutting step of cutting the optical film,
in which the heating step is a step of heating the optical film by irradiating the optical film with infrared rays, and
an irradiation amount of the infrared rays has a distribution in a plane of the optical film.

[2] The forming method according to [1],
in which the mold is a concave surface of a non-developable surface in which a Gaussian curvature is positive, and
in a case where an in-plane position of the optical film is projected onto the mold from a normal direction of a main surface of the optical film, an amount of infrared irradiation to the optical film at a vertex of the concave surface is larger than an amount of infrared irradiation to the optical film at an end part of the concave surface.

[3] A forming method of an optical film, comprising:
a heating step of heating an optical film;
a forming step of pressing the optical film against a mold to deform the optical film along a shape of the mold; and
a cutting step of cutting the optical film,
in which a surface of the mold, which comes into contact with the optical film, is a concave surface of a non-developable surface in which a Gaussian curvature is positive and an outer peripheral shape is an ellipse,
a cutting shape in the cutting step is an ellipse, and
a major axis of an elliptical outer peripheral shape of the optical film before the cutting is larger than 50% and smaller than 95% with respect to a major axis of the elliptical outer peripheral shape of the mold.

[4] A forming method of an optical film, comprising:
a heating step of heating an optical film;
a forming step of pressing the optical film against a mold to deform the optical film along a shape of the mold; and
a cutting step of cutting the optical film,
in which, in the heating step, a region of the optical film, which comes into contact with the mold, is heated at a temperature higher than a glass transition temperature Tg of the optical film, and
in the forming step, immediately after the optical film comes into contact with the mold, the pressing of the optical film against the mold is controlled such that the region of the optical film, which comes into contact with the mold, has a temperature lower than the glass transition temperature Tg.

[5] A forming method of an optical film, comprising:
a heating step of heating a mold;
a forming step of pressing the heated mold against an optical film to deform the optical film along a shape of the mold; and
a cutting step of cutting the optical film,
in which the mold is a convex surface of a non-developable surface in which a Gaussian curvature is positive, and
in the forming step, a vertex of the convex surface of the mold is pressed against a center of the optical film.

[6] The forming method according to [5],
in which a cutting shape of the optical film in the cutting step is an ellipse, and
in the forming step, the optical film is pressed against the mold while constraining a position on an elliptical line which is to be the cutting shape.

[7] A cholesteric liquid crystal layer,
in which the cholesteric liquid crystal layer has a phase difference region in which a phase difference increases from a center toward outside, and
in the phase difference region, a direction of a slow axis at one point in the phase difference region and a direction from the center to the one point are orthogonal to each other.

[8] An optical laminate comprising:
a plurality of the cholesteric liquid crystal layers according to [7].

[9] The optical laminate according to [8],
in which the cholesteric liquid crystal layer formed of a rod-like liquid crystal compound and the cholesteric liquid crystal layer formed of a disk-like liquid crystal compound are alternately laminated.

[10] A production method of a curved-shaped optically functional layer, comprising:
a cholesteric liquid crystal layer-producing step of producing the cholesteric liquid crystal layer according to [7]; and
a forming step of forming the cholesteric liquid crystal layer into a curved shape to cancel out a phase difference of the cholesteric liquid crystal layer.

[11] The production method of a curved-shaped optically functional layer according to [10],
in which, in the forming step, the cholesteric liquid crystal layer is installed on a forming die having a concave surface-forming surface such that a bottom portion of the concave surface-forming surface and a center of the cholesteric liquid crystal layer coincide with each other, and the cholesteric liquid crystal layer is deformed along the concave surface-forming surface.

[12] An optical film having a non-developable surface in which a Gaussian curvature is positive,
in which the optical film is a cholesteric liquid crystal layer, and
in a case where a wavelength obtained by subtracting 20 nm from a half-value wavelength on a side shorter than a selective reflection center wavelength in the cholesteric liquid crystal layer is defined as an evaluation wavelength of an in-plane retardation, an in-plane retardation A at the evaluation wavelength in a center of the cholesteric liquid crystal layer is less than 2% of the evaluation wavelength, and an in-plane retardation B at the evaluation wavelength in an outer edge portion of the cholesteric liquid crystal layer is less than 2% of the evaluation wavelength.

[13] An optical film having a non-developable surface in which a Gaussian curvature is positive,
in which the optical film has no selective reflection characteristic,
an in-plane retardation A in a center of the optical film at a wavelength of 550 nm is less than 11 nm, and
an in-plane retardation B in an outer edge portion of the optical film at a wavelength of 550 nm is less than 11 nm.

[14] The optical film according to [12] or [13], in which an outer peripheral shape is an ellipse.

According to the present invention, it is possible to provide a forming method capable of obtaining an optical film in which occurrence of ghost can be suppressed in a case of being used in, for example, a virtual reality display apparatus; an optical film; a cholesteric liquid crystal layer; an optical laminate; and a production method of a curved-shaped optically functional layer.

### BRIEF DESCRIPTION OF THE DRAWINGS

FIG. 1 is an example of a virtual reality display apparatus in which an optical film according to a first embodiment of the present invention can be used, and shows an example of ray of a main image.

FIG. 2 is an example of the virtual reality display apparatus in which the optical film according to the first embodiment of the present invention can be used, and shows an example of ray of ghost.

FIG. 3 is a schematic view showing an example of an optical laminate including the optical film according to the first embodiment of the present invention.

FIG. 4 is a schematic view showing an example of the optical film according to the first embodiment of the present invention.

FIG. 5 is a schematic view of an exposure mask.

FIG. 6 is a schematic view for describing action and effect of the first embodiment of the present invention.

FIG. 7 is a conceptual view showing an example of a cholesteric liquid crystal layer.

FIG. 8 is a conceptual view showing an example of a part of a liquid crystal compound of a cholesteric liquid crystal layer according to a second embodiment of the present invention, as viewed from a helical axis direction.

FIG. 9 is a view of a part of a plurality of liquid crystal compounds twistedly aligned along a helical axis in the cholesteric liquid crystal layer according to the second embodiment of the present invention, as viewed from the helical axis direction.

FIG. 10 is a conceptual view showing an existence probability of the liquid crystal compound in the cholesteric liquid crystal layer according to the second embodiment of the present invention, as viewed from the helical axis direction.

FIG. 11 is a schematic view of an exposure mask used in producing the cholesteric liquid crystal layer according to the second embodiment of the present invention.

FIG. 12 is a conceptual view showing a slow axis for each region of the cholesteric liquid crystal layer according to the second embodiment of the present invention.

### DESCRIPTION OF THE PREFERRED EMBODIMENTS

Hereinafter, the present invention will be described in detail.

The description of configuration requirements described below may be made based on typical embodiments of the present invention, but the present invention is not limited to such embodiments.

Any numerical range expressed using “to” in the present specification refers to a range including the numerical values before and after the “to” as a lower limit value and an upper limit value, respectively.

In addition, in the present specification, a term “parallel” or “orthogonal” does not indicate parallel or orthogonal in a strict sense, but indicates a range of ±5° from parallel or orthogonal.

In addition, in the present specification, a liquid crystal composition and a liquid crystal compound include those which no longer exhibit liquid crystal properties due to curing or the like as a concept.

Hereinafter, the present invention will be described in detail with reference to the accompanying drawings. The description of the configuration requirements described below may be made based on representative embodiments and specific examples, but the present invention is not limited to such embodiments. Any numerical range expressed using “to” in the present specification refers to a range including the numerical values before and after the “to” as a lower limit value and an upper limit value, respectively.

In the present specification, the term “orthogonal” does not denote 90° in a strict sense, but denotes 90°±10°, preferably 90°±5°. In addition, a term “parallel” does not denote 0° in a strict sense, but denotes 0°±10°, preferably 0°±5°. Furthermore, a term “45°” does not denote 45° in a strict sense, but denotes 45°±10°, preferably 45°±5° Here, in the expression related to polarized light, “state of polarized light orthogonal to each other” denotes a state of polarized light both positioned at antipodal points on the Poincare sphere, and for example, linearly polarized light orthogonal to each other, and clockwise circularly polarized light (dextrorotatory circularly polarized light) and counterclockwise circularly polarized light (levorotatory circularly polarized light) are in the corresponding state as described above.

In the present specification, a term “absorption axis” denotes a polarization direction in which absorbance is maximized in a plane in a case where linearly polarized light is incident. In addition, a term “reflection axis” denotes a polarization direction in which reflectivity is maximized in a plane in a case where linearly polarized light is incident. In addition, a term “transmission axis” denotes a direction orthogonal to the absorption axis or the reflection axis in a plane. Furthermore, a term “slow axis” denotes a direction in which refractive index is maximized in a plane.

In the present specification, a phase difference denotes an in-plane retardation unless otherwise specified, and is referred to as Re (λ). Here, Re (λ) represents an in-plane retardation at a wavelength λ, and the wavelength λ is 550 nm unless otherwise specified.

In addition, a retardation at the wavelength λ in a thickness direction is referred to as Rth (λ) in the present specification.

As Re (λ) and Rth (λ), values measured at the wavelength λ with AxoScan OPMF-1 (manufactured by Opto Science, Inc.) can be used. By inputting an average refractive index ((nx+ny+nz)/3) and a film thickness (d (μm)) in AxoScan,
a slow axis direction (°)

$$Re ( λ ) = R 0 ( λ ) , and$$

$$“ Rth ( λ ) = ( ( n x + ny ) / 2 - nz ) \times d ” are calculated .$$

In addition, in the present specification, a liquid crystal composition and a liquid crystal compound include those which no longer exhibit liquid crystal properties due to curing or the like as a concept.

### First Embodiment

### <Optical Film>

The optical film according to the first embodiment of the present invention has a curved shape.

Specifically, the optical film according to the first embodiment of the present invention has a curved shape of a non-developable surface in which a Gaussian curvature is positive. As such a curved shape, various curved shapes having a non-developable surface in which the Gaussian curvature is positive can be used, such as a spherical surface, a parabolic surface, an elliptical surface, an aspherical surface in which curvature changes from the center toward the outer side, and an asymmetric curved surface with respect to the center, for example, a lens having a circular shape, and a curved surface asymmetric with respect to the optical axis in the diameter direction.

In addition, in the optical film according to the first embodiment of the present invention, having such a curved shape, an outer peripheral shape (shape of an outer peripheral end), that is, a planar shape is not limited, and various shapes such as an elliptical shape, a non-elliptical oblong shape, a polygonal shape, and an amorphous shape can be used. Among these, an elliptical shape is preferable. In the present invention, the “elliptical” includes “circular”.

The planar shape refers to a shape in a case where the optical film is viewed from a normal direction of a top (bottom) of the curved surface. For example, in a case where the optical film having a curved shape is a lens, the planar shape is a shape in a case of being viewed from an optical axis direction.

The optical film according to the first embodiment of the present invention consists of a cholesteric liquid crystal layer or a film with low phase difference, so-called zero retardation film.

Specifically, a first aspect of the optical film according to the first embodiment of the present invention is an optical film consisting of a cholesteric liquid crystal layer having the above-described curved shape, in which, in a case where a wavelength obtained by subtracting 20 nm from a half-value wavelength on a side shorter than a selective reflection center wavelength in the cholesteric liquid crystal layer is defined as an evaluation wavelength (measurement wavelength), an in-plane retardation A at the evaluation wavelength in a center is less than 2% of the evaluation wavelength, and an in-plane retardation B at the evaluation wavelength in an outer edge portion is less than 2% of the evaluation wavelength.

In the first aspect of the optical film according to the first embodiment of the present invention, for example, in a case where the half-value wavelength on a side shorter than a selective reflection center wavelength in the cholesteric liquid crystal layer is 430 nm, and light having a wavelength of 410 nm is used as the evaluation wavelength of the in-plane retardation, the in-plane retardation A in the center is less than 8.2 nm, and the in-plane retardation B in the outer edge portion is also less than 8.2 nm.

In a case where the optical film in the first aspect according to the first embodiment of the present invention has a plurality of cholesteric liquid crystal layers, a wavelength obtained by subtracting 20 nm from a half-value wavelength on a side shorter than a selective reflection center wavelength in a cholesteric liquid crystal layer having the shortest selective reflection center wavelength may be regarded as the evaluation wavelength of the in-plane retardation in the optical film.

In addition, a second aspect of the optical film according to the first embodiment of the present invention consists of a film having the above-described curved shape and having no selective reflectivity, in which an in-plane retardation A in a center at a wavelength of 550 nm is less than 11 nm, and an in-plane retardation B in an outer edge portion at the above-described evaluation wavelength is less than 11 nm.

In the optical film according to the first embodiment of the present invention, the center is usually the bottommost portion (the deepest portion) in a case where the curved shape is concave, and is usually the topmost portion in a case where the curved shape is convex. In a case where the optical film acts as a lens, the center is usually the optical axis.

In addition, the outer edge portion (end part) refers to a point located 5 mm inside from the outermost edge of the lens.

That is, the optical film according to the first embodiment of the present invention consists of a cholesteric liquid crystal layer having a curved shape or a film having a curved shape and no selective reflectivity, in which the phase difference, that is, the in-plane retardation is small over the entire surface.

With the optical film according to the first embodiment of the present invention, for example, in a case of used as a reflective type polarizer in a pancake lens constituting a virtual reality display apparatus, occurrence of ghost can be suppressed.

The optical film according to the first embodiment of the present invention may be used as an optical laminate formed by being combined with various optical elements such as a support (transparent film), a retardation film (retardation plate), a polarizer (polarizing plate), a reflective type polarizer, and an antireflection film.

The optical laminate will be described later.

### [Film Having No Selective Reflectivity]

In the optical film according to the first embodiment of the present invention, as the film having no selective reflectivity, various films such as a zero retardation film (low retardation film), which is a film having a small phase difference and is formed of a polymer resin having low birefringence, can be used.

As the polymer resin having low birefringence, an organic material having a low birefringence index, that has been used in a light disk substrate, a pickup lens, a lens of a camera, a lens of a microscope, a lens of a video camera, a substrate for a liquid crystal display, a prism, an optical interconnection component, an optical fiber, a light guide plate for liquid crystal display, a laser beam printer, a lens for a projector and a facsimile, a Fresnel lens, a contact lens, a polarizing plate protective film, and a micro lens array, which causes birefringence to interfere with image formation and to cause signal noise, can be used.

Examples of such a film include acrylic resins (for example, acrylic acid esters such as polymethyl (meth)acrylate), polycarbonate, cyclic polyolefins such as cyclopentadiene-based polyolefin and norbornene-based polyolefin, polyolefins such as polypropylene, aromatic vinyl polymers such as polystyrene, polyarylate, and cellulose acylate.

A thickness of these films is not limited, and an appropriate thickness may be set according to the forming material, the application, and the like.

### [Cholesteric Liquid Crystal Layer]

As described above, the cholesteric liquid crystal layer is formed by immobilizing a cholesteric liquid crystalline phase, and has a helical structure in which the liquid crystal compound is helically turned and laminated. In the helical structure, a configuration in which the liquid crystal compound is helically rotated once (rotated by 360°) and laminated is set as one pitch, and the helically turned liquid crystal compounds are laminated a plurality of pitches.

In addition, as is well known, the cholesteric liquid crystal layer has selective reflectivity. Specifically, the cholesteric liquid crystal layer selectively reflects light in a predetermined wavelength range, and transmits light in other wavelength ranges. In addition, the cholesteric liquid crystal layer selectively reflects dextrorotatory circularly polarized light and transmits levorotatory circularly polarized light, or selectively reflects levorotatory circularly polarized light and transmits dextrorotatory circularly polarized light.

That is, the cholesteric liquid crystal layer selectively reflects dextrorotatory circularly polarized light or levorotatory circularly polarized light in a predetermined wavelength range, and transmits other light. In other words, the cholesteric liquid crystal layer separates incidence ray into dextrorotatory circularly polarized light and levorotatory circularly polarized light in a specific wavelength range, specularly reflecting one type of the circularly polarized light and transmitting the other.

A central wavelength of selective reflection (selective reflection center wavelength λ) of the cholesteric liquid crystalline phase depends on a length of one helical pitch P (helical pitch P) in the cholesteric liquid crystalline phase, and satisfies a relationship of λ=n×P with an average refractive index n of the cholesteric liquid crystalline phase. Therefore, by adjusting the helical pitch, the selective reflection center wavelength, that is, the selective reflection wavelength range can be adjusted. The selective reflection center wavelength of the cholesteric liquid crystalline phase increases as the helical pitch P increases.

In addition, a half-width Δλ (nm) of a wavelength range where selective reflection is exhibited (circular polarization reflection wavelength range) depends on Δn of the cholesteric liquid crystalline phase and the helical pitch P, and complies with a relationship of Δλ=Δn×P. Therefore, the width of the selective reflection wavelength range can be controlled by adjusting Δn. Δn can be adjusted by the type of liquid crystal compound forming a cholesteric liquid crystal layer and mixing ratio thereof, and the temperature during immobilizing the alignment.

In the present invention, various known cholesteric liquid crystal layers can be used.

As the cholesteric liquid crystal layer, for example, a cholesteric liquid crystal layer obtained by immobilizing a cholesteric liquid crystalline phase can be used, as described in JP2020-060627A. The cholesteric liquid crystal layer obtained by immobilizing a cholesteric liquid crystalline phase is preferable due to a thin film and its high degree of polarization of transmitted light. From the viewpoint that a decrease in degree of polarization and a distortion of a polarization axis are suppressed in a case of being stretched or formed into a three-dimensional shape, the cholesteric liquid crystal layer is preferably used as an optical film for curved surface forming. In addition, a decrease in degree of polarization due to the distortion of the polarization axis is unlikely to occur.

The optical film according to the first embodiment of the present invention may be formed by laminating a plurality of cholesteric liquid crystal layers.

As an example, it is preferable that the optical film according to the first embodiment of the present invention is a laminate of four cholesteric liquid crystal layers, including a blue light reflecting layer in which a reflectivity at a wavelength of at least 460 nm is 40% or more, a green light reflecting layer in which a reflectivity at a wavelength of 550 nm is 40% or more, a yellow light reflecting layer in which a reflectivity at a wavelength of 600 nm is 40% or more, and a red light reflecting layer in which a reflectivity at a wavelength of 650 nm is 40% or more. With such a configuration, high reflection characteristics can be exhibited over a wide wavelength range in the visible region, which is preferable. The above-described reflectivity is a reflectivity in a case where non-polarized light is incident on the cholesteric liquid crystal layer at each wavelength.

In addition, the blue light reflecting layer, the green light reflecting layer, the yellow light reflecting layer, and the red light reflecting layer, which are the cholesteric liquid crystal layer formed by immobilizing a cholesteric liquid crystalline phase, may have a pitch gradient structure in which the helical pitch of the cholesteric liquid crystalline phase continuously changes in the thickness direction. With regard to the pitch gradient structure, for example, the green light reflecting layer and the yellow light reflecting layer can be continuously produced with reference to JP2020-060627A and the like.

In the optical film according to the first embodiment of the present invention, it is preferable that the cholesteric liquid crystal layer is formed by laminating the blue light reflecting layer, the green light reflecting layer, the yellow light reflecting layer, and the red light reflecting layer in this order.

In addition, the cholesteric liquid crystal layer is usually combined with a retardation layer. In this case, it is preferable that the blue light reflecting layer is installed on a surface opposite to the retardation layer which converts circularly polarized light into linearly polarized light, that is, on a light source side. In such an arrangement, a ray passes through the blue light reflecting layer, the green light reflecting layer, the yellow light reflecting layer, and the red light reflecting layer in this order.

The present inventors have considered that the cause of the suppression of the occurrence of the ghost by disposing the blue light reflecting layer on the light source side is that the influence of Rth can be suppressed. The estimation mechanism thereof will be described below. In the cholesteric liquid crystal layer used as the light reflecting layer, a film thickness required to obtain sufficient reflectivity (for example, 40% or more) increases on a long wavelength side. Therefore, in a case where there is a light reflecting layer which reflects light having a long wavelength on the light source side, a film thickness thereof is increased, and as a result, Rth of the light passing through the light reflecting layer is increased. For such a reason, it is considered to be more preferable that a reflection band of the light reflecting layer disposed on the light source side is on the short wavelength side.

It is also preferable that the optical film according to the first embodiment of the present invention includes a cholesteric liquid crystal layer containing a rod-like liquid crystal compound and a cholesteric liquid crystal layer containing a disk-like liquid crystal compound.

In such a configuration, since the cholesteric liquid crystalline phase containing a rod-like liquid crystal compound has a positive Rth and the cholesteric liquid crystalline phase containing a disk-like liquid crystal compound has a negative Rth, the Rth of each other is offset, and thus the occurrence of the ghost can be suppressed even for the light incident from the oblique direction, which is preferable.

According to the studies by the present inventors, in this case, it is preferable to include a blue light reflecting layer consisting of a cholesteric liquid crystal layer containing a disk-like liquid crystal compound, a green light reflecting layer consisting of a cholesteric liquid crystal layer containing a rod-like liquid crystal compound, a yellow light reflecting layer consisting of a cholesteric liquid crystal layer containing a disk-like liquid crystal compound, and a red light reflecting layer consisting of a cholesteric liquid crystal layer containing a rod-like liquid crystal compound in this order. The order of the reflecting layers and the type of liquid crystal are merely examples, and the present invention is not limited to these configurations.

The state in which the Rth is offset is represented by an expression as follows.

In an optical laminated film including n light reflecting layers, in a case where the light reflecting layers are named L1, L2, L3, . . . , and Ln from a light source side, the sum of Rth's of each layer from the light reflecting layer L1 to the light reflecting layer Li is denoted by SRthi. Specifically, the expression is as follows.

$$\begin{matrix}SRth 1 = Rth 1 \\ SRth 2 = Rth 1 + Rth 2 \\ … \\ SRthi = Rth 1 + Rth 2 … + Rthi \\ … \\ SRthn = Rth 1 + Rth 2 … + Rthi … + Rthn\end{matrix}$$

Absolute values of all of SRthi (SRth1 to SRthn) are preferably 0.3 m or less, more preferably 0.2 m or less, and most preferably 0.1 m or less. The Rthi of each layer in the above-described expression is determined by the expression of [0023] for calculating Rth described above.

A thickness of the cholesteric liquid crystal layer is not particularly limited, but from the viewpoint of thinning, it is preferably 30 m or less and more preferably 15 m or less.

In addition, in a case where the cholesteric liquid crystal layer is stretched or formed, the reflection wavelength range of the cholesteric liquid crystal layer may shift, and thus it is preferable that the reflection wavelength range is selected in advance, considering a potential shift in wavelength.

For example, in a case of using the cholesteric liquid crystal layer, the film may extend during stretching or forming, which can reduce the helical pitch of the cholesteric liquid crystal layer. Therefore, it is preferable to set the helical pitch of the cholesteric liquid crystalline phase to be large in advance. In addition, it is also preferable that the cholesteric liquid crystal layer includes an infrared light reflecting layer having a reflectivity of 40% or more at a wavelength of 800 nm, in consideration of the short wavelength shift of the reflection wavelength range due to the stretching or the forming.

Furthermore, in a case where a stretching ratio during the stretching or the forming is not uniform in a plane, an appropriate reflection wavelength range may be selected at each location in the plane according to the wavelength shift caused by the stretching. That is, regions with different reflection wavelength ranges may be present in the plane. In addition, it is also preferable that the reflection wavelength range is set wider than the required wavelength range in advance in consideration that the stretching ratios at the respective locations in the plane are different from each other.

### (Method of Manufacturing Cholesteric Liquid Crystal Layer)

The cholesteric liquid crystal layer can be formed according to the following procedure of: applying a liquid crystal composition, which is obtained by dissolving a liquid crystal compound, a chiral agent, a polymerization initiator, a surfactant added as necessary, and the like in a solvent, onto a support or an underlayer (alignment film) formed on the support; drying the liquid crystal composition to obtain a coating film; aligning the liquid crystal compound in the coating film; and irradiating the coating film with actinic ray to cure the liquid crystal composition.

As a result, a cholesteric liquid crystal layer having a cholesteric liquid crystal structure in which cholesteric regularity (cholesteric liquid crystalline phase) is immobilized can be formed.

### [Applying Method]

Examples of the applying method include known methods such as a roll coating method, a gravure printing method, a spin coating method, a wire bar coating method, an extrusion coating method, a direct gravure coating method, a reverse gravure coating method, a die-coating method, a spraying method, and an ink jet method.

### [Method of Imparting In-Plane Distribution to Helical Pitch]

The cholesteric liquid crystal layer constituting the optical film according to the first embodiment of the present invention may have an in-plane distribution in the helical pitch. In a case where the cholesteric liquid crystal layer has an in-plane distribution in the helical pitch, even in a case where the film thickness changes due to forming into a curved shape described later, it is possible to suppress variation in the selective reflection wavelength range in the plane.

In a method of imparting the in-plane distribution to the helical pitch of the cholesteric liquid crystal layer, for example, there is a method of using a chiral agent in which HTP is changed by photoisomerization.

The details thereof will be described.

By performing light irradiation corresponding to photoisomerization on the cholesteric liquid crystal layer which is obtained by applying the liquid crystal composition containing a chiral agent, in which the HTP changes due to the photoisomerization, and aligning the liquid crystal compound by heating treatment as necessary, the HTP of the chiral agent is changed, and as a result, the helical pitch of the cholesteric liquid crystal layer changes, allowing the reflection wavelength to be changed.

By utilizing this property, the aligned cholesteric liquid crystal layer is irradiated with light in a patterned manner using an exposure mask or the like to be photoisomerized, thereby obtaining a pattern in which the reflection wavelength is changed only in the light-irradiated region. After obtaining the pattern, the entire cholesteric liquid crystal layer is exposed to light for curing the liquid crystal composition, and the liquid crystal composition is polymerized, thereby finally obtaining a cholesteric liquid crystal layer (patterned cholesteric liquid crystal layer) having a helical pitch with an in-plane distribution. The patterned cholesteric liquid crystal layer after the curing no longer undergoes photoisomerization and has stable properties.

In order to effectively perform the pattern formation, it is preferable that the light irradiation for the photoisomerization and the light irradiation for the curing can be separated. In other words, in order to effectively perform the pattern formation, it is preferable that, in a case where either the photoisomerization or the curing proceeds, the other does not proceed as much as possible.

Examples of a method for separating the two include separation by oxygen concentration and separation by exposure wavelength.

First, with regard to the oxygen concentration, the photoisomerization is less affected by the oxygen concentration, but the curing is basically less likely to occur as the oxygen concentration is higher, depending on an initiator to be used.

Therefore, the photoisomerization is performed under a condition of a high oxygen concentration, for example, in the atmosphere, and the curing is performed under a condition of a low oxygen concentration, for example, in a nitrogen atmosphere with an oxygen concentration of 300 ppm by volume or less. As a result, the separation between the photoisomerization and the curing is easier.

In addition, with regard to the exposure wavelength, the photoisomerization by a chiral agent is likely to proceed at an absorption wavelength of the chiral agent, and the curing is likely to proceed at an absorption wavelength of the photopolymerization initiator.

Therefore, in a case where the chiral agent and the photopolymerization initiator are selected such that the absorption wavelengths thereof are different from each other, it is possible to separate the photoisomerization and the curing by the exposure wavelength.

One or both of the photoisomerization and the curing may be performed under heating, as necessary. A temperature at the time of heating is preferably 25° C. to 140° C. and more preferably 30° C. to 100° C.

As another method of using the chiral agent in which the HTP is changed by the photoisomerization, there is also a method in which curing is performed in a patterned manner first and then isomerization of an uncured region is performed.

That is, the aligned cholesteric liquid crystalline phase is first irradiated with light for curing in a patterned manner using an exposure mask or the like. Thereafter, the entire surface is irradiated with light for the photoisomerization. In a region where the curing has been performed in advance, the change in pitch due to the photoisomerization cannot occur. Therefore, the change in pitch due to the photoisomerization occurs only in a region where the curing has not been performed in advance, resulting in the change in reflection wavelength.

In this case as well, after obtaining the pattern, the entire cholesteric liquid crystal layer is exposed to light for curing the liquid crystal composition, and the liquid crystal composition is polymerized, thereby finally obtaining the patterned cholesteric liquid crystal layer.

### [Direct Application of Each Layer]

As described above, the optical film according to the first embodiment of the present invention may be formed by laminating a plurality of cholesteric liquid crystal layers.

In this case, it is preferable that adjacent layers are directly formed without a bonding layer between the cholesteric liquid crystal layers. In a case of forming a layer, the bonding layer can be eliminated by directly coating an adjacent layer which has already been formed. In the following description, the cholesteric liquid crystal layer is also referred to as “light reflecting layer”.

Furthermore, in order to reduce the difference in refractive index in all in-plane directions, it is preferable that alignment directions (slow axis directions) of the liquid crystal compound are arranged to continuously change at the interface. For example, in a case where a light reflecting layer containing a rod-like liquid crystal compound is formed on a light reflecting layer containing a disk-like liquid crystal compound, the light reflecting layer containing a rod-like liquid crystal compound can be formed by directly applying a coating liquid containing the rod-like liquid crystal compound, and the rod-like liquid crystal compound can be aligned such that the slow axis direction is continuous at the interface by an alignment regulating force of the disk-like liquid crystal compound in the light reflecting layer containing a disk-like liquid crystal compound.

### [Method of Bonding Each Layer]

As described above, the optical film according to the first embodiment of the present invention may be formed by laminating a plurality of cholesteric liquid crystal layers (light reflecting layers). In this case, each light reflecting layer can be bonded by any bonding method. The bonding can be performed using a pressure sensitive adhesive, an adhesive, or the like.

As the pressure sensitive adhesive, a commercially available pressure sensitive adhesive can be optionally used. Here, from the viewpoint of thinning the optical film and reducing a surface roughness Ra, a thickness of the pressure sensitive adhesive is preferably m or less, more preferably 15 m or less, and still more preferably 6 m or less. In addition, a pressure sensitive adhesive which is unlikely to generate outgas is preferable as the pressure sensitive adhesive. In particular, in a case of performing stretching or forming, a vacuum process or a heating process may be performed, and it is preferable that no outgas is generated even under such conditions.

As the adhesive, a commercially available adhesive or the like can be optionally used. Specific examples of the adhesive include an epoxy resin-based adhesive and an acrylic resin-based adhesive.

Here, from the viewpoint of thinning the optical film and reducing the surface roughness Ra, a thickness of the adhesive is preferably 25 m or less, more preferably 5 m or less, and still more preferably 1 m or less. In addition, from the viewpoint of reducing the thickness of the adhesive layer and coating an adherend with the adhesive such that the thickness thereof is uniform, a viscosity of the adhesive is preferably 300 cP or less and more preferably 100 cP or less.

In addition, in a case where the adherend has surface unevenness, from the viewpoint of reducing the surface roughness Ra of the cholesteric liquid crystal layer, an appropriate viscoelasticity or an appropriate thickness of the pressure sensitive adhesive and the adhesive can also be selected so that the surface unevenness of the layer to be bonded can be embedded. From the viewpoint of embedding the surface unevenness, it is preferable that the pressure sensitive adhesive and the adhesive have a viscosity of 50 cP or more. In addition, it is preferable that the thickness thereof is more than a height of the surface unevenness.

Examples of a method of adjusting the viscosity of the adhesive include a method of using an adhesive containing a solvent. In this case, the viscosity of the adhesive can be adjusted by a proportion of the solvent. In addition, the thickness of the adhesive can be further reduced by drying the solvent after coating the adherend with the adhesive.

In the cholesteric liquid crystal layer, from the viewpoint of reducing the extra reflection and suppressing a decrease in degree of polarization of transmitted light, it is preferable that the pressure sensitive adhesive or adhesive used for adhering each layer has a small difference in refractive index with adjacent layers. Since the liquid crystal layer has birefringence, refractive indices differ between a fast axis direction and a slow axis direction. In a case where an average refractive index nₐᵥₑ of a liquid crystal layer is calculated by adding the refractive indices in the fast axis direction and the slow axis direction and dividing the sum by 2, a difference between a refractive index of the adjacent pressure-sensitive adhesive layer or bonding layer and the nₐᵥₑ is preferably 0.075 or less, more preferably 0.05 or less, and still more preferably 0.025 or less. The refractive index of the pressure sensitive adhesive and the adhesive can be adjusted, for example, by mixing fine particles of titanium oxide, fine particles of zirconia, or the like.

In addition, the cholesteric liquid crystal layer has in-plane refractive index anisotropy, but the difference in refractive index with the adjacent layer is preferably 0.10 or less in all in-plane directions. Therefore, the pressure sensitive adhesive or the adhesive may have in-plane refractive index anisotropy. Regarding this point, the same applies even in a case where an optical laminate using the optical film (cholesteric liquid crystal layer) according to the first embodiment of the present invention includes a retardation layer having in-plane refractive index anisotropy and a linear polarizer.

In addition, in a case where the optical film according to the first embodiment of the present invention is composed of a plurality of cholesteric liquid crystal layers, a refractive index adjusting layer having a difference in refractive index between the fast axis direction and the slow axis direction, which is smaller than that of the cholesteric liquid crystal layer, may be provided between the cholesteric liquid crystal layer and the pressure sensitive adhesive or between the cholesteric liquid crystal layer and the adhesive. In this case, the refractive index adjusting layer has a cholesteric liquid crystal. By including the refractive index adjusting layer, interface reflection can be further suppressed, and the occurrence of ghost can be further reduced. In addition, it is preferable that an average refractive index of the refractive index adjusting layer is smaller than an average refractive index of the cholesteric liquid crystal layer. In addition, a central wavelength of reflected light of the refractive index adjusting layer may be less than 430 nm or more than 670 nm, and is more preferably less than 430 nm.

In addition, a thickness of the bonding layer between the cholesteric liquid crystal layers is preferably 100 nm or less.

In a case where the thickness of the bonding layer is 100 nm or less, light in the visible region is less likely to be affected by the difference in refractive index, and extra reflection can be suppressed. The thickness of the bonding layer is more preferably 50 nm or less and still more preferably 30 nm or less.

Examples of a method of forming the bonding layer having a thickness of 100 nm or less include a method of vapor-depositing a ceramic adhesive such as silicon oxide (SiOx layer) on the bonding surface.

A bonding surface of the bonding member may be subjected to a surface reforming treatment such as plasma treatment, corona treatment, and saponification treatment, before the bonding. In addition, a primer layer may be provided on the bonding surface of the bonding member.

In addition, in a case where there are a plurality of bonding surfaces, the type and thickness of the bonding layer may be adjusted for each bonding surface. Specifically, for example, the bonding layer having a thickness of 100 nm or less can be provided by the procedures (1) to (3) described below.
(1) A layer to laminate is bonded to a temporary support consisting of a glass base material.
(2) An SiOx layer having a thickness of 100 nm or less is formed on both the surface of the layer to laminate and the surface of the layer to be laminated by vapor deposition or the like; the vapor deposition can be carried out by, for example, a vapor deposition device (model number ULEYES, manufactured by ULVAC, Inc.) using SiOx powder as a vapor deposition source; in addition, it is preferable that the surface of the formed SiOx layer is subjected to a plasma treatment.
(3) After the formed SiOx layers are bonded to each other, the temporary support is peeled off; it is preferable that the bonding is carried out, for example, at a temperature of 120° C.

The application, the adhesion, or the bonding of the layers may be carried out by roll-to-roll or single-wafer.

The roll-to-roll method is preferable from the viewpoint of improving productivity, reducing axis misalignment of each layer, and the like.

Meanwhile, the single-wafer method is preferable from the viewpoint that this method is suitable for production of many kinds in small quantities, that a special adhesion method in which the thickness of the bonding layer is 100 nm or less can be selected, and the like.

In addition, examples of the method of coating the adherend with the adhesive include known methods such as a roll coating method, a gravure printing method, a spin coating method, a wire bar coating method, an extrusion coating method, a direct gravure coating method, a reverse gravure coating method, a die-coating method, a spraying method, and an ink jet method.

As described above, the cholesteric liquid crystal layer which is the optical film according to the first embodiment of the present invention can also be used as an optical laminate by being laminated with other layers. These layers may include a support, an alignment layer, and the like.

Here, the support and the alignment layer may be a temporary support which is peeled off and removed in a case of manufacturing the optical laminate. It is preferable that a temporary support is used from the viewpoint that the thickness of the optical laminate can be reduced by transferring the cholesteric liquid crystal layer to another laminate and peeling and removing the temporary support and the adverse effect of the phase difference of the temporary support on the degree of polarization of transmitted light can be eliminated.

The type of the support is not particularly limited, but it is preferable that the support is transparent, and examples thereof include films of cellulose acylate, polycarbonate, polysulfone, polyethersulfone, polyacrylate and polymethacrylate, cyclic polyolefin, polyolefin, polyamide, polystyrene, polyester, and the like. Among these, a film such as cellulose acylate, cyclic polyolefin, polyacrylate, and polymethacrylate is preferable. In addition, as these films, commercially available products may be used. Examples of the commercially available products include “TD80U” and “Z-TAC” manufactured by FUJIFILM Corporation, as the cellulose acetate film.

In a case where the support is a temporary support, a support having high tear strength is preferable from the viewpoint of preventing breakage during peeling. In this regard, a polycarbonate-based film or a polyester-based film is preferable.

In addition, from the viewpoint of suppressing the adverse effect on the degree of polarization of transmitted light, it is preferable that the support has a small phase difference. Specifically, it is preferable that Re (in-plane retardation) of the support is 10 nm or less, and it is preferable that the absolute value of Rth (thickness direction retardation) of the support is 50 nm or less. Even in a case where the support is used as the above-described temporary support, it is preferable that the temporary support has a small phase difference from the viewpoint of performing quality inspection of the cholesteric liquid crystal layer or other laminates in a step of manufacturing the optical laminate.

In addition, various sensors using near-infrared light as a light source, such as eye tracking, facial expression recognition, and iris authentication, may be incorporated into an optical system of a virtual reality display apparatus, an electronic finder, or the like. In this case, in order to minimize influence on the sensor, it is preferable that the cholesteric liquid crystal layer is transparent to near-infrared light.

### [Optical Laminate]

As described above, the optical film (cholesteric liquid crystal layer) according to the first embodiment of the present invention may be used as an optical laminate laminated with other film-like optical elements.

Here, as the optical laminate, a configuration in which the cholesteric liquid crystal layer, a retardation layer which converts circularly polarized light into linearly polarized light, and a linear polarizer are provided in this order is preferably exemplified.

The optical film according to the first embodiment of the present invention and the optical laminate including the optical film (cholesteric liquid crystal layer) according to the first embodiment of the present invention may be used as a composite lens in combination with a lens. Suitable usage examples of the composite lens include a virtual reality display apparatus.

Hereinafter, the function of the optical laminate including the optical film (cholesteric liquid crystal layer) according to the first embodiment of the present invention will be described in detail by explaining the function of the virtual reality display apparatus.

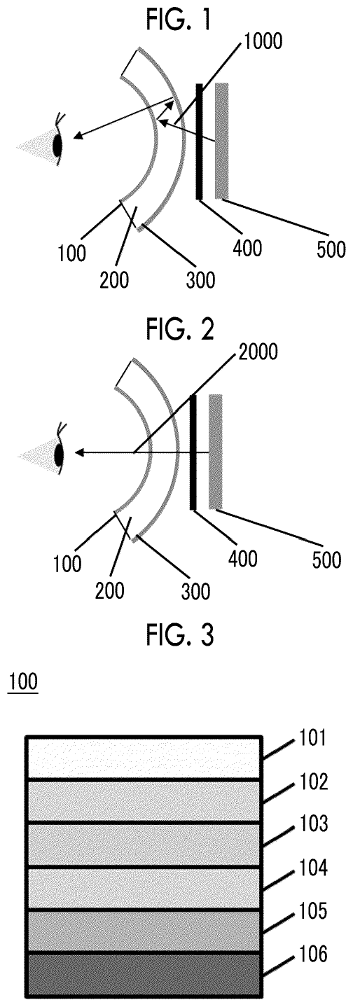

FIG. 1 is a view conceptually showing a virtual reality display apparatus using the optical laminate.

A virtual reality display apparatus shown in FIG. 1 includes an image display panel 500, a circularly polarizing plate 400, a half mirror 300, a lens 200, and an optical laminate 100. As described above, the optical laminate 100 includes the cholesteric liquid crystal layer, the retardation layer, and the linear polarizer in this order.

In the virtual reality display apparatus shown in FIG. 1, a ray 1000 (display image) emitted from the image display panel 500 is transmitted through the circularly polarizing plate 400 to be circularly polarized light, and half of the ray 1000 is transmitted through the half mirror 300.

The ray 1000 transmitted through the half mirror 300 is then transmitted through the lens 200, and incident on the optical laminate 100 from a side of the cholesteric liquid crystal layer, whereby the dextrorotatory circularly polarized light or the levorotatory circularly polarized light is reflected.

The circularly polarized light reflected by the cholesteric liquid crystal layer is transmitted through the lens 200 again, reflected by the half mirror 300 again, transmitted through the lens 200 once more before, and incident on the optical laminate 100. Here, a circularly polarized state of the ray 1000 does not change in a case of being reflected by the optical laminate (cholesteric liquid crystal layer), but changes to circularly polarized light orthogonal to the initial circularly polarized light in a case of being first incident on the optical laminate 100 and then reflected by the half mirror 300. That is, the dextrorotatory circularly polarized light is changed to the levorotatory circularly polarized light, and the levorotatory circularly polarized light is changed to the dextrorotatory circularly polarized light. Therefore, the ray 1000 reflected by the half mirror 300 is transmitted through the optical laminate 100 and is visually recognized by the user.

In addition, in a case where the ray 1000 is reflected by the half mirror 300, since the half mirror has a concave mirror shape, the image is magnified so that the user can visually recognize the magnified virtual image. Such an optical system is called a pancake lens (reciprocal optical system or folded optical system).

On the other hand, FIG. 2 is a schematic view showing a case in which the ray 1000 is incident on the optical laminate 100 for the first time, is unnecessarily transmitted without being reflected to be a leaked light 2000. Specifically, the leaked light 2000 is, for example, light that is not reflected and is unnecessarily transmitted in a case where the optical laminate 100 (cholesteric liquid crystal layer) selectively reflects dextrorotatory circularly polarized light, and the ray 1000 of the dextrorotatory circularly polarized light is incident on the optical laminate 100 for the first time.

In this case, as shown in FIG. 2, the user visually recognizes the leaked light 2000 which is an image not magnified. This image is referred to as the ghost or the like, and the ghost or the like is required to be reduced.

The cholesteric liquid crystal layer originally does not have a phase difference (in-plane retardation). However, in the virtual reality display apparatus shown in FIGS. 1 and 2, the optical laminate 100, that is, the cholesteric liquid crystal layer is formed into a concave mirror shape. Therefore, the helical axis of the cholesteric liquid crystal layer changes partially in the plane, resulting in a phase difference. In the cholesteric liquid crystal layer having a phase difference, the incidence ray cannot be properly reflected and transmitted. Therefore, in a case where such a cholesteric liquid crystal layer is used in the pancake lens constituting the virtual reality display apparatus, the leaked light 2000, that is, the ghost increases.

On the other hand, the optical film (cholesteric liquid crystal layer) according to the first embodiment of the present invention has a curved shape as described above. Furthermore, in a case where a wavelength obtained by subtracting 20 nm from a half-value wavelength on a side shorter than a selective reflection center wavelength in the cholesteric liquid crystal layer is defined as an evaluation wavelength (measurement wavelength) of the in-plane retardation, an in-plane retardation A at the evaluation wavelength in a center of the cholesteric liquid crystal layer is less than 2% of the evaluation wavelength, and an in-plane retardation B at the evaluation wavelength in an outer edge portion of the cholesteric liquid crystal layer is less than 2% of the evaluation wavelength. That is, the optical film according to the first embodiment of the present invention has a small phase difference over the entire surface.

Therefore, the virtual reality display apparatus using the optical laminate 100 including the optical film according to the first embodiment of the present invention can suppress the occurrence of ghost even though the optical film, that is, the cholesteric liquid crystal layer has a curved shape.

In addition, such an optical film with a small phase difference over the entire surface can be produced by the forming method according to the first embodiment of the present invention, which will be described later.

FIG. 3 shows a layer configuration of one embodiment of the optical laminate 100.

The optical laminate 100 shown in FIG. 3 includes an antireflection layer 101, a positive C-plate 102, an optical film 103, a positive C-plate 104, a retardation layer 105, and a linear polarizer 106 in this order. The optical film 103 is the optical film according to the first embodiment of the present invention, and is a cholesteric liquid crystal layer.

The optical laminate 100 includes the optical film 103, the retardation layer 105 which converts circularly polarized light into linearly polarized light, and the linear polarizer 106 in this order. Here, the retardation layer 105 and the linear polarizer 106 are set such that the optical film 103 which originally reflects circularly polarized light converts the reflected circularly polarized light into linearly polarized light in a direction in which the linear polarizer absorbs. With the optical laminate 100, the light leakage from the optical film 103 (cholesteric liquid crystal layer) can be absorbed by the linear polarizer. Therefore, the degree of polarization of the transmitted light can be increased.

In a case where the optical laminate is formed, there is a concern that phase difference may occur in the cholesteric liquid crystal layer. However, as described above, in the cholesteric liquid crystal layer according to the first embodiment of the present invention, the phase difference remains small even in a case where the cholesteric liquid crystal layer is stretched or formed, and the amount of light leakage from the cholesteric liquid crystal layer is small, so that the increase in light leakage is suppressed to a minimal amount.

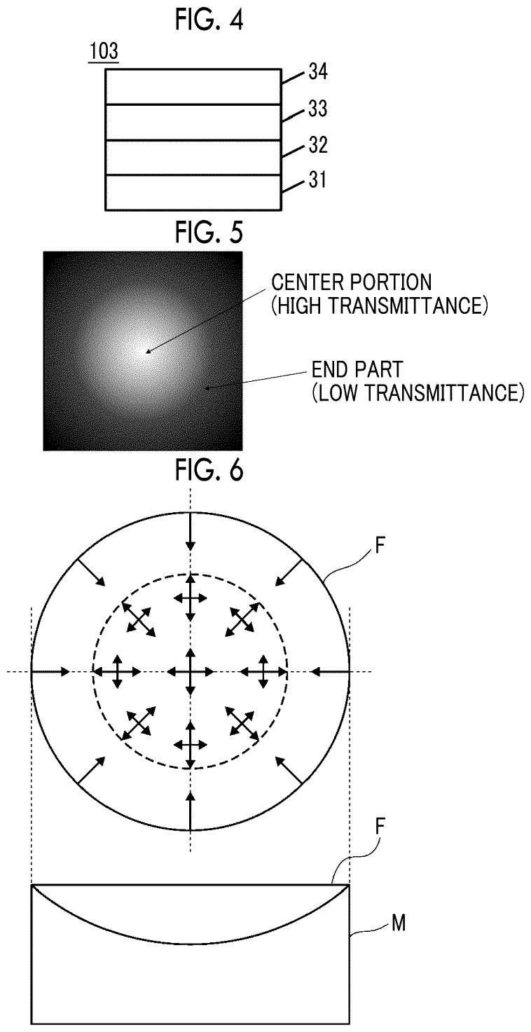

As described above, the optical film according to the first embodiment of the present invention may be composed of a plurality of cholesteric liquid crystal layers. FIG. 4 shows an example of the configuration.

The optical film 103 includes a first light reflecting layer (cholesteric liquid crystal layer) 31, a second light reflecting layer 32, a third light reflecting layer 33, and a fourth light reflecting layer 34 in this order. Examples of such an optical film 103 include the above-described optical film including a blue light reflecting layer in which a reflectivity at a wavelength of at least 460 nm is 40% or more, a green light reflecting layer in which a reflectivity at a wavelength of 550 nm is 40% or more, a yellow light reflecting layer in which a reflectivity at a wavelength of 600 nm is 40% or more, and a red light reflecting layer in which a reflectivity at a wavelength of 650 nm is 40% or more.

In addition, in the optical laminate, a surface roughness Ra is preferably 100 nm or less.

As the Ra is small, sharpness of the image can be improved, for example, in a case where the optical laminate is used in the virtual reality display apparatus or the like, which is preferable. The present inventors have presumed that, in a case where the light is reflected on the optical laminate, an angle of the reflected light is distorted in a case where the optical laminate has unevenness, which leads to image distortion and blurriness. The Ra of the optical laminate is preferably 50 nm or less, more preferably 30 nm or less, and still more preferably 10 nm or less.

In addition, the optical laminate is produced by laminating a plurality of layers. According to the studies conducted by the present inventors, it has been found that, in a case where a layer is laminated on a layer with unevenness, the unevenness may be amplified. Therefore, in the optical laminate, it is preferable that the Ra is small in all layers. Each layer of the optical laminate preferably has an Ra of 50 nm or less, more preferably 30 nm or less, and still more preferably 10 nm or less.

In addition, from the viewpoint of further enhancing image sharpness of the reflection image, it is particularly preferable that the Ra of the cholesteric liquid crystal layer is small.

The surface roughness Ra can be measured by, for example, a non-contact surface/layer cross-sectional shape measuring system VertScan (manufactured by Ryoka System, Inc.). Since the Vertscan is a surface shape measurement method using a phase of reflected light from a sample, in a case of measuring a reflective type circular polarizer consisting of the cholesteric liquid crystal layer, the reflected light from inside the film may overlap, which makes it possible to accurately measure the surface shape. In this case, a metal layer may be formed on the surface of the sample to increase the reflectivity of the surface and further suppress the reflection from the inside. As a main method of forming the metal layer on the surface of the sample, a sputtering method is used. Au, Al, Pt, or the like is used as a material to be sputtered.

It is preferable that the number of point defects per unit area in the optical laminate is small. Since the point defects lead to a decrease in degree of polarization of transmitted light or reflected light or a decrease in image sharpness, it is preferable that the number of point defects is small.

Since the optical laminate is produced by laminating a large number of layers, it is preferable that the number of point defects in each layer is also small in order to reduce the number of point defects in the entire optical laminate. Specifically, the number of point defects in each layer is preferably 20 or less, more preferably 10 or less, and still more preferably 1 or less per square meter. In addition, the number of point defects in the entire optical laminate is preferably 100 or less, more preferably 50 or less, and still more preferably 5 or less per square meter.

The number of the point defects is counted as the number of point defects having a size of preferably 100 m or more, more preferably 30 m or more, and still more preferably m or more.

The point defects include foreign matter, scratches, stains, fluctuations in film thickness, alignment failure of a liquid crystal compound, and the like.

In addition, various sensors using near-infrared light as a light source, such as eye tracking, facial expression recognition, and iris authentication, may be incorporated into an optical system of a virtual reality display apparatus, an electronic finder, or the like. In this case, in order to minimize influence on the sensor, it is preferable that the optical laminate is transparent to near-infrared light.

### [Retardation Layer]

The retardation layer used in the optical laminate has a function of converting emitted light into substantially linearly polarized light in a case where circularly polarized light is incident.

As the retardation layer, for example, a retardation layer in which an in-plane retardation Re is approximately ¼ wavelength at any of wavelengths in the visible range can be used. As an example, in the retardation layer, the in-plane retardation Re(550) at a wavelength of 550 nm is preferably 120 to 150 nm, more preferably 125 to 145 nm, and still more preferably 135 to 140 nm.

In addition, a retardation layer in which the Re is an approximately ¾ wavelength or approximately 5/4 wavelength is also preferable from the viewpoint that the linearly polarized light can be converted into the circularly polarized light.

In addition, it is preferable that the retardation layer used in the optical laminate has reverse dispersibility with respect to the wavelength.

It is preferable that the retardation layer has reverse dispersibility from the viewpoint that circularly polarized light can be converted into linearly polarized light over a wide wavelength range in the visible region. Here, the expression “having reverse dispersibility with respect to the wavelength” denotes that as the wavelength increases, the value of the phase difference at the wavelength increases.

The retardation layer having reverse dispersibility can be prepared, for example, by uniaxially stretching a polymer film such as a modified polycarbonate resin film having reverse dispersibility with reference to JP2017-049574A and the like.

In addition, the retardation layer having reverse dispersibility is not limited as long as the retardation layer substantially has reverse dispersibility, and can be prepared by laminating a retardation layer having Re of an approximately ¼ wavelength and a retardation layer having Re of an approximately ½ wavelength such that the slow axes form an angle of approximately 600 as described in, for example, JP06259925B. Here, it is known that even in a case where the ¼ wavelength retardation layer and the ½ wavelength retardation layer each have forward dispersibility (as the wavelength increases, the value of the phase difference at the wavelength decreases), circularly polarized light can be converted into linearly polarized light over a wide wavelength range in the visible region, and the layers can be regarded as having substantially reverse dispersibility. In this case, it is preferable that the optical laminate includes a cholesteric liquid crystal layer, a ¼ wavelength retardation layer, a ½ wavelength retardation layer, and a linear polarizer in this order.

In addition, it is also preferable that the retardation layer used in the optical laminate has a layer formed by immobilizing uniformly aligned liquid crystal compounds.

As such a retardation layer, for example, a layer formed by uniformly aligning rod-like liquid crystal compounds horizontally to the in-plane direction, a layer formed by uniformly aligning disk-like liquid crystal compounds vertically to the in-plane direction, or the like can be used. Furthermore, for example, a retardation layer having reverse dispersibility produced by uniformly aligning rod-like liquid crystal compounds having reverse dispersibility and immobilizing the compounds with reference to JP2020-084070A and the like can be used.

In addition, it is also preferable that the retardation layer used in the optical laminate has a layer formed by immobilizing twistedly aligned liquid crystal compounds with a helical axis in the thickness direction.

For example, as described in JP05753922B and JP05960743B, a retardation layer having a layer formed by immobilizing twistedly aligned rod-like liquid crystal compounds or twistedly aligned disk-like liquid crystal compounds with a helical axis in the thickness direction is used. In this case, the retardation layer can be regarded as having substantially reverse dispersibility, which is preferable.

A thickness of the retardation layer is not particularly limited, but from the viewpoint of thinning, it is preferably 0.1 to 8 m and more preferably 0.3 to 5 km.

The retardation layer may include a support, an alignment layer, or the like.

The support and the alignment layer may be a temporary support which is peeled off and removed in a case of manufacturing the optical laminate. It is preferable that a temporary support is used from the viewpoint that the thickness of the optical laminate can be reduced by transferring the retardation layer to another laminate and peeling and removing the temporary support and the adverse effect of the phase difference of the temporary support on the degree of polarization of transmitted light can be eliminated.

The type of the support is not particularly limited, but it is preferable that the support is transparent, and examples thereof include films of cellulose acylate, polycarbonate, polysulfone, polyethersulfone, polyacrylate and polymethacrylate, cyclic polyolefin, polyolefin, polyamide, polystyrene, polyester, and the like. Among these, a cellulose acylate film, cyclic polyolefin, polyacrylate, or polymethacrylate is preferable. As the support, a commercially available product can also be used. Examples of the commercially available product include cellulose acetate films such as “TD80U” and “Z-TAC” manufactured by FUJIFILM Corporation.

In a case where the support is a temporary support, a support having high tear strength is preferable from the viewpoint of preventing breakage during peeling. In this regard, a polycarbonate-based film or a polyester-based film is preferable.

In addition, from the viewpoint of suppressing the adverse effect on the degree of polarization of transmitted light, it is preferable that the support has a small phase difference. Specifically, it is preferable that an in-plane retardation of the support is 10 nm or less, and it is preferable that the absolute value of a thickness direction retardation Rth of the support is 50 nm or less. In addition, even in a case where the support is used as the above-described temporary support, it is preferable that the temporary support has a small phase difference from the viewpoint of performing quality inspection of the retardation layer or other laminates in a step of manufacturing the optical laminate.

In addition, various sensors using near-infrared light as a light source, such as eye tracking, facial expression recognition, and iris authentication, may be incorporated into an optical system of a virtual reality display apparatus, an electronic finder, or the like. In this case, in order to minimize influence on the sensor, it is preferable that the retardation layer used in the optical laminate is transparent to near-infrared light.

### [Linear Polarizer]

The linear polarizer used in the optical laminate is an absorption type polarizer, and absorbs linearly polarized light in an absorption axis direction among incidence rays and transmits linearly polarized light in a transmission axis direction.

As the linear polarizer, a general polarizer can be used. Examples thereof include a polarizer in which a dichroic substance is dyed on polyvinyl alcohol or another polymer resin and is stretched so that the dichroic substance is aligned may be used, and a polarizer in which a dichroic substance is aligned by using alignment of a liquid crystal compound. Among these, from the viewpoint of availability and an increase in degree of polarization, a polarizer obtained by dyeing polyvinyl alcohol with iodine and stretching polyvinyl alcohol is preferable.

A thickness of the linear polarizer is preferably 10 μm or less, more preferably 7 μm or less, and still more preferably 5 m or less. In a case where the linear polarizer is thin, cracks or breakage of the film can be prevented in a case where the optical laminate is stretched or formed.

In addition, a single plate transmittance of the linear polarizer is preferably 40% or more and more preferably 42% or more. Moreover, the degree of polarization is preferably 90% or more, more preferably 95% or more, and still more preferably 99% or more. In the present invention, the single plate transmittance and the degree of polarization of the linear polarizer are measured using an automatic polarizing film measuring device: VAP-7070 (manufactured by Jasco Corporation).

In addition, it is preferable that the direction of the transmission axis of the linear polarizer coincides with the direction of the polarization axis of light converted into linearly polarized light by the retardation layer. For example, in a case where the retardation layer is a layer having a phase difference of a ¼ wavelength, an angle between the transmission axis of the linear polarizer and the slow axis of the retardation layer is preferably approximately 450.

It is also preferable that the linear polarizer used in the optical laminate is a light absorption anisotropic layer containing a liquid crystal compound and a dichroic substance. The linear polarizer containing a liquid crystal compound and a dichroic substance is preferable from the viewpoint that the thickness thereof can be reduced and cracks or breakage is unlikely to occur even in a case of being stretched or formed. A thickness of the light absorption anisotropic layer is not particularly limited, but from the viewpoint of thinning, it is preferably 0.1 to 8 μm and more preferably 0.3 to 5 μm.

The linear polarizer containing a liquid crystal compound and a dichroic substance can be produced with reference to, for example, JP2020-023153A.

From the viewpoint of improving the degree of polarization of the linear polarizer, an alignment degree of the dichroic substance in the light absorption anisotropic layer is preferably 0.95 or more and more preferably 0.97 or more.

In a case where the linear polarizer consists of a light absorption anisotropic layer containing a liquid crystal compound and a dichroic substance, the linear polarizer may include a support, an alignment layer, or the like.

The support and the alignment layer may be a temporary support which is peeled off and removed in a case of manufacturing the optical laminate. It is preferable that a temporary support is used from the viewpoint that the thickness of the optical laminate can be reduced by transferring the light absorption anisotropic layer to another laminate and peeling and removing the temporary support and the adverse effect of the phase difference of the temporary support on the degree of polarization of transmitted light can be eliminated.

The type of the support is not particularly limited, but it is preferable that the support is transparent, and examples thereof include films made of cellulose acylate, polycarbonate, polysulfone, polyethersulfone, polyacrylate and polymethacrylate, cyclic polyolefin, polyolefin, polyamide, polystyrene, polyester, or the like. Among these, a cellulose acylate film, cyclic polyolefin, polyacrylate, or polymethacrylate is preferable. As the support, a commercially available product can also be used. Examples of the commercially available product include cellulose acetate films such as “TD80U” and “Z-TAC” manufactured by FUJIFILM Corporation.

In a case where the support is a temporary support, a support having high tear strength is preferable from the viewpoint of preventing breakage during peeling. In this regard, a polycarbonate-based film or a polyester-based film is preferable.

In addition, from the viewpoint of suppressing the adverse effect on the degree of polarization of transmitted light, it is preferable that the support has a small phase difference. Specifically, it is preferable that an in-plane retardation Re of the support is 10 nm or less, and it is preferable that the absolute value of a thickness direction retardation Rth of the support is 50 nm or less. In addition, even in a case where the support is used as the above-described temporary support, it is preferable that the temporary support has a small phase difference from the viewpoint of performing quality inspection of the light absorption anisotropic layer or other laminates in a step of manufacturing the optical laminate.

In addition, various sensors using near-infrared light as a light source, such as eye tracking, facial expression recognition, and iris authentication, may be incorporated into an optical system of a virtual reality display apparatus, an electronic finder, or the like. In this case, in order to minimize influence on the sensor, it is preferable that the linear polarizer used in the optical laminate is transparent to near-infrared light.

### [Other Functional Layers]

The optical laminate may include other functional layers, in addition to the cholesteric liquid crystal layer, the retardation layer, and the linear polarizer.

In addition, various sensors using near-infrared light as a light source, such as eye tracking, facial expression recognition, and iris authentication, may be incorporated into an optical system of a virtual reality display apparatus, an electronic finder, or the like. In this case, in order to minimize influence on the sensor, it is preferable that the other functional layers used in the optical laminate are transparent to near-infrared light.

### <Positive C-Plate>

As shown in FIG. 3, it is also preferable that the optical laminate further includes a positive C-plate. Here, the positive C-plate is a retardation layer in which an in-plane retardation Re is substantially zero and a thickness direction retardation Rth has a negative value.

The positive C-plate can be obtained, for example, by vertically aligning rod-like liquid crystal compounds. With regard to the details of the method for manufacturing the positive C-plate, reference can be made to the description in, for example, JP2017-187732A, JP2016-53709A, JP2015-200861A, and the like.

The positive C-plate functions as an optical compensation layer for increasing the degree of polarization of the transmitted light with respect to light incident obliquely. A plurality of the positive C-plates may be provided at any position of the optical laminate.

The positive C-plate may be provided adjacent to the cholesteric liquid crystal layer or inside the cholesteric liquid crystal layer.

For example, in a case where a light reflecting layer containing a rod-like liquid crystal compound, which is formed by immobilizing a cholesteric liquid crystalline phase, is used as the cholesteric liquid crystal layer, the light reflecting layer has a positive Rth. Here, in a case where light is incident on the cholesteric liquid crystal layer in an oblique direction, the polarization states of the reflected light and the transmitted light may change due to the action of the Rth, and the degree of polarization of the transmitted light may decrease. In a case where the positive C-plate is provided inside the cholesteric liquid crystal layer and/or in the vicinity thereof, the change in polarization state of the oblique incident light is suppressed and the decrease in degree of polarization of the transmitted light can be suppressed, which is preferable. According to the studies by the present inventors, it is preferable that the positive C-plate is disposed on a surface of the blue light reflecting layer on a side opposite to the green light reflecting layer, but the positive C-plate may be disposed at another place.

In this case, the in-plane retardation Re of the positive C-plate is preferably 10 nm or less, and the thickness direction retardation Rth of the positive C-plate is preferably −600 to −100 nm and more preferably −400 to −200 nm.

In addition, in the optical laminate, the positive C-plate may be provided adjacent to the retardation layer or inside the retardation layer.

For example, in a case where a layer formed by immobilizing a rod-like liquid crystal compound is used as the retardation layer, the retardation layer has a positive Rth. Here, in a case where light is incident on the retardation layer in an oblique direction, the polarization state of the transmitted light may change due to the action of the Rth, and the degree of polarization of the transmitted light may decrease. In a case where the positive C-plate is provided inside the retardation layer and/or in the vicinity thereof, the change in polarization state of the oblique incident light is suppressed and the decrease in degree of polarization of the transmitted light can be suppressed, which is preferable. According to the studies by the present inventors, it is preferable that the positive C-plate is disposed on a surface of the retardation layer on a side opposite to the linear polarizer, but the positive C-plate may be disposed at another place.

In this case, the in-plane retardation Re of the positive C-plate is preferably approximately 10 nm or less, and the thickness direction retardation Rth of the positive C-plate is preferably −90 to −40 nm.

### <Antireflection Layer>

It is also preferable that the optical laminate includes an antireflection layer on a surface thereof.

The optical laminate has a function of reflecting specific circularly polarized light and transmitting circularly polarized light orthogonal to the specific circularly polarized light, and the reflection on a surface of the optical laminate typically includes unintended reflection of polarized light, which leads to the decrease in degree of polarization of the transmitted light. Therefore, it is preferable that the optical laminate includes an antireflection layer on the surface thereof.

The antireflection layer may be provided only on one surface or on both surfaces of the optical laminate.

The type of the antireflection layer is not particularly limited, but from the viewpoint of further decreasing the reflectivity, suitable examples thereof include a moth-eye film and an AR film. In addition, in a case where the optical laminate is stretched or formed, the moth-eye film is more preferable from the viewpoint that high antireflection performance can be maintained even in a case of fluctuation in the film thickness due to the stretching.

Furthermore, the antireflection layer may include a support. In a case where the antireflection layer includes a support and the stretching or the forming of the optical laminate is performed, from the viewpoint of facilitating the stretching or the forming, the support of the antireflection layer has a Tg peak temperature of preferably 170° C. or lower and more preferably 130° C. or lower. Specifically, the support is preferably, for example, a PMMA film or the like.

### <Second Retardation Layer>

It is also preferable that the optical laminate further includes a second retardation layer. For example, the optical laminate may include the cholesteric liquid crystal layer, the retardation layer, the linear polarizer, and a second retardation layer in this order.

It is preferable that the second retardation layer converts linearly polarized light into circularly polarized light, and for example, a retardation layer having Re of a ¼ wavelength is preferable. The reason for this will be described below.

Light which has been incident on the optical laminate from the side of the cholesteric liquid crystal layer and transmitted through the cholesteric liquid crystal layer, the retardation layer, and the linear polarizer is converted into linearly polarized light, and a part of the light is reflected on the outermost surface on the side of the linear polarizer and emitted from the surface on the side of the cholesteric liquid crystal layer again. Such light is extra reflected light and may decrease the degree of polarization of the reflected light, and thus it is preferable that the amount of such light is reduced. Therefore, a method of laminating an antireflection layer may be considered to suppress reflection on the outermost surface on the side of the linear polarizer, but in a case where the optical laminate is used by being bonded to a medium such as glass or plastic, the antireflection effect cannot be obtained because reflection on the surface of the medium cannot be suppressed even in a case where the antireflection layer is provided on the bonding surface of the optical laminate.

On the other hand, in a case where the second retardation layer which converts linearly polarized light into circularly polarized light is provided, light which reaches the outermost surface on the side of the linear polarizer is converted into circularly polarized light, and converted into circularly polarized light orthogonal to each other in a case of reflection on the outermost surface of the medium. Thereafter, in a case where the light is transmitted through the second retardation layer again and reaches the linear polarizer, the light is converted into linearly polarized light in the absorption axis orientation of the linear polarizer and absorbed by the linear polarizer. Therefore, it is possible to prevent extra reflection. From the viewpoint of more effectively suppressing the extra reflection, it is preferable that the second retardation layer has substantially reverse dispersibility.

### <Support>

The optical laminate may further include a support. The support can be provided at any position, and for example, in a case where the cholesteric liquid crystal layer, the retardation layer, or the linear polarizer is a film used by being transferred from the temporary support, the support can be used as a transfer destination thereof.

The type of the support is not particularly limited, but it is preferable that the support is transparent, and examples thereof include films made of cellulose acylate, polycarbonate, polysulfone, polyethersulfone, polyacrylate and polymethacrylate, cyclic polyolefin, polyolefin, polyamide, polystyrene, polyester, or the like. Among these, a cellulose acylate film, cyclic polyolefin, polyacrylate, or polymethacrylate is preferable. In addition, as the support, a commercially available product can also be used. Examples of the commercially available product include cellulose acetate films such as “TD80U” and “Z-TAC” manufactured by FUJIFILM Corporation.

In addition, it is preferable that the support has a small phase difference from the viewpoint of suppressing the adverse effect on the degree of polarization of the transmitted light and viewpoint of facilitating the optical inspection of the optical laminate. Specifically, it is preferable that an in-plane retardation Re is 10 nm or less, and it is preferable that the absolute value of a thickness direction retardation Rth is 50 nm or less.

In a case where the optical laminate is stretched or formed, it is preferable that the support has a tan δ peak temperature of 170° C. or lower. From the viewpoint that the laminated optical film can be formed at a low temperature, the tan δ peak temperature is preferably 150° C. or lower and more preferably 130° C. or lower.

Here, a method of measuring tan δ will be described.

E″ (loss elastic modulus) and E′ (storage elastic modulus) of a film sample which has been humidity-adjusted in advance in an atmosphere of a temperature of 25° C. and a humidity of 60% Rh for 2 hours or longer are measured under the following conditions using a dynamic viscoelasticity measuring device (for example, DVA-200 manufactured by IT Measurement & Control Co., Ltd.), and the values are used to acquire tan δ (=E″/E′).
Device: DVA-200, manufactured by IT Measurement & Control Co., Ltd.
Sample: 5 mm, length of 50 mm (gap of 20 mm)
Measurement conditions: tension mode
Measurement temperature: −150° C. to 220° C.
Heating conditions: 5° C./min
Frequency: 1 Hz

Typically in optical applications, a resin base material subjected to a stretching treatment is frequently used, and the tan δ peak temperature is frequently increased due to the stretching treatment. For example, with a TAC (triacetyl cellulose) base material (TG40 manufactured by FUJIFILM Corporation), the tan δ peak temperature is 180° C. or higher.

The support having a tan δ peak temperature of 170° C. or lower is not particularly limited, and various resin base materials can be used.

Examples thereof include polyolefin such as polyethylene, polypropylene, and a norbornene-based polymer; a cyclic olefin-based resin; polyvinyl alcohol; polyethylene terephthalate; an acrylic resin such as polymethacrylic acid ester and polyacrylic acid ester; polyethylene naphthalate; polycarbonate; polysulfone; polyethersulfone; polyetherketone; polyphenylene sulfide, and polyphenylene oxide. Among these, from the viewpoint of being easily available from the market and having excellent transparency, a cyclic olefin-based resin, polyethylene terephthalate, an acrylic resin, or the like is suitable; and a cyclic olefin-based resin or polymethacrylic acid ester is particularly preferable.

Examples of a commercially available resin base material include TECHNOLLOY S001G, TECHNOLLOY S014G, TECHNOLLOY S000, TECHNOLLOY C001, and TECHNOLLOY C000 (Sumika Acryl Co., Ltd.); LUMIRROR U type, LUMIRROR FX10, and LUMIRROR SF20 (manufactured by Toray Industries, Inc.); HK-53A (manufactured by Higashiyama Film Co., Ltd.); TEFLEX FT3 (manufactured by TOYOBO CO., LTD.); ESCENA and SCA40 (manufactured by Sekisui Chemical Co., Ltd.); ZEONOR Film (manufactured by ZEON CORPORATION); and Arton Film (manufactured by JSR Corporation).

A thickness of the support is not particularly limited, and is preferably 5 to 300 m, more preferably 5 to 100 m, and still more preferably 5 to 30 m.

### [Method of Bonding Each Layer]

The optical laminate is a laminate consisting of a plurality of layers. Each layer can be bonded by any bonding method. The bonding can be performed using a pressure sensitive adhesive, an adhesive, or the like.

As the pressure sensitive adhesive, a commercially available pressure sensitive adhesive can be optionally used. Here, from the viewpoint of thinning and reducing the surface roughness Ra of the optical laminate, a thickness of the pressure sensitive adhesive is preferably 25 μm or less, more preferably 15 μm or less, and still more preferably 6 μm or less. In addition, a pressure sensitive adhesive which is unlikely to generate outgas is preferable as the pressure sensitive adhesive. In particular, in a case of performing stretching, forming, or the like of the optical laminate, a vacuum process or a heating process may be performed, and it is preferable that no outgas is generated even under such conditions.

As the adhesive, a commercially available adhesive or the like can be optionally used. Examples of the adhesive include an epoxy resin-based adhesive and an acrylic resin-based adhesive.

From the viewpoint of thinning and reducing the surface roughness Ra of the optical laminate, a thickness of the adhesive is preferably 25 μm or less, more preferably 5 μm or less, and still more preferably 1 μm or less. In addition, from the viewpoint of reducing the thickness of the adhesive layer and coating an adherend with the adhesive such that the thickness thereof is uniform, a viscosity of the adhesive is preferably 300 cP or less, more preferably 100 cP or less, and still more preferably 10 cP or less.

In addition, in a case where the adherend has surface unevenness, from the viewpoint of reducing the surface roughness Ra of the optical laminate, an appropriate viscoelasticity or an appropriate thickness of the pressure sensitive adhesive or the adhesive can also be selected so that the surface unevenness of the layer to be bonded can be embedded. From the viewpoint of embedding the surface unevenness, it is preferable that the pressure sensitive adhesive or the adhesive has a viscosity of 50 cP or more. In addition, it is preferable that the thickness thereof is more than a height of the surface unevenness.

Examples of a method of adjusting the viscosity of the adhesive include a method of using an adhesive containing a solvent. In this case, the viscosity of the adhesive can be adjusted by a proportion of the solvent. In addition, the thickness of the adhesive can be further reduced by drying the solvent after coating the adherend with the adhesive.

In the optical laminate, from the viewpoint of reducing the extra reflection and suppressing a decrease in degree of polarizations of transmitted light and reflected light, it is preferable that the pressure sensitive adhesive or adhesive used for adhering each layer has a small difference in refractive index with adjacent layers. Specifically, the difference in refractive index with the adjacent layer is preferably 0.1 or less, more preferably 0.05 or less, and still more preferably 0.01 or less. The refractive index of the pressure sensitive adhesive or the adhesive can be adjusted, for example, by mixing fine particles of titanium oxide, fine particles of zirconia, or the like.

In addition, the cholesteric liquid crystal layer, the retardation layer, and the linear polarizer have in-plane refractive index anisotropy, but the difference in refractive index with the adjacent layer is preferably 0.05 or less in all in-plane directions. Therefore, the pressure sensitive adhesive or the adhesive may have in-plane refractive index anisotropy.

In addition, a thickness of the bonding layer between the layers is preferably 100 nm or less. In a case where the thickness of the bonding layer is 100 nm or less, light in the visible region is less likely to be affected by the difference in refractive index, and extra reflection can be suppressed. The thickness of the bonding layer is more preferably 50 nm or less.

Examples of a method of forming the bonding layer having a thickness of 100 nm or less include a method of vapor-depositing a ceramic adhesive such as silicon oxide (SiOx layer) on the bonding surface. A bonding surface of the bonding member may be subjected to a surface reforming treatment such as plasma treatment, corona treatment, and saponification treatment, before the bonding. In addition, a primer layer may be provided on the bonding surface of the bonding member.

Furthermore, in a case where a plurality of bonding surfaces are present, the type and thickness of the bonding layer can be adjusted for each of the bonding surfaces. Specifically, for example, the bonding layer having a thickness of 100 nm or less can be provided by the procedures (1) to (3) described below.

(1) A layer to laminate is bonded to a temporary support consisting of a glass base material.

(2) An SiOx layer having a thickness of 100 nm or less is formed on both the surface of the layer to laminate and the surface of the layer to be laminated by vapor deposition or the like; the vapor deposition can be carried out by, for example, a vapor deposition device (model number ULEYES, manufactured by ULVAC, Inc.) using SiOx powder as a vapor deposition source; in addition, it is preferable that the surface of the formed SiOx layer is subjected to a plasma treatment.

(3) After the formed SiOx layers are bonded to each other, the temporary support is peeled off; it is preferable that the bonding is carried out, for example, at a temperature of 120° C.

The application, the adhesion, or the bonding of the layers may be carried out by roll-to-roll or single-wafer. The roll-to-roll method is preferable from the viewpoint of improving productivity, reducing axis misalignment of each layer, and the like.

Meanwhile, the single-wafer method is preferable from the viewpoints that this method is suitable for production of many kinds in small quantities and that a special adhesion method in which the thickness of the bonding layer is 100 nm or less can be selected.

In addition, examples of the method of coating the adherend with the adhesive include known methods such as a roll coating method, a gravure printing method, a spin coating method, a wire bar coating method, an extrusion coating method, a direct gravure coating method, a reverse gravure coating method, a die-coating method, a spraying method, and an ink jet method.

### [Direct Application of Each Layer]

It is also preferable that the optical laminate does not include the bonding layer between the layers. In a case of forming a layer, the bonding layer can be eliminated by directly coating an adjacent layer which has already been formed.

Furthermore, in a case where one or both adjacent layers are layers containing a liquid crystal compound, it is preferable that the alignment direction of the liquid crystal compound is continuously changed at the interface in order to reduce the difference in refractive index in all in-plane directions. For example, the linear polarizer containing a liquid crystal compound and a dichroic substance is directly coated a retardation layer containing a liquid crystal compound, and the liquid crystal compound of the retardation layer can be aligned so as to align the liquid crystal compound continuously at the interface by alignment regulating force of the liquid crystal compound of the linear polarizer.

### [Lamination Order of Each Layer]

The optical laminate consists of a plurality of layers, and the order of the steps of laminating the plurality of layers is not particularly limited and can be optionally selected.

For example, in a case where a functional layer is transferred from a film consisting of a temporary support and a functional layer, wrinkles and cracks during the transfer can be prevented by adjusting the laminating order such that the thickness of the film at the transfer destination reaches 10 m or more.

In addition, in a case where another layer is laminated on a layer with large surface unevenness in the optical laminate, the surface unevenness may be further amplified. Therefore, from the viewpoint of reducing the surface roughness Ra of the optical laminate, it is preferable to laminate the layers in the order from a layer with the smallest surface roughness Ra.

Furthermore, from the viewpoint of quality evaluation in the step of producing the optical laminate, the laminating order can also be selected. For example, layers excluding the cholesteric liquid crystal layer are laminated, the quality evaluation is performed using a transmission optical system, the cholesteric liquid crystal layer is laminated thereon, and the quality evaluation is performed using a reflection optical system.

In addition, from the viewpoint of improving the production yield of the optical laminate and reducing the cost, it is also possible to select the laminating order.

A second aspect of the optical film according to the first embodiment of the present invention is a film which is not the cholesteric liquid crystal layer and does not have selective reflectivity.

Various known optical elements can be used for the optical laminate using the optical film, and the above description applies to each optical element.

### <Composite Lens>

One aspect of the composite lens includes a lens and the optical film according to the first embodiment of the present invention. Alternatively, one aspect of the composite lens includes a lens and an optical laminate which includes the optical film according to the first embodiment of the present invention. As shown in FIG. 1, the half mirror may be formed on one surface of the lens.

As the lens, a convex lens or a concave lens can be used. As the convex lens, a biconvex lens, a plano-convex lens, or a convex meniscus lens can be used. As the concave lens, a biconcave lens, a plano-concave lens, or a concave meniscus lens can be used.

As the lens used in the virtual reality display apparatus, a convex meniscus lens or a concave meniscus lens is preferable for enlarging the angle of view, and a concave meniscus lens is more preferable in that chromatic aberration can be further suppressed.

As a forming material of the lens, a material transparent to visible light, such as glass, crystal, and plastic, can be used. Since the birefringence of the lens causes rainbow-like unevenness or light leakage, it is preferable that the birefringence is small, and a material having zero birefringence is more preferable.

### <Virtual Reality Display Apparatus>

As shown in FIG. 1, one embodiment of the virtual reality display apparatus includes at least an image display panel which emits polarized light, and a composite lens including the optical film according to the first embodiment of the present invention. In addition, the virtual reality display apparatus may include an additional optical member such as a half mirror and a visual acuity adjustment lens.

### <Image Display Panel>

In the virtual reality display apparatus using the optical film according to the first embodiment of the present invention, a known image display device can be used as the image display panel (image display device).

Specific examples of the image display panel include a display device in which self-luminous microscopic light emitters are arranged on a transparent substrate, such as an organic electroluminescent display device, a light emitting diode (LED) display device, and a micro LED display device.

In these self-luminous display devices, a (circular) polarizing plate is usually bonded to a display surface to prevent reflection on the display surface. Therefore, the emitted light is polarized.

In addition, a liquid crystal display device is exemplified as other image display devices. Since the liquid crystal display device also has a polarizing plate on the surface, the emitted light is polarized. In the following description, the organic electroluminescent display device will also be referred to as “OLED”. OLED is an abbreviation for “Organic Light Emitting Diode”.

### <Forming Method>

As described above, the optical film according to the first embodiment of the present invention has a curved shape of a non-developable surface with a positive Gaussian curvature, such as a spherical surface, a parabolic surface, an elliptical surface, and an aspherical surface. The optical film (optical laminate) having such a curved shape is formed by producing a planar optical film, pressing the optical film against a mold to form the optical film into a curved surface shape, and finally cutting the formed optical film into a desired shape of an optical element, for example, a circular shape in the case of a lens having a circular planar shape.

A forming method (molding method) according to the first embodiment of the present invention, in which the planar optical film is formed into an optical film having a curved shape, includes a step (heating step) of heating the optical film or the mold, a step (forming step) of pressing the heated optical film against a mold to deform the optical film along a shape of the mold, and a step (cutting step) of cutting the formed optical film. The forming method shown below also includes forming of an optical laminate including the optical film according to the first embodiment of the present invention.

In the following description, the planar optical film to be formed into a curved shape is also referred to as “film to be formed” for convenience.

### [Heating Step (Step of Heating Optical Film)]

In the heating step, there are no restrictions on a method of heating the film to be formed, and various known methods can be used.

Examples thereof include heating by bringing a heated solid into contact, heating by bringing a heated liquid into contact, heating by bringing a heated gas into contact, heating by irradiating with infrared rays, and heating by irradiating with microwaves. Among these, heating by irradiation with infrared rays is preferable because it allows for remote heating just before the forming.

In the heating step, the mold may be heated instead of the film to be formed. The heating of the mold in this case may also be performed by a known method.

A wavelength of the infrared rays used for the heating is not limited, but is preferably 1.0 to 30.0 μm and more preferably 1.5 to 5 μm.

Examples of the infrared ray source (IR light source) include a near-infrared lamp heater in which a tungsten filament is inserted into a quartz tube, and a wavelength control heater in which a mechanism for cooling a part between quartz tubes with air is provided by multiplexing the quartz tubes.

In addition, by distributing the irradiation amount of infrared rays on the film to be formed, physical property values during the forming can be controlled according to the purpose. As a method of providing the distribution (intensity distribution) to the irradiation amount of infrared rays, a known method can be used. Examples thereof include a method of varying the density of the arrangement of the IR light sources and a method of placing a filter with a patterned transmittance to infrared light between the IR light sources and the film to be formed.

Examples of the filter in which the transmittance is patterned include a filter in which a metal is deposited on glass, a filter in which a cholesteric liquid crystal layer having a selective reflection wavelength range in an infrared region is provided, a filter in which a dielectric multi-layer film having a selective reflection wavelength range in an infrared region is provided, and a filter in which an ink that absorbs infrared rays is applied.

In the heating step, a temperature of the film to be formed may be controlled by the amount of irradiated infrared rays. Examples thereof include a method of controlling the irradiation time of the infrared rays and a method of controlling the illuminance of the infrared rays to be irradiated. The temperature of the film to be formed can be monitored using, for example, a noncontact radiation thermometer, a thermocouple, or the like, and can be set to a desired temperature.

In the heating step, the mold may be heated instead of the film to be formed. The heating of the mold in this case may also be performed by a known method.

### [Forming Step (Step of Pressing Film to be Formed Against Mold to Deform Film to be Formed Along Shape of Mold)]

In the forming step, as a method of pressing the film to be formed against the mold to deform the film to be formed along a shape of the mold, for example, in a case where the mold is a concave surface, decompression and pressurization of a molding space are exemplified. In addition, in a case where the mold is a convex surface, a method of pushing the mold can also be used.

### [Step of Cutting Optical Film]

As a method of cutting the formed optical film into any desired shape, a cutter, scissors, a cutting plotter, or a laser cutting machine can be used.

The optical film according to the first embodiment of the present invention, which has a curved shape, is obtained by forming a cholesteric liquid crystal layer or an optical film which does not have selective reflectivity into a curved shape.

The cholesteric liquid crystal layer basically does not have a phase difference (in-plane retardation). In addition, in the present invention, the optical film having no selective reflectivity is preferably an optical film with a small phase difference, which is formed of a polymer resin having low birefringence, and specifically the optical film has an in-plane retardation of less than 11 nm at a wavelength of 550 nm. In the present invention, the phase difference is an in-plane phase difference (phase difference in an in-plane direction), unless otherwise specified.

Here, according to the studies of the present inventors, in a case where such an optical film (film to be formed) is heated and formed into a curved shape, the amount and direction of stretching partially differ, resulting in an in-plane phase difference.

As an example, a case in which a film F to be formed is formed by pressing the film F against a mold M having a concave spherical surface will be described conceptually with reference to FIG. 6.

In a case where such forming is performed, the optical film F after the forming has different states of stretching between a center part and an outer edge portion (end part). Specifically, in this case, the center part of the optical film F is stretched in both the circumferential direction and the diameter direction. On the other hand, in the optical film F, that is, at the outer edge portion of the spherical mold M, stretching in the circumferential direction is almost nonexistent, and stretching occurs only in the diameter direction.

That is, in this case, the center part of the optical film F is uniformly stretched over the entire surface, whereas the outer edge portion is stretched only in one direction along the diameter. Such unevenness of the stretching amount increases as a distance from the center to the outer edge portion increases. In other words, in a case where the optical film is formed into a curved shape by being pressed against the mold M, the optical film is isotropically stretched at the center part, but the optical film has anisotropy in stretching at the outer edge portion, that is, the end part. In addition, the anisotropy of the stretching increases gradually from the center to the end part.

As a result, in the cholesteric liquid crystal layer, the change in helical axis in the center part is small, but the helical axis changes in the outer edge portion and the vicinity of the outer edge portion, causing a phase difference. In the cholesteric liquid crystal layer having a phase difference, the incidence ray cannot be properly reflected and transmitted. Therefore, in a case where such a cholesteric liquid crystal layer is used in a pancake lens constituting a virtual reality display apparatus, occurrence of unnecessary images is observed, that is, so-called ghost (light leakage) increases, as described above.

In addition, in a case where a so-called low retardation film (zero retardation film) is stretched uniformly in the plane direction at the center part and is stretched largely only in the diameter direction at the outer edge portion, the balance of the optical characteristics of the film is deteriorated in the outer edge portion and in the vicinity of the outer edge portion. As a result, a phase difference occurs, and the formed optical film having a curved shape exhibits a variation with in-plane phase difference, leading to a deterioration in the function as a low retardation film.

On the other hand, according to the forming method according to the first embodiment of the present invention, in a case where a planar optical film (film to be formed) is heated and pressed against a mold to be formed into a curved shape, it is possible to suppress the occurrence of phase difference.

As a result, with the forming method according to the first embodiment of the present invention, as described above, the optical film according to the first embodiment of the present invention, which includes the cholesteric liquid crystal layer having a curved shape or the film having a curved shape and having no selective reflectivity, in which the phase difference, that is, the in-plane retardation is small, can be produced.

Hereinafter, the forming method according to the first embodiment of the present invention will be described.

As described above, the forming method according to the first embodiment of the present invention includes a heating step of heating a planar optical film (film to be formed), a forming step of pressing the heated film to be formed against a mold to deform the film into a curved shape along the mold, and a cutting step of cutting the formed optical film.

A first aspect of the forming method according to the first embodiment of the present invention is that, in the heating step of the forming method, the film to be formed is heated by irradiation with infrared rays, and an in-plane distribution of the irradiation amount of infrared rays is provided. In other words, in the first aspect of the forming method according to the first embodiment of the present invention, in the heating of the film to be formed by infrared irradiation, an in-plane distribution is provided for the heating amount of the film to be formed, that is, the temperature of the film to be formed after the heating.

More specifically, as a preferred aspect, in the first aspect of the forming method according to the first embodiment of the present invention, a mold having a concave surface of a non-developable surface with a positive Gaussian curvature is used, and in a case where an in-plane position of the film to be formed is projected onto the mold from a normal direction of a main surface of the film to be formed, an amount of infrared irradiation to the film to be formed at a vertex (bottom portion) of the concave surface is larger than an amount of infrared irradiation to the film to be formed at the end part of the concave surface, that is, at the outer edge portion. In other words, with the first aspect of the forming method according to the first embodiment of the present invention, in the heating of the film to be formed by infrared irradiation, the temperature of the vertex of the concave surface of the mold, that is, the center of the film to be formed after the forming, is set to be higher than the outer edge portion (end part).

The main surface is a maximum surface of a material (a film, a plate-like material, or a layer), and is usually on both surfaces of the sheet-like material in a thickness direction. In addition, the normal direction is, in other words, a direction orthogonal to the main surface of the sheet-like material.

In the forming by pressing against the mold, the deformation, that is, the stretching of the film to be formed is usually more easily performed at a higher temperature.

That is, in the first aspect of the forming method according to the first embodiment of the present invention, by setting the temperature of the center part of the film to be formed higher than the temperature of the outer edge portion, most of the forming, that is, the stretching is performed at the center part which is stretched uniformly in the plane direction. Therefore, the optical film after being formed into a curved shape can largely be a region which is uniformly stretched in the plane direction and does not exhibit the phase difference.

As a result, with the first aspect of the forming method according to the first embodiment of the present invention, the optical film according to the first embodiment of the present invention, with a small phase difference, that is, small in-plane retardation can be produced.

In the first aspect of the forming method according to the first embodiment of the present invention, a difference in temperature between the center part and the end part of the film to be formed (mold) is not limited, and may be appropriately set according to a material for forming the film to be formed (optical laminate before forming). Examples thereof include a method in which the temperature of the center part is set to Tg or higher and the temperature of the end part is set to lower than Tg in accordance with Tg (glass transition temperature) of a layer which mainly controls the stretching of the film to be formed.

As a result, it is possible to further deform the center part which is uniformly stretched in the plane direction.

In addition, in the first aspect of the forming method according to the first embodiment of the present invention, the conversion of the irradiation amount of infrared rays between the center part and the end part, that is, the temperature change may be stepwise or continuous.

In the first aspect of the forming method according to the first embodiment of the present invention, a known method can be used for providing the difference in irradiation amount of infrared rays between the center part and the end part. Examples thereof include a method of varying the density of the arrangement of the above-described light sources and a method of placing a filter with a patterned transmittance to infrared light between the light sources and the film to be formed.

A second aspect of the forming method according to the first embodiment of the present invention is that, in the forming of the optical film including the heating step, the forming step, and the cutting step as described above, a surface of the mold, which comes into contact with the optical film (film to be formed), is a concave surface of a non-developable surface in which a Gaussian curvature is positive, and an outer peripheral shape thereof is an ellipse. In addition, in the cutting step, the optical film is cut into an elliptical shape, and a major axis of the elliptical outer peripheral shape of the optical film cut out by the cutting is set to be more than 50% and less than 95% of a major axis of the elliptical outer peripheral shape of the mold.

In the present invention, the ellipse includes the circular shape as described above.

That is, in the second aspect of the forming method according to the first embodiment of the present invention, the heating step and the forming step are performed using a large planar-shaped film to be formed and a large mold, as compared with the produced optical film having a curved shape. Thereafter, in the cutting step, only a portion which is pressed and formed, that is, stretched, at the center part of the optical film, that is, at the center part of the mold is cut out.

Therefore, also in the second aspect of the forming method according to the first embodiment of the present invention, the optical film after being cut and formed into a curved shape has a region which is uniformly stretched in the plane direction and in which the phase difference does not occur, in most cases. As a result, even with the second aspect of the forming method according to the first embodiment of the present invention, the optical film according to the embodiment of the present invention, with a small phase difference, that is, small in-plane retardation can be produced.

In the second aspect of the forming method according to the first embodiment of the present invention, the major axis of the elliptical outer peripheral shape of the optical film cut out in the cutting step is set to be more than 50% and less than 95% of the major axis of the elliptical outer peripheral shape of the mold.

In a case where the major axis of the optical film to be cut out is 50% or less of the major axis of the outer peripheral shape of the mold, a disadvantage that the optical film is wasted occurs.

In a case where the major axis of the optical film to be cut out is 95% or more of the major axis of the outer peripheral shape of the mold, there are many regions where the amount of stretching in the circumferential direction and the amount of stretching in the diameter direction differ significantly, making it impossible to obtain an optical film with a curved shape and a sufficiently small phase difference over the entire surface.

In the second aspect of the forming method according to the first embodiment of the present invention, the major axis of the elliptical outer peripheral shape of the optical film cut out in the cutting step is preferably 60% to 90% and more preferably 70% to 90% with respect to the major axis of the elliptical outer peripheral shape of the mold.

A third aspect of the forming method according to the first embodiment of the present invention is that, in the forming of the optical film including the heating step, the forming step, and the cutting step as described above, in the heating step, a region of the optical film (film to be formed), which comes into contact with the mold, is heated at a temperature higher than a glass transition temperature Tg of the film to be formed, and in the forming step, immediately after the film to be formed comes into contact with the mold, the pressing of the film to be formed against the mold is controlled such that the region of the film to be formed, which comes into contact with the mold, has a temperature lower than the glass transition temperature Tg.

In the forming method, in a case of forming an optical laminate including the optical film, that is, in a case where the optical laminate including the optical film is the film to be formed, temperature control is performed targeting the glass transition temperature Tg of the member with the highest rigidity, such as a support.

For example, in a case where the mold is a concave surface and the planar optical film (film to be formed) is pressed against the mold, the film to be formed first comes into contact with the mold at the end part of the film, and finally, the center part comes into contact with the top (bottom) of the concave surface. In addition, unless heating or the like is performed, the temperature of the mold is lower than the temperature of the film to be formed, which is heated for the forming.

That is, the third aspect of the forming method according to the first embodiment of the present invention is that, in the forming step, the film to be formed is pressed against the mold at a temperature of Tg or higher, such that the center part remains in a stretchable state, while the region which comes into contact with the mold is in a less stretchable state. Therefore, also in the third aspect of the forming method according to the first embodiment of the present invention, most of the forming, that is, the stretching is performed in the center part which is uniformly stretched in the plane direction, and the optical film after being formed into a curved shape can be regarded as a region which is uniformly stretched in the plane direction and in which the phase difference does not occur.

As a result, with the third aspect of the forming method according to the first embodiment of the present invention, the optical film according to the first embodiment of the present invention, with a small phase difference, that is, small in-plane retardation can be produced.

In the third aspect of the forming method according to the first embodiment of the present invention, in the forming step, various methods can be used as a control method for pressing the film to be formed such that the region of the film to be formed, which comes into contact with the mold, is lower than the glass transition temperature Tg immediately after the film to be formed comes into contact with the mold.

Examples thereof include a control method in which the film to be formed is heated in the heating step, and then a speed at which the film to be formed is pressed against the mold is adjusted such that the region which comes into contact with the mold has a temperature lower than the glass transition temperature Tg.

A fourth aspect of the forming method according to the first embodiment of the present invention includes a heating step of heating the mold, a forming step of pressing the heated mold against an optical film (film to be formed) to deform the optical film along a shape of the mold, and a cutting step of cutting the optical film.

In the fourth aspect of the forming method according to the first embodiment of the present invention, the mold is a convex surface of a non-developable surface in which a Gaussian curvature is positive, and in the forming step, the forming of the film to be formed is performed by pressing a vertex of the convex surface of the mold against a center of the film to be formed.

In addition, it is preferable that a cutting shape of the optical film in the cutting step is an ellipse, and in the forming step, the film to be formed is pressed against the mold while constraining a position on an elliptical line which is to be the cutting shape.

That is, in the fourth aspect of the forming method according to the first embodiment of the present invention, by pressing the heated mold against the center of the optical film (film to be formed) to form the optical film into a curved shape, the temperature of the center part of the film to be formed is first increased to make it easier to stretch, and as the mold is continuously pressed against the film to be formed, the high temperature region spreads toward the end part.

Therefore, also in the fourth aspect of the forming method according to the first embodiment of the present invention, most of the forming, that is, the stretching is performed in the center part which is uniformly stretched in the plane direction, and the optical film after being formed into a curved shape can be regarded as a region which is uniformly stretched in the plane direction and in which the phase difference does not occur.

Preferably, the forming is performed by pressing the mold while constraining the end part of the film to be formed, thereby suppressing the stretching near the end part where the stretching has anisotropy and the phase difference is likely to occur, and more suitably performing most of the stretching in the center part.

As a result, with the fourth aspect of the forming method according to the first embodiment of the present invention, the optical film according to the first embodiment of the present invention, with a small phase difference, that is, small in-plane retardation can be produced.

In the fourth aspect of the forming method according to the first embodiment of the present invention, there are no restrictions on the method of constraining the end part of the film to be formed, and various methods can be used.

Examples thereof include a method in which the vicinity of the end part of the film to be formed is attached to a support table which supports the film to be formed by pressing a convex mold against the film, using a peelable pressure-sensitive adhesive sheet or the like; and a method in which the vicinity of the end part of the film to be formed is fixed to a support table which supports the film to be formed by pressing a convex mold against the film, using a holding device or the like.

### <Forming Device>

A forming device for the optical film, which performs the forming method according to the first embodiment of the present invention, is not limited, and a forming device having various configurations can be used.

As one aspect of the forming device, a box 1 having an opening portion on an upper surface and a box 2 having an opening portion on a lower surface are provided. The opening portion of the box 1 and the opening portion of the box 2 are fitted together directly or through other holding devices to form a sealed forming space.

In the forming space, a planar optical film to be formed (film to be formed) and a mold for forming the optical film are arranged. In a case where the optical film (optical laminate) according to the first embodiment of the present invention is bonded to a lens to form the composite lens as described above, a lens such as a concave lens may be used as the mold, and the optical film formed into a curved shape may be directly bonded to the mold.

The forming device is provided with a heating unit for heating the film to be formed, such as an IR light source. A plurality of heating units may be arranged in a dispersed manner. The heating unit may be disposed within the forming space, or may be disposed outside the forming space to irradiate the film to be formed with heat rays such as infrared rays through a transparent window.

The film to be formed is disposed as a partition to divide the forming space which consists of the box 1 and the box 2 into two spaces. In addition, the mold is disposed in the box 1 which is located below the film to be formed.

In this state, the inside of the box 1 and the inside of the box 2 are depressurized to a predetermined pressure, the film to be formed is heated, and then the pressure inside the box 2 is increased (the degree of depressurization is decreased) to press the film to be formed against the mold.

### Second Embodiment

### <Cholesteric Liquid Crystal Layer (Optically Functional Layer)>

The cholesteric liquid crystal layer (optically functional layer) according to the second embodiment of the present invention is an optically functional layer containing a liquid crystal compound, in which the cholesteric liquid crystal layer has a phase difference region in which a phase difference increases from a center toward outside, and in the phase difference region, a direction of a slow axis at one point in the phase difference region and a direction from the center to the one point are orthogonal to each other.

In addition, the optical laminate according to the second embodiment of the present invention is an optical laminate having a plurality of the cholesteric liquid crystal layers described above.

The cholesteric liquid crystal layer and the optical laminate according to the second embodiment of the present invention may be used alone, or may be laminated with other functional layers such as a support and an alignment film, to be used as an optical film.

### [Cholesteric Liquid Crystalline Phase]

It is known that the cholesteric liquid crystalline phase exhibits selective reflectivity at a specific wavelength.

A central wavelength of selective reflection (selective reflection center wavelength) k of a general cholesteric liquid crystalline phase depends on a helical pitch P in the cholesteric liquid crystalline phase, and satisfies a relationship of λ=n×P with an average refractive index n of the cholesteric liquid crystalline phase. Therefore, the selective reflection center wavelength can be adjusted by adjusting the helical pitch.

The selective reflection center wavelength of the cholesteric liquid crystalline phase increases as the pitch P increases.

As described above, the helical pitch P refers to one pitch (helical period) of the helical structure of the cholesteric liquid crystalline phase, in other words, one helical turn. That is, the helical pitch refers to a length in a helical axis direction in which a director (in the case of a rod-shaped liquid crystal, a major axis direction) of the liquid crystal compound constituting the cholesteric liquid crystalline phase rotates by 360°.

In a case where a cross-section of the cholesteric liquid crystal layer is observed with a scanning electron microscope (SEM), a stripe pattern in which bright lines (bright portions) and dark lines (dark portions) derived from a cholesteric liquid crystalline phase are alternately laminated in the thickness direction is observed. The helical pitch, that is, the pitch P is equal to a length corresponding to two bright lines and two dark lines in the thickness direction, that is, a length corresponding to two dark lines and two bright lines in the thickness direction.

The helical pitch of the cholesteric liquid crystalline phase depends on the type of the chiral agent used together with the liquid crystal compound, and the concentration of the chiral agent added during the formation of the cholesteric liquid crystal layer. Therefore, a desired helical pitch can be obtained by adjusting these conditions.

Regarding the adjustment of the pitch, detailed description can be referred to FUJIFILM Research Report No. 50 (2005), pp. 60 to 63. Regarding a method for measuring the helical sense and the pitch of the helix, it is possible to use the method described on page 46 of “Liquid Crystal Chemical Experiment Introduction” edited by Japan Liquid Crystal Society, published by Sigma Corporation in 2007, and page 196 of “Liquid Crystal Handbook” Liquid Crystal Handbook Editing Committee, Maruzen Publishing Co., Ltd.

The cholesteric liquid crystalline phase exhibits selective reflectivity with respect to left-handed or right-handed circular polarization at a specific wavelength. Whether or not the reflected light is dextrorotatory circularly polarized light or levorotatory circularly polarized light is determined depending on a helically twisted direction (sense) of the cholesteric liquid crystalline phase. Regarding the selective reflection of the circular polarization by the cholesteric liquid crystalline phase, in a case where the helically twisted direction of the cholesteric liquid crystal layer is dextrorotatory, dextrorotatory circularly polarized light is reflected, and in a case where the helically twisted direction of the cholesteric liquid crystal layer is levorotatory, levorotatory circularly polarized light is reflected. Accordingly, the helical twisted direction in the cholesteric liquid crystalline phase can be verified by causing dextrorotatory circularly polarized light and/or levorotatory circularly polarized light to be incident into the cholesteric liquid crystal layer.

The direction of revolution of the cholesteric liquid crystalline phase can be adjusted by the type of liquid crystal compound forming the cholesteric liquid crystal layer and/or the type of chiral agent added.

In addition, a half-width Δλ (nm) of a selective reflection wavelength range where selective reflection is exhibited (circular polarization reflection wavelength range) depends on Δn of the cholesteric liquid crystalline phase and the helical pitch P, and complies with a relationship of Δλ=Δn×P. Therefore, the width of the selective reflection wavelength range can be controlled by adjusting Δn. An can be adjusted by the type of liquid crystal compound forming a cholesteric liquid crystal layer and mixing ratio thereof, and the temperature during immobilizing the alignment.

### [Cholesteric Liquid Crystal Layer]

As is well known, the cholesteric liquid crystal layer is a layer obtained by immobilizing a cholesteric liquid crystalline phase formed by helical cholesteric alignment of a liquid crystal compound. The cholesteric liquid crystal layer has a selective reflection center wavelength which is determined depending on a helical pitch of a cholesteric liquid crystalline phase, reflects light in a wavelength range including the selective reflection center wavelength, and allows transmission of light in the other wavelength ranges.

Here, a general cholesteric liquid crystal layer has no difference in refractive index in the plane, and has an in-plane retardation of approximately 0.

On the other hand, in the present invention, the cholesteric liquid crystal layer has a configuration in which the cholesteric liquid crystal layer has a region (phase difference region) where a refractive index nx in an in-plane slow axis direction and a refractive index ny in a fast axis direction satisfy nx>ny, so that the cholesteric liquid crystal layer exhibits frontal retardation (in-plane retardation). In addition, in the present invention, the cholesteric liquid crystal layer has a phase difference region where the phase difference increases from the center toward the outside, and the direction of the slow axis at one point in the phase difference region is orthogonal to the direction from the center to this one point.

Hereinafter, the cholesteric liquid crystal layer having a region satisfying nx>ny will be described.

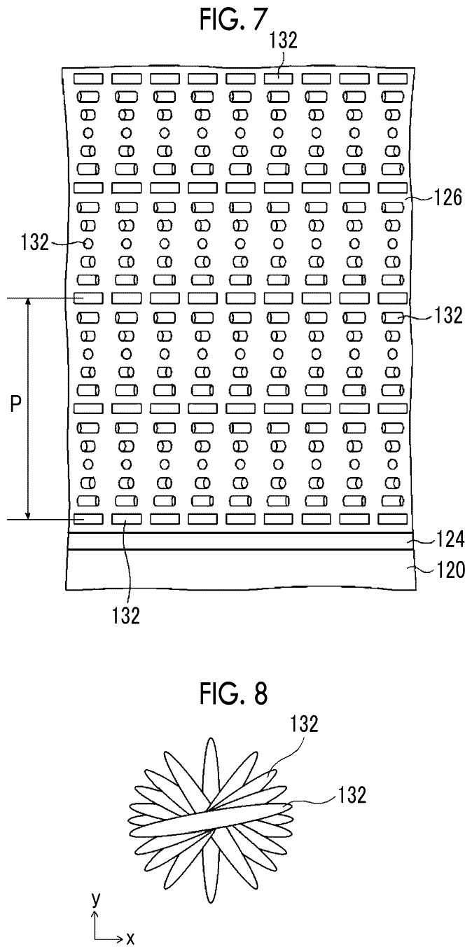

FIG. 7 conceptually shows an example of the cholesteric liquid crystal layer. A cholesteric liquid crystal layer 126 is formed on an alignment film 124 which is formed on a support 120.

In the following description, the support 120 side is also referred to as a lower side, and the cholesteric liquid crystal layer 126 side is also referred to as an upper side. Therefore, in the support 120, the cholesteric liquid crystal layer 126 side is referred to as an upper surface, and the opposite side is referred to as a lower surface. In addition, in the alignment film 124 and the cholesteric liquid crystal layer 126, the surface on the support 120 side is referred to as the lower surface, and the opposite side is referred to as the upper surface.

The support 120 supports the cholesteric liquid crystal layer 126 in a case where the cholesteric liquid crystal layer is formed. In a case where the support 120 is a temporary support, various temporary supports used in producing the cholesteric liquid crystal layer are exemplified. Examples of the temporary support include film-shaped members formed of glass, triacetyl cellulose (TAC), polyethylene terephthalate (PET), polycarbonates, polyvinyl chloride, acryl, polyolefin, and the like. In addition, the temporary support may be a multi-layer support including a plurality of layers formed of the above-described materials.

The alignment film 124 is formed on the surface (upper surface) of the support 120. The alignment film 124 is an alignment film for aligning liquid crystal compounds 132 in a predetermined alignment state in a case of forming the cholesteric liquid crystal layer 126.

As the alignment film 124, various known films can be used.

Examples of the alignment film include a rubbed film formed of an organic compound such as a polymer; an obliquely deposited film formed of an inorganic compound; a film having a microgroove; a film formed by lamination of Langmuir-Blodgett (LB) films formed with a Langmuir-Blodgett's method using an organic compound such as ω-tricosanoic acid, dioctadecylmethylammonium chloride, and methyl stearate; and a photo-alignment film obtained by irradiating a material having photo alignment with polarized light or non-polarized light.

The alignment film 124 may be formed by a known method according to the material used for forming the alignment film.

For example, the alignment film formed by a rubbing treatment can be formed by rubbing a surface of a polymer layer with paper or fabric in a given direction multiple times.

As the material used for the alignment film, a material for forming polyimide, polyvinyl alcohol, a polymer having a polymerizable group described in JP1997-152509A (JP-H9-152509A), or an alignment film and the like described in JP2005-97377A, JP2005-99228A, and JP2005-128503A is preferable.

In addition, the support 120 may be used as the alignment film by performing a treatment such as a rubbing treatment a laser processing on the support 120, without forming the alignment film 124.

As the alignment film 124, a so-called photo-alignment film obtained by irradiating a material having photo alignment with polarized light or non-polarized light is also suitably used. That is, a photo-alignment film which is formed by applying a photo-alignment material onto the support 120 is suitably used as the alignment film 124.

The irradiation of polarized light can be performed in a direction perpendicular or oblique to the photo-alignment film, and the irradiation of non-polarized light can be performed in a direction oblique to the photo-alignment film.

Preferable examples of the photo-alignment material used in the alignment film which can be used in the present invention include: an azo compound described in JP2006-285197A, JP2007-76839A, JP2007-138138A, JP2007-94071A, JP2007-121721A, JP2007-140465A, JP2007-156439A, JP2007-133184A, JP2009-109831A, JP3883848B, and JP4151746B; an aromatic ester compound described in JP2002-229039A; a maleimide- and/or alkenyl-substituted nadiimide compound having a photo-alignable unit described in JP2002-265541A and JP2002-317013A; a photocrosslinking silane derivative described in JP4205195B and JP4205198B, a photocrosslinking polyimide, a photocrosslinking polyamide, or a photocrosslinking polyester described in JP2003-520878A, JP2004-529220A, and JP4162850B; and a photodimerizable compound, in particular, a cinnamate compound, a chalcone compound, or a coumarin compound described in JP1997-118717A (JP-H9-118717A), JP1998-506420A (JP-H10-506420A), JP2003-505561A, WO2010/150748A, JP2013-177561A, and JP2014-12823A.

Among these, an azo compound, a photocrosslinking polyimide, a photocrosslinking polyamide, a photocrosslinking polyester, a cinnamate compound, or a chalcone compound is suitability used.

The thickness of the alignment film 124 is not particularly limited. The thickness with which a required alignment function can be obtained may be appropriately set depending on the material for forming the alignment film.

The thickness of the alignment film is preferably 0.01 to 5 μm and more preferably 0.05 to 2 μm.

The support and the alignment film may be a temporary support which is peeled off and removed. It is preferable that a temporary support is used from the viewpoint that, by transferring the cholesteric liquid crystal layer to another laminate and peeling and removing the temporary support, the adverse effect of the phase difference of the temporary support on the degree of polarization of transmitted light and reflected light can be eliminated.

The cholesteric liquid crystal layer 126 is formed on the surface (upper surface) of the alignment film 124.

In FIG. 7, the cholesteric liquid crystal layer 126 is conceptually shown only for two rotations (7200 rotation) of the twisted alignment of the liquid crystal compounds 132 in the cholesteric liquid crystalline phase, in order to clearly show the configuration of the cholesteric liquid crystal layer 126. That is, FIG. 7 shows only two pitches of the helical structure of the cholesteric liquid crystalline phase.

However, same as the general cholesteric liquid crystal layer obtained by immobilizing the cholesteric liquid crystalline phase, the cholesteric liquid crystal layer 126 has a helical structure in which the liquid crystal compounds 132 are stacked in a helical manner along a helical axis in the thickness direction, In the structure, a configuration in which the liquid crystal compound 132 is helically rotated once (rotated by 360°) and laminated is set as one helical pitch, and the helically turned liquid crystal compounds 132 are laminated one or more pitches.

That is, in the present invention, the cholesteric liquid crystalline phase (cholesteric liquid crystal layer) refers to a structure in which one or more pitches of the helical structures are laminated. The cholesteric liquid crystal layer exhibits the above-described reflective property with wavelength selectivity in a case where the helical structure formed by the liquid crystal compound 132 is laminated with one or more pitches.

Therefore, in the present invention, even in a case where the liquid crystal compounds 132 form a layer having a helical structure, which are stacked in a spiral shape while turning along a helical axis in the thickness direction, a layer with a helical period of less than 1 pitch is not the cholesteric liquid crystal layer.

The cholesteric liquid crystal layer 126 is formed by immobilizing a cholesteric liquid crystalline phase. That is, the cholesteric liquid crystal layer 126 is a layer in which the liquid crystal compound 132 (liquid crystal material) is cholesterically aligned. As is well known, the cholesteric liquid crystal layer formed by immobilizing the cholesteric liquid crystalline phase has wavelength-selective reflectivity. As described above, the selective reflection wavelength range of the cholesteric liquid crystal layer depends on the length in the thickness direction of the helix pitch described above (pitch P shown in FIG. 7).

Here, in the present invention, the cholesteric liquid crystal layer 126 has a region (phase difference region) where a refractive index nx in an in-plane slow axis direction and a refractive index ny in a fast axis direction satisfy nx>ny. In addition, in the present invention, the cholesteric liquid crystal layer has a phase difference region where the phase difference increases from the center toward the outside, and the direction of the slow axis at one point in the phase difference region is orthogonal to the direction from the center to this one point.

In the present invention, as shown in FIG. 8, the cholesteric liquid crystal layer 126 has a configuration in which angles formed by molecular axes of adjacent liquid crystal compounds 132 in a case where the arrangement of the liquid crystal compounds 132 is viewed from the helical axis direction gradually change. In other words, existence probability of the liquid crystal compound 132 is different in a case where the arrangement of the liquid crystal compounds 132 is viewed from the helical axis direction. As a result, the cholesteric liquid crystal layer 126 has a configuration in which the refractive index nx in the in-plane slow axis direction and the refractive index ny in the fast axis direction satisfy nx>ny.

In the following description, the cholesteric liquid crystal layer 126 having a configuration in which, as shown in FIG. 8, the angles formed by the molecular axes of the adjacent liquid crystal compounds 132 gradually change in a case where the arrangement of the liquid crystal compounds 132 is viewed from the helical axis direction is also referred to as having a refractive index ellipsoid.

In the cholesteric liquid crystal layer, the selective reflection center wavelength is not limited and may be appropriately set according to the application.

In the present invention, it is preferable that the cholesteric liquid crystal layer includes a blue light reflecting layer in which a reflectivity at a wavelength of at least 450 nm is 40% or more, a green light reflecting layer in which a reflectivity at a wavelength of 530 nm is 40% or more, and a red light reflecting layer in which a reflectivity at a wavelength of 630 nm is 40% or more. That is, in an optical laminate including a plurality of the cholesteric liquid crystal layers, the selective reflection center wavelengths of the respective cholesteric liquid crystal layers may be different from each other. With such a configuration, high reflection characteristics can be exhibited over a wide wavelength range in the visible region, which is preferable. The above-described reflectivity is a reflectivity in a case where non-polarized light is incident on the reflective type circular polarizer at each wavelength.

In an image display device, there are cases in which blue light, green light, and red light each have an emission peak in their respective wavelength ranges. For example, a liquid crystal display device having a backlight including quantum dots, a liquid crystal display device having a backlight provided with LEDs that emit blue light, green light, and red light, an organic EL display device, a micro LED display device, and the like have emission peaks with a full width at half maximum in the respective wavelength ranges of the blue light, green light, and red light. From the viewpoint of improving color reproducibility, it is preferable that the full width at half maximum of the emission peak of each color is narrow. In a case where the reflective type circular polarizer is used in combination with any of these image display devices, it is preferable that the reflective type circular polarizer (cholesteric liquid crystal layer) selectively has a reflection band in a wavelength range corresponding to the emission peak of the image display device.

In addition, the blue light reflecting layer, the green light reflecting layer, and the red light reflecting layer, which are formed by immobilizing the cholesteric liquid crystalline phase, may have a pitch gradient layer in which the helical pitch of the cholesteric liquid crystalline phase continuously changes in the thickness direction. For example, the green light reflecting layer and the red light reflecting layer can be continuously produced with reference to JP2020-060627A and the like.

In addition, in a case where the cholesteric liquid crystal layer (optical film including the cholesteric liquid crystal layer) according to the embodiment of the present invention is stretched or formed, the reflection wavelength range as the reflective type circular polarizer may shift to the short wavelength side, so that it is preferable that the reflection wavelength range is selected in advance in consideration of the shift in wavelength. For example, in a case where an optical film including a cholesteric liquid crystal layer formed by immobilizing a cholesteric liquid crystalline phase is used as the reflective type circular polarizer, the film extends by being stretched or formed and thus a helical pitch of the cholesteric liquid crystalline phase may be reduced. Therefore, it is preferable that the helical pitch of the cholesteric liquid crystalline phase is set to be large in advance. In addition, it is also preferable that the reflective type circular polarizer includes an infrared light reflecting layer having a reflectivity of 40% or more at a wavelength of 800 nm, in consideration of the short wavelength shift of the reflection wavelength range due to the stretching, the forming, or the like.

Furthermore, in a case where a stretching ratio during the stretching, the forming, or the like is not uniform in a plane, an appropriate reflection wavelength range may be selected at each location in the plane according to the wavelength shift caused by the stretching. That is, regions with different reflection wavelength ranges may be present in the plane. In addition, it is preferable that the reflection wavelength range is set wider than the required wavelength range in advance in consideration that the stretching ratios at the respective locations in the plane are different from each other.

In the present invention, in a case of an optical laminate including a plurality of cholesteric liquid crystal layers, it is preferable that the blue light reflecting layer, the green light reflecting layer, and the red light reflecting layer, which are the cholesteric liquid crystal layer, are laminated in this order. In addition, in a case of including a retardation layer in addition to the plurality of the cholesteric liquid crystal layers, it is preferable that the blue light reflecting layer is installed on the surface opposite to the surface of the retardation layer which converts circularly polarized light into linearly polarized light. In such an arrangement, a ray passes through the blue light reflecting layer, the green light reflecting layer, and the red light reflecting layer in this order. The present inventors assumed that the degree of polarization of the reflected light and the degree of polarization of the transmitted light can be increased because the degrees of polarization are unlikely to be affected by the Rth of each layer particularly in a case of oblique incidence with such arrangement.

It is also preferable that, in the optical laminate according to the second embodiment of the present invention, a first cholesteric liquid crystal layer formed of a rod-like liquid crystal compound and a second cholesteric liquid crystal layer formed of a disk-like liquid crystal compound are alternately laminated.

It is preferable that the first cholesteric liquid crystal layer is a light reflecting layer obtained by immobilizing a cholesteric liquid crystalline phase containing a rod-like liquid crystal compound, the second cholesteric liquid crystal layer is a light reflecting layer obtained by immobilizing a cholesteric liquid crystalline phase containing a disk-like liquid crystal compound, and the first cholesteric liquid crystal layer and the second cholesteric liquid crystal layer are alternately arranged. In such a configuration, since the cholesteric liquid crystalline phase containing a rod-like liquid crystal compound has a positive Rth and the cholesteric liquid crystalline phase containing a disk-like liquid crystal compound has a negative Rth, the Rth of each other is offset, and thus the degree of polarization of the reflected light and the transmitted light can be increased even for light incident from the oblique direction, which is preferable. In this case, the first cholesteric liquid crystal layer and the second cholesteric liquid crystal layer may have substantially the same selective reflection center wavelength, or may have different selective reflection center wavelengths. According to the studies of the present inventors, in this case, it is preferable that the blue light reflecting layer consisting of the cholesteric liquid crystalline phase containing a disk-like liquid crystal compound, the red light reflecting layer consisting of the cholesteric liquid crystalline phase containing a rod-like liquid crystal compound, and the green light reflecting layer consisting of the cholesteric liquid crystalline phase containing a rod-like liquid crystal compound are included in this order, and the blue light reflecting layer is disposed on the surface opposite to the retardation layer which converts circularly polarized light into linearly polarized light. In addition, from the viewpoint of visual sensitivity, the order of the reflecting layers is preferably green, red, and blue in this order from the display side.

In addition, from the viewpoint of compensation, it is preferable that the type of the liquid crystal is disk-like, rod-like, and disk-like, or disk-like, rod-like, and rod-like, from the display side.

The order of the reflecting layers (cholesteric liquid crystal layers) and the type of liquid crystal are merely examples, and the present invention is not limited to these configurations.

A thickness of the optically functional layer (cholesteric liquid crystal layer) may be appropriately set to a thickness at which a required reflectivity of light is obtained, depending on the forming material of the cholesteric liquid crystal layer, and the like; but from the viewpoint of thinning, the thickness is preferably 30 m or less and more preferably 20 m or less.

### [Method of Forming Cholesteric Liquid Crystal Layer]

The cholesteric liquid crystal layer can be formed by immobilizing a cholesteric liquid crystalline phase in a layer shape.

A structure in which the cholesteric liquid crystalline phase is immobilized may be any structure as long as the alignment of the liquid crystal compound in the cholesteric liquid crystalline phase is maintained, and typically, the structure is preferably a structure in which a polymerizable liquid crystal compound is brought into the alignment state of the cholesteric liquid crystalline phase and is polymerized and cured by ultraviolet irradiation, heating, and the like to form a layer without fluidity, and simultaneously, the layer changes to a state that an external field or an external force does not cause a change in alignment.

The structure in which the cholesteric liquid crystalline phase is immobilized is not particularly limited as long as the optical characteristics of the cholesteric liquid crystalline phase are maintained, and the liquid crystal compound in the cholesteric liquid crystal layer does not necessarily exhibit liquid crystallinity. For example, the polymerizable liquid crystal compound may lose its liquid crystal property by increasing its molecular weight by a curing reaction.

Examples of a material used for forming the cholesteric liquid crystal layer obtained by immobilizing the cholesteric liquid crystalline phase include a liquid crystal composition containing a liquid crystal compound. It is preferable that the liquid crystal compound is a polymerizable liquid crystal compound.

In addition, the liquid crystal composition used for forming the cholesteric liquid crystal layer may further contain a surfactant and a chiral agent.

The polymerizable liquid crystal compound may be a rod-like liquid crystal compound or a disk-like liquid crystal compound.

Examples of the rod-like polymerizable liquid crystal compound forming the cholesteric liquid crystalline phase include a rod-like nematic liquid crystal compound. As the rod-like nematic liquid crystal compound, azomethines, azoxys, cyano biphenyls, cyanophenyl esters, benzoic acid esters, cyclohexane carboxylic acid phenyl esters, cyanophenyl cyclohexanes, cyano-substituted phenyl pyrimidines, alkoxy-substituted phenyl pyrimidines, phenyl dioxanes, tolanes, alkenylcyclohexylbenzonitriles, and the like are preferably used. High-molecular-weight liquid crystal compounds can also be used as well as low-molecular-weight liquid crystal compounds.

The polymerizable liquid crystal compound is obtained by introducing a polymerizable group into the liquid crystal compound. Examples of the polymerizable group include an unsaturated polymerizable group, an epoxy group, and an aziridinyl group, and an unsaturated polymerizable group is preferable and an ethylenically unsaturated polymerizable group is more preferable. The polymerizable group can be introduced into the molecule of the liquid crystal compound by various methods. The number of polymerizable groups included in the polymerizable liquid crystal compound is preferably 1 to 6 and more preferably 1 to 3.

Examples of the polymerizable liquid crystal compound include compounds described in “Makromol. Chem., vol. 190, p. 2255 (1989), Advanced Materials, vol. 5, p. 107 (1993)”, U.S. Pat. No. 4,683,327A, 5,622,648A, 5,770,107A, WO1995/22586A, WO1995/24455A, WO1997/00600A, WO1998/23580A, WO1998/52905A, JP1989-272551A (JP-H1-272551A), JP1994-16616A (JP-H6-16616A), JP1995-110469A (JP-H7-110469A), JP1999-80081A (JP-H11-80081A), JP2001-328973A, and the like. Two or more kinds of polymerizable liquid crystal compounds may be used in combination. In a case where two or more kinds of polymerizable liquid crystal compounds are used in combination, an alignment temperature can be decreased.

In addition, as a polymerizable liquid crystal compound other than the above, a cyclic organopolysiloxane compound having a cholesteric liquid crystalline phase, as described in JP1982-165480A (JP-S57-165480A), or the like can be used. Furthermore, as the above-described high-molecular-weight liquid crystal compound, a polymer in which a mesogen group exhibiting liquid crystalline phase are introduced into the main chain, the side chain, or both main chain and side chain, a polymeric cholesteric liquid crystal in which a cholesteryl group is introduced into the side chain, a liquid crystalline polymer as described in JP1997-133810A (JP-H9-133810A), a liquid crystalline polymer as described in JP1999-293252A (JP-H11-293252A), and the like can be used.

As the disk-like liquid crystal compound, for example, compounds described in JP2007-108732A, JP2010-244038A, and the like can be preferably used.

In addition, an amount of the polymerizable liquid crystal compound added to the liquid crystal composition is preferably 75% to 99.9% by mass, more preferably 80% to 99% by mass, and still more preferably 85% to 90% by mass with respect to the mass of solid content of the liquid crystal composition (mass excluding a solvent).

### <<Surfactant>>

The liquid crystal composition used in forming the cholesteric liquid crystal layer may contain a surfactant.

The surfactant is preferably a compound which can function as an alignment control agent contributing to the alignment of the cholesteric liquid crystalline phase in a stable or rapid manner. Examples of the surfactant include a silicone-based surfactant and a fluorine-based surfactant, and preferred examples thereof include a fluorine-based surfactant.

Specific examples of the surfactant include compounds described in paragraphs [0082] to [0090] of JP2014-119605A, compounds described in paragraphs [0031] to [0034] of JP2012-203237A, compounds exemplified in paragraphs [0092] and [0093] of JP2005-99248A, compounds exemplified in paragraphs [0076] to [0078] and paragraphs [0082] of JP2002-129162A, and fluorine (meth)acrylate polymers described in paragraphs [0018] to [0043] and the like of JP2007-272185A.

The surfactant may be used alone or in combination of two or more kinds thereof.

As the fluorine-based surfactant, the compounds described in paragraphs [0082] to [0090] of JP2014-119605A are preferable.

An amount of the surfactant added to the liquid crystal composition is preferably 0.01% to 10% by mass, more preferably 0.01% to 5% by mass, and still more preferably 0.02% to 1% by mass with respect to the total mass of the liquid crystal compound.

### <<Chiral Agent (Optically Active Compound)>>

The chiral agent has a function of inducing the helical structure of the cholesteric liquid crystalline phase. The chiral agent may be selected according to the purpose because a helical twisted direction or a period of a helical pitch of the induced helix varies depending on the compound.

The chiral agent is not limited, and a known compound (for example, described in “Liquid Crystal Device Handbook”, Chapter 3, Section 4-3, chiral agent for twisted nematic (TN) and super-twisted nematic (STN), p. 199, Japan Society for the Promotion of Science edited by the 142nd committee, 1989), a derivative of isosorbide, isomannide, and the like can be used.

The chiral agent generally includes an asymmetric carbon atom, but an axially asymmetric compound or a planar asymmetric compound, including no asymmetric carbon atom, can also be used as the chiral agent. Examples of the axially asymmetric compound or the planar asymmetric compound include binaphthyl, helicene, paracyclophane, and derivatives thereof. The chiral agent may also have a polymerizable group. In a case where both the chiral agent and the liquid crystal compound have a polymerizable group, a polymer having a repeating unit induced from the polymerizable liquid crystal compound and a repeating unit induced from the chiral agent can be formed by a polymerization reaction between the polymerizable chiral agent and the polymerizable liquid crystal compound. In this aspect, the polymerizable group in the polymerizable chiral agent is preferably the same group as the polymerizable group in the polymerizable liquid crystal compound. Accordingly, the polymerizable group of the chiral agent is preferably an unsaturated polymerizable group, an epoxy group, or an aziridinyl group, more preferably an unsaturated polymerizable group, and still more preferably an ethylenically unsaturated polymerizable group.

In addition, the chiral agent may be a liquid crystal compound.

In a case where the chiral agent has a photoisomerization group, a pattern having a desired reflection wavelength corresponding to a luminescence wavelength can be formed by irradiation with actinic ray or the like through a photo mask after coating and alignment, which is preferable. As the photoisomerization group, an isomerization site of a compound exhibiting photochromic properties, an azo group, an azoxy group, or a cinnamoyl group is preferable. Specific examples of the compound include compounds described in JP2002-80478A, JP2002-80851A, JP2002-179668A, JP2002-179669A, JP2002-179670A, JP2002-179681A, JP2002-179682A, JP2002-338575A, JP2002-338668A, JP2003-313189A, JP2003-313292A, and the like.

A content of the chiral agent in the liquid crystal composition is preferably 0.01 to 200 mol % and more preferably 1 to 30 mol % with respect to the contained molar amount of the liquid crystal compound.

### <<Polymerization Initiator>>

In a case where the liquid crystal composition contains a polymerizable compound, it is preferable that the liquid crystal composition contains a polymerization initiator. In an aspect in which the polymerization reaction proceeds by ultraviolet irradiation, the polymerization initiator to be used is preferably a photopolymerization initiator capable of initiating the polymerization reaction by ultraviolet irradiation.

Examples of the photopolymerization initiator include α-carbonyl compounds (described in U.S. Pat. Nos. 2,367,661A and 2,367,670A), acyloin ether (described in U.S. Pat. No. 2,448,828A), α-hydrocarbon-substituted aromatic acyloin compounds (described in U.S. Pat. No. 2,722,512A), polynuclear quinone compounds (described in U.S. Pat. Nos. 3,046,127A and 2,951,758A), combinations of triarylimidazole dimer and p-aminophenyl ketone (described in U.S. Pat. No. 3,549,367A), acridine compounds and phenazine compounds (described in JP1985-105667A (JP-S60-105667A) and U.S. Pat. No. 4,239,850A), and oxadiazole compounds (described in U.S. Pat. No. 4,212,970A).

In particular, it is preferable that the polymerization initiator is a dichroic radical polymerization initiator.

The dichroic radical polymerization initiator refers to, among photopolymerization initiators, a polymerization initiator which has absorption selectivity with respect to light in a specific polarization direction, and is excited by the polarized light to generate a free radical. That is, the dichroic radical polymerization initiator refers to a polymerization initiator having different absorption selectivities between light in a specific polarization direction and light in a polarization direction perpendicular to the light in the specific polarization direction.

The details and specific examples thereof are described in WO2003/054111A.

Specific examples of the dichroic radical polymerization initiator include a polymerization initiator represented by the following chemical formula. In addition, as the dichroic radical polymerization initiator, polymerization initiators described in paragraphs [0046] to [0097] of JP2016-535863A can be used.

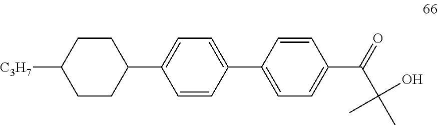

A content of the photopolymerization initiator in the liquid crystal composition is preferably 0.1% to 20% by mass, and more preferably 0.5% to 12% by mass with respect to the content of the liquid crystal compound.

### <<Crosslinking Agent>>

The liquid crystal composition may optionally contain a crosslinking agent in order to improve film hardness and durability after curing. As the crosslinking agent, a crosslinking agent which cures the liquid crystal composition with ultraviolet rays, heat, humidity, and the like can be suitably used.

The crosslinking agent is not particularly limited and can be appropriately selected according to the purpose, and examples thereof include polyfunctional acrylate compounds such as trimethylolpropane tri(meth)acrylate and pentaerythritol tri(meth)acrylate; epoxy compounds such as glycidyl (meth)acrylate and ethylene glycol diglycidyl ether; aziridine compounds such as 2,2-bishydroxymethylbutanol-tris[3-(1-aziridinyl)propionate] and 4,4-bis(ethyleneiminocarbonylamino); isocyanate compounds such as hexamethylene diisocyanate and biuret-type isocyanate; polyoxazoline compounds having an oxazoline group in the side chain; and alkoxysilane compounds such as vinyltrimethoxysilane and N-(2-aminoethyl) 3-aminopropyltrimethoxysilane. In addition, a known catalyst can be used depending on reactivity of the crosslinking agent, and in addition to improving the film hardness and durability, productivity can be improved. These may be used alone or in combination of two or more kinds thereof.

A content of the crosslinking agent is preferably 3% to 20% by mass, and more preferably 5% to 15% by mass with respect to the mass of solid content of the liquid crystal composition. In a case where the content of the crosslinking agent is within the above-described range, an effect of improving crosslinking density can be easily obtained, and stability of the cholesteric liquid crystalline phase is further improved.

### <<Other Additives>>

As necessary, a polymerization inhibitor, an antioxidant, an ultraviolet absorber, a light stabilizer, a coloring material, metal oxide fine particles, and the like can be further added to the liquid crystal composition as long as the optical performance or the like is not degraded.

The liquid crystal composition is preferably used as a liquid in forming the cholesteric liquid crystal layer. The liquid crystal composition may contain a solvent. The solvent is not limited and can be appropriately selected according to the purpose, but an organic solvent is preferable.

The organic solvent is not limited and may be appropriately selected according to the purpose, and examples thereof include ketones, alkyl halides, amides, sulfoxides, heterocyclic compounds, hydrocarbons, esters, and ethers. These may be used alone or in combination of two or more kinds thereof. Among these, in consideration of environmental load, ketones are preferable.

In a case of forming the cholesteric liquid crystal layer, it is preferable that the cholesteric liquid crystal layer is formed by applying the liquid crystal composition to a surface where the cholesteric liquid crystal layer is to be formed, aligning the liquid crystal compound to a state of the cholesteric liquid crystalline phase, and then curing the liquid crystal compound.

For example, in a case where the cholesteric liquid crystal layer 126 is formed on the alignment film 124, it is preferable that the liquid crystal composition is applied onto the alignment film 124, the liquid crystal compound is aligned in a state of the cholesteric liquid crystalline phase, and then the liquid crystal compound is cured to form the cholesteric liquid crystal layer 126 in which the cholesteric liquid crystalline phase is immobilized. For the application of the liquid crystal composition, any known method capable of uniformly applying a liquid onto a sheet-like material, such as printing methods such as ink jet and scroll printing, spin coating, bar coating, and spray coating, can be used.

The applied liquid crystal composition is dried and/or heated as necessary, and then is cured to form the cholesteric liquid crystal layer. In the drying and/or heating step, the liquid crystal compound in the liquid crystal composition may be aligned to the cholesteric liquid crystalline phase. In a case of heating, a heating temperature is preferably 200° C. or lower and more preferably 130° C. or lower.

The aligned liquid crystal compound is further polymerized as necessary. The polymerization may be either thermal polymerization or photopolymerization by light irradiation, but photopolymerization is preferable. It is preferable to use ultraviolet rays for the light irradiation. An irradiation energy is preferably 20 mJ/cm² to 50 J/cm² and more preferably 50 to 1,500 mJ/cm². In order to promote the photopolymerization reaction, the light irradiation may be performed under heating conditions or in a nitrogen atmosphere. A wavelength of the ultraviolet rays to be emitted is preferably 250 to 430 nm.

### (Liquid Crystal Elastomer)

In the present invention, a liquid crystal elastomer may be used for the cholesteric liquid crystal layer. The liquid crystal elastomer is a hybrid material of liquid crystal and an elastomer. For example, the liquid crystal elastomer has a structure in which a rigid mesogenic group having liquid crystallinity is introduced into a flexible polymer network having rubber elasticity. Therefore, the liquid crystal elastomer has flexible mechanical characteristics and elasticity. In addition, the alignment state of the liquid crystal and the macroscopic shape of the system strongly correlate to each other, and in a case where the alignment state of the liquid crystal changes depending on a temperature, an electric field, or the like, macroscopic deformation corresponding to a change in alignment degree occurs. For example, in a case where the liquid crystal elastomer is heated up to a temperature at which a nematic phase is transformed into an isotropic phase of random alignment, a sample contracts in a director direction, and the contraction amount thereof increases along with a temperature increase, that is, the alignment degree of liquid crystal decreases. The deformation is thermoreversible, and the liquid crystal elastomer returns to its original shape in a case where it is cooled to the temperature of the nematic phase again. On the other hand, in a case where the liquid crystal elastomer of the cholesteric liquid crystalline phase is heated such that the alignment degree of liquid crystal decreases, the macroscopic elongational deformation of the helical axis direction occurs. Therefore, the helical pitch length increases, and the reflection center wavelength of the selective reflection peak is shifted to the long wavelength side. This change is also thermoreversible, and as the liquid crystal elastomer is cooled, the reflection center wavelength returns to the short wavelength side.

### <<Refractive Index Ellipsoid of Cholesteric Liquid Crystal Layer>>

As described above, the cholesteric liquid crystal layer 126 has a refractive index ellipsoid with a configuration in which the angles formed by the molecular axes of adjacent liquid crystal compounds 132 gradually change in a case where the arrangement of the liquid crystal compounds 132 is viewed from the helical axis direction.

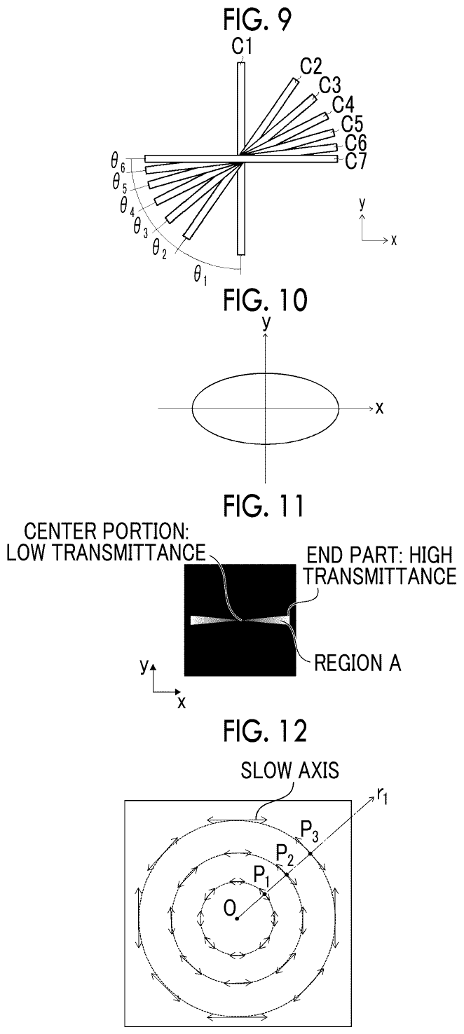

The refractive index ellipsoid will be described with reference to FIGS. 9 and 10.

FIG. 9 is a view showing a part (¼ pitch portion) of a plurality of liquid crystal compounds which are twistedly aligned along a helical axis in case of being viewed from a helical axis direction (z direction), and FIG. 10 is a view conceptually showing an existence probability of the liquid crystal compound viewed from the helical axis direction. FIG. 9 is an example in which the liquid crystal compound is a rod-like liquid crystal compound, and a major axis of the rod-like liquid crystal compound is the molecular axis. In a case where the liquid crystal compound is a disk-like liquid crystal compound, a disk plane direction of the disk-like liquid crystal compound in a case of being viewed from the helical axis direction is the molecular axis.

In FIG. 9, a liquid crystal compound having a molecular axis parallel to the y direction is represented by C1; a liquid crystal compound having a molecular axis parallel to the x direction is represented by C7; and liquid crystal compounds between C1 and C7 are represented by C2 to C6 in order from the liquid crystal compound C1 side to the liquid crystal compound C7 side. The liquid crystal compounds C1 to C7 are twistedly aligned along the helical axis, and the liquid crystal compound rotates by 90° from the liquid crystal compound C1 to the liquid crystal compound C7. In a case where a length between the liquid crystal compounds over which the angle of the liquid crystal compound which is twistedly aligned changes by 360° is set as one pitch (“P” in FIG. 7), a length in the helical axis direction (direction perpendicular to the paper plane in FIG. 9) between the liquid crystal compound C1 and the liquid crystal compound C7 is set as ¼ pitch.

As shown in FIG. 9, in the ¼ pitch from the liquid crystal compound C1 to the liquid crystal compound C7, the angles between the molecular axes of the adjacent liquid crystal compounds in case of being viewed from the z direction (helical axis direction) vary. In the example shown in FIG. 9, an angle θ₁ between the liquid crystal compound C1 and the liquid crystal compound C2 is larger than an angle θ₂ between the liquid crystal compound C2 and the liquid crystal compound C3; the angle θ₂ between the liquid crystal compound C2 and the liquid crystal compound C3 is larger than an angle θ₃ between the liquid crystal compound C3 and the liquid crystal compound C4; the angle θ₃ between the liquid crystal compound C3 and the liquid crystal compound C4 is larger than an angle θ₄ between the liquid crystal compound C4 and the liquid crystal compound C5; the angle θ₄ between the liquid crystal compound C4 and the liquid crystal compound C5 is larger than an angle θ₅ between the liquid crystal compound C5 and the liquid crystal compound C6; the angle θ₅ between the liquid crystal compound C5 and the liquid crystal compound C6 is larger than an angle θ₆ between the liquid crystal compound C6 and the liquid crystal compound C7; and the angle θ₆ between the liquid crystal compound C6 and the liquid crystal compound C7 is the smallest.

That is, the liquid crystal compounds C1 to C7 are twistedly aligned such that the angles between the molecular axes of the adjacent liquid crystal compounds decrease in order from the liquid crystal compound C1 side toward the liquid crystal compound C7 side. For example, in a case where the interval between the liquid crystal compounds (the interval in the thickness direction) is substantially regular, the rotation angle per unit length decreases in order from the liquid crystal compound C1 side to the liquid crystal compound C7 side, in the ¼ pitch from the liquid crystal compound C1 to the liquid crystal compound C7.

In the cholesteric liquid crystal layer 126, the configuration in which the rotation angle per unit length changes as described above in the ¼ pitch is repeated such that the liquid crystal compound is twistedly aligned.

Here, in a case where the rotation angle per unit length is constant, the angles between the molecular axes of the adjacent liquid crystal compounds are constant. Therefore, the existence probability of the liquid crystal compound in case of being viewed from the helical axis direction is the same in any direction, and in this case, the cholesteric liquid crystal layer does not have anisotropy in the in-plane direction (is isotropic).

On the other hand, as described above, with the rotation angle per unit length decreases in order from the liquid crystal compound C1 side to the liquid crystal compound C7 side in the ¼ pitch from the liquid crystal compound C1 to the liquid crystal compound C7, the existence probability of the liquid crystal compound in case of being viewed from the helical axis direction in the x direction is higher than that in the y direction, as conceptually shown in FIG. 10. By making the existence probability of the liquid crystal compound to vary between the x direction and the y direction, the refractive index varies between the x direction and the y direction such that refractive index anisotropy occurs. In other words, refractive index anisotropy in a plane perpendicular to the helical axis occurs.

The refractive index nx in the x direction, in which the existence probability of the liquid crystal compound is high, is higher than the refractive index ny in the y direction, in which the existence probability of the liquid crystal compound is low. Accordingly, the refractive index nx and the refractive index ny satisfy nx>ny.

The x direction in which the existence probability of the liquid crystal compound is high is the in-plane slow axis direction of the cholesteric liquid crystal layer 126, and the y direction in which the existence probability of the liquid crystal compound is low is the in-plane fast axis direction of the cholesteric liquid crystal layer 126.

In this way, the configuration in which the rotation angle per unit length in the ¼ pitch change in the twisted alignment of the liquid crystal compound (the configuration having the refractive index ellipsoid) can be formed by applying a composition for forming the cholesteric liquid crystal layer and irradiating the cholesteric liquid crystalline phase (composition layer) with polarized light in a direction perpendicular to the helical axis.

The cholesteric liquid crystalline phase can be distorted by polarized light irradiation to cause in-plane retardation to occur. That is, the refractive index nx>refractive index ny can be satisfied.

Specifically, the polymerization of the liquid crystal compound having a molecular axis in a direction which matches a polarization direction of irradiated polarized light progresses. At this time, since only a part of the liquid crystal compound is polymerized, a chiral agent present at this position is excluded and moves to another position.

Accordingly, at a position where the direction of the molecular axis of the liquid crystal compound is close to the polarization direction, the amount of the chiral agent decreases, and the rotation angle of the twisted alignment decreases. On the other hand, at a position where the direction of the molecular axis of the liquid crystal compound is perpendicular to the polarization direction, the amount of the chiral agent increases, and the rotation angle of the twisted alignment increases.

As a result, as shown in FIG. 9, the liquid crystal compound which is twistedly aligned along the helical axis can be configured such that, in the ¼ pitch from the liquid crystal compound having the molecular axis parallel to the polarization direction to the liquid crystal compound having the molecular axis perpendicular to the polarization direction, the angles between the molecular axes of the adjacent liquid crystal compounds adjacent decrease in order from the liquid crystal compound side parallel to the polarization direction to the liquid crystal compound side perpendicular to the polarization direction. That is, by irradiating the cholesteric liquid crystalline phase with polarized light, the existence probability of the liquid crystal compound varies between the x direction and the y direction, the refractive index varies between the x direction and the y direction such that the refractive index anisotropy occurs. As a result, the refractive index nx and the refractive index ny of the cholesteric liquid crystal layer 126 can satisfy nx>ny. That is, the cholesteric liquid crystal layer can adopt the configuration having the refractive index ellipsoid.

The polarized light irradiation may be performed at the same time as the immobilization of the cholesteric liquid crystalline phase, the immobilization may be further performed by non-polarized light irradiation after the polarized light irradiation, and photo alignment may be performed by polarized light irradiation after performing the immobilization by non-polarized light irradiation. In order to obtain high retardation, it is preferable that only polarized light irradiation is performed or polarized light irradiation is performed in advance. It is preferable to perform the polarized light irradiation in an inert gas atmosphere in which an oxygen concentration is 0.5% or less. An irradiation energy is preferably 20 mJ/cm² to 10 J/cm² and more preferably 100 to 800 mJ/cm². An illuminance is preferably 20 to 1,000 mW/cm², more preferably 50 to 500 mW/cm², and still more preferably 100 to 350 mW/cm². The type of the liquid crystal compound to be cured by the polarized light irradiation is not particularly limited, and a liquid crystal compound having an ethylenically unsaturated group as a reactive group is preferable.

In addition, examples of a method of distorting the cholesteric liquid crystalline phase by polarized light irradiation to cause in-plane retardation to occur include a method using a dichroic liquid crystalline polymerization initiator (WO2003/054111A1) and a method using a rod-like liquid crystal compound having a photo-alignable functional group such as a cinnamoyl group in the molecule (JP2002-6138A).

The light to be emitted may be ultraviolet rays, visible light, or infrared rays. That is, the light with which the liquid crystal compound is polymerizable may be appropriately selected depending on the liquid crystal compound, the polymerization initiator, or the like contained in the coating film.

In a case where the composition layer is irradiated with polarized light using the dichroic radical polymerization initiator as the polymerization initiator, the polymerization of the liquid crystal compound having a molecular axis in a direction which matches the polarization direction can be more suitably made to progress.

The in-plane slow axis direction, the in-plane fast axis direction, the refractive index nx, and the refractive index ny can be measured using M-2000 UI manufactured by J. A. Woollam Co., Ltd. as a spectroscopic ellipsometer. The refractive index nx and the refractive index ny can be obtained from a measured value of a phase difference Δn×d, using measured values of an average birefringence nₐᵥₑ and a thickness d. Here, Δn=nx−ny and the average refractive index nₐᵥₑ=(nx+ny)/2. In general, since the average refractive index of liquid crystal is approximately 1.5, nx and ny can be obtained using this value. In addition, in a case of measuring the in-plane slow axis direction, the fast axis direction, the refractive index nx, and the refractive index ny of the cholesteric liquid crystal layer used in the present invention, a measurement wavelength is determined to be a wavelength obtained by subtracting 20 nm from a half-value wavelength on the side shorter than the selective reflection center wavelength in the cholesteric liquid crystal layer. As a result, the influence of retardation derived from the cholesteric selective reflection on a rotary polarization component is reduced as far as possible, so that the measurement can be performed with high accuracy.

In addition, the cholesteric liquid crystal layer having the refractive index ellipsoid can be formed by stretching the cholesteric liquid crystal layer after applying the composition for forming the cholesteric liquid crystal layer, and after immobilizing the cholesteric liquid crystalline phase or in a state in which the cholesteric liquid crystalline phase is semi-immobilized.

Here, in the second embodiment of the present invention, it is preferable that the slow axis of the cholesteric liquid crystal layer having the refractive index ellipsoid has a plurality of in-plane orientations, and it is preferable to change the orientation according to the application. For example, in a case where the material is formed on a curved surface such as a part of a sphere, it is preferable that the material is substantially disposed in a concentric circle to cancel out the phase difference due to stretching during the forming. In addition, it is preferable that the retardation after the forming is less than 10 nm.

Specifically, the cholesteric liquid crystal layer has a phase difference region in which a phase difference increases from a center toward outside, and in the phase difference region, a direction of a slow axis at one point in the phase difference region and a direction from the center to the one point are orthogonal to each other. The cholesteric liquid crystal layer having such a configuration will be described with reference to FIG. 12.

FIG. 12 is a view conceptually showing the slow axis of the cholesteric liquid crystal layer according to the embodiment of the present invention.

In FIG. 12, the direction of the slow axis in a minute region in the plane of the cholesteric liquid crystal layer is indicated by an arrow, and the magnitude of the phase difference in the region is indicated by the length of the arrow.

In FIG. 12, the phase difference is approximately 0 at a center O. In addition, for example, on a line indicated by an one-dot chain line r₁ extending from the center O toward the outside, directions of slow axes at positions (minute regions) of a point P₁, a point P₂, and a point P₃ are all substantially orthogonal to the one-dot chain line r₁. In addition, the magnitude of the phase difference at the position of the point P₂ is larger than the magnitude of the phase difference at the position of the point P₁; and the magnitude of the phase difference at the position of the point P₃ is larger than the magnitude of the phase difference at the position of the point P₂. That is, as the distance from the center O to the outside is farther, the phase difference is larger.

As shown in FIG. 12, in the cholesteric liquid crystal layer, the phase difference increases from the center O toward the outside in any direction, and the direction of the slow axis at a certain point is substantially orthogonal to a line segment connecting the certain point and the center O. In other words, the direction of the slow axis is substantially orthogonal to a radial direction. In this way, in the cholesteric liquid crystal layer, the direction of the slow axis and the magnitude of the phase difference for each minute region in the plane are different depending on the in-plane position.

In addition, as shown in FIG. 12, the magnitudes of the phase differences are substantially the same at the positions where the distances from the center O are the same.

In the cholesteric liquid crystal layer shown in FIG. 12, in a case where a tangent line which is in contact with all arrows representing the slow axis in the region where the magnitude of the phase difference is the same is drawn, a circle with the center O is depicted as shown by a broken line in FIG. 12. Circles with different diameters are drawn for each magnitude of the phase difference, and a plurality of circles share the center O as concentric circles. In the following description, the pattern of the slow axis as shown in FIG. 12 is also referred to as a concentric circular pattern.

In the cholesteric liquid crystal layer according to the second embodiment of the present invention, since the slow axis has the concentric circular pattern, for example, in a case where the cholesteric liquid crystal layer is formed on a curved surface such as a part of a sphere, the phase difference due to stretching during the forming can be canceled.

Specifically, in a case of the cholesteric liquid crystal layer in the related art, the angle formed by the molecular axes of the adjacent liquid crystal compounds as viewed from the helical axis direction is substantially constant, that is, the rotation angle per unit length is constant. Therefore, the cholesteric liquid crystal layer in the related art is an isotropic material having no refractive index anisotropy (phase difference) at any in-plane position (minute region).

In a case where the cholesteric liquid crystal layer in the related art is formed on, for example, a curved surface such as a part of a sphere, the anisotropy does not occur because a region close to the center in a plan view is stretched at a constant stretching ratio, regardless of the direction. However, in a region close to the end part of the region to be formed, the region is stretched at different stretching ratios in the circumferential direction and the radial direction. Therefore, a bias in the existence probability of the liquid crystal compound occurs in the circumferential direction and the radial direction, and thus an anisotropy (phase difference) of the refractive index occurs. Specifically, in a region closer to the end part, the stretching ratio in the circumferential direction is smaller, and the stretching ratio in the radial direction is higher, and as a result, the existence probability of the liquid crystal compound in the radial direction is higher, and the liquid crystal compound has the slow axis in the radial direction (see FIG. 6). As described above, in a case where the cholesteric liquid crystal layer in the related art is formed on a curved surface such as a part of a sphere, the magnitude of the phase difference to be generated varies depending on the in-plane position. Therefore, in a case where the formed cholesteric liquid crystal layer is used as a reflective type circular polarizer constituting a pancake lens of a virtual reality display apparatus, incidence ray cannot be appropriately reflected and transmitted, resulting in increased light leakage. In the virtual reality display apparatus, the leaked light is visually recognized as ghost.

On the other hand, in the cholesteric liquid crystal layer according to the second embodiment of the present invention, the phase difference increases toward the outside, the direction of the slow axis is substantially orthogonal to the radial direction, and the cholesteric liquid crystal layer has a concentric circular pattern. Therefore, for example, in a case where the optical film is formed on a curved surface such as a part of a sphere, in a plan view, a region close to the center is stretched at a constant stretching ratio regardless of the direction, so that no anisotropy occurs and the phase difference is substantially 0. On the other hand, in a region close to the end part of the region to be formed, the liquid crystal compound is stretched at a small stretching ratio in the circumferential direction and at a high stretching ratio in the radial direction. However, since the region close to the end part has a direction of the slow axis which is substantially orthogonal to the radial direction, that is, the existence probability of the liquid crystal compound in the direction (circumferential direction) substantially orthogonal to the radial direction is high, the difference in existence probability of the liquid crystal compound between the radial direction and the circumferential direction is small in a case where the liquid crystal compound is stretched in the radial direction. As a result, the anisotropy (phase difference) of the refractive index in the region close to the end part is reduced. In this way, by applying the concentric pattern in which the phase difference is larger toward the outside of the cholesteric liquid crystal layer and the direction of the slow axis is substantially orthogonal to the radial direction, depending on the circumferential direction and the radial direction of the magnitude of the stretching ratio for each position in a case of being formed, the phase difference in each region in the plane after the forming can be reduced (substantially 0). Therefore, in a case where the cholesteric liquid crystal layer according to the embodiment of the present invention is formed and used as a reflective type circular polarizer constituting a pancake lens of a virtual reality display apparatus, incidence ray can be appropriately reflected and transmitted, and leakage light can be reduced. As a result, it is possible to prevent ghost from being seen in the virtual reality display apparatus.

A method of forming the cholesteric liquid crystal layer having a concentric circular pattern, in which the phase difference is larger toward the outside and the direction of the slow axis is substantially orthogonal to the radial direction, will be described.

As described above, the cholesteric liquid crystal layer having a phase difference can be formed by applying a composition for forming the cholesteric liquid crystal layer and then irradiating the cholesteric liquid crystalline phase (composition layer) with polarized light. In this case, since the existence probability of the liquid crystal compound is higher in the direction of the polarization and the refractive index ellipsoid is formed in the direction of the slow axis, the polarized light is emitted in a direction where the phase difference is larger toward the outside and the direction of the slow axis is substantially orthogonal to the radial direction, resulting in formation of the concentric circular pattern.

In order for the slow axis of the cholesteric liquid crystal layer having the refractive index ellipsoid to have a plurality of in-plane orientations, a known polarization exposure method can be used. As a specific example of the method, the cholesteric liquid crystal layer can be produced by a method described in JP2008-233903A.

Examples thereof include a method of irradiating the cholesteric liquid crystalline phase (composition layer) with polarized light while rotating the cholesteric liquid crystalline phase (composition layer) using a mask as shown in FIG. 11.

In the mask shown in FIG. 11, a transmission portion with a triangular shape is formed to be elongated toward the end part such that the top portion substantially matches the center. In addition, the light transmittance (transmittance of light having a wavelength used for exposure) in the transmission portion is low on the center side and high toward the end part. By irradiating the cholesteric liquid crystalline phase (composition layer) with polarized light in a direction orthogonal to the radial direction through the mask and rotating the cholesteric liquid crystalline phase (composition layer) around the top of the transmission portion with a triangular shape, it is possible to form the concentric circular pattern in which the phase difference is larger toward the outside and the direction of the slow axis is substantially orthogonal to the radial direction.

### <Optical Laminate>

The optical laminate according to the second embodiment of the present invention includes, for example, the above-described optically functional layer (cholesteric liquid crystal layer) and a substrate film. In addition, the optically functional layer may include a plurality of laminated layers. Examples of the substrate film include polyacrylate and polymethacrylate.

### <Optical Component>

The optical component according to the second embodiment of the present invention is a formed product (curved-shaped optically functional layer) obtained by forming the above-described cholesteric liquid crystal layer. In a case where the optical component is used in a pancake lens-type virtual reality display apparatus, the optical component can be designed to have an appropriate shape with a curved surface, so that a wide field of view, low chromatic aberration, low distortion, and excellent MTF can be obtained.

The shape of the formed product can be various shapes such as a part of a sphere, a paraboloid, and an aspherical lens shape. In addition, the shape of the formed product may conform to the shape of the lens to be laminated.

Specifically, the formed product obtained by forming the cholesteric liquid crystal layer (optical laminate including the cholesteric liquid crystal layer) according to the second embodiment of the present invention can have the same configuration as the first aspect of the optical film according to the first embodiment of the present invention described above. That is, the formed product has a curved shape of a non-developable surface in which a Gaussian curvature is positive. As such a curved shape, various curved shapes having a non-developable surface in which the Gaussian curvature is positive can be used, such as a spherical surface, a parabolic surface, an elliptical surface, an aspherical surface in which curvature changes from the center toward the outer side, and an asymmetric curved surface with respect to the center, for example, a lens having a circular shape, and a curved surface asymmetric with respect to the optical axis in the diameter direction.

In addition, in the formed product having such a curved shape, an outer peripheral shape (shape of an outer peripheral end), that is, a planar shape is not limited, and various shapes such as an elliptical shape, a non-elliptical oblong shape, a polygonal shape, and an amorphous shape can be used. Among these, an elliptical shape is preferable. In the present invention, the “elliptical” includes “circular”.

The planar shape refers to a shape in a case where the formed product is viewed from a normal direction of a top (bottom) of the curved surface. For example, in a case where the formed product having a curved shape is a lens, the planar shape is a shape in a case of being viewed from an optical axis direction.

In the formed product obtained by forming the cholesteric liquid crystal layer (optical laminate including the cholesteric liquid crystal layer) according to the second embodiment of the present invention, as in the first aspect of the optical film according to the first embodiment of the present invention, in a case where a wavelength obtained by subtracting 20 nm from a half-value wavelength on a side shorter than a selective reflection center wavelength in the cholesteric liquid crystal layer is defined as an evaluation wavelength (measurement wavelength), an in-plane retardation A at the evaluation wavelength in a center can be less than 2% of the evaluation wavelength, and an in-plane retardation B at the evaluation wavelength in an outer edge portion can be less than 2% of the evaluation wavelength.

A production method of the formed product (curved-shaped optically functional layer) includes a cholesteric liquid crystal layer-producing step of producing the above-described cholesteric liquid crystal layer, and a forming step of forming the cholesteric liquid crystal layer into a curved shape to cancel out a phase difference of the cholesteric liquid crystal layer. In addition, in the forming step, it is preferable that the cholesteric liquid crystal layer is installed on a forming die having a concave surface-forming surface such that a bottom portion of the concave surface-forming surface and a center of the cholesteric liquid crystal layer (center of the phase difference region) coincide with each other, and the cholesteric liquid crystal layer is deformed along the concave surface-forming surface.

A forming method using a forming die with such a concave surface-forming surface can utilize known methods in the related art, such as vacuum forming.

### <Virtual Reality Display Apparatus>

A virtual reality display apparatus according to the second embodiment of the present invention includes at least an image display device which emits polarized light, and the optical component (formed product) according to the second embodiment of the present invention described above. In addition, the virtual reality display apparatus according to the second embodiment of the present invention may include an additional optical member such as a half mirror and a visual acuity adjustment lens.

As the image display device which emits polarized light, a known image display device can be used. Examples thereof include a display device in which self-luminous microscopic light emitters are arranged on a transparent substrate, such as an organic electroluminescent display device, a light emitting diode (LED) display device, and a micro LED display device. In these self-luminous display devices, a (circular) polarizing plate is usually bonded to a display surface to prevent reflection on the display surface. Therefore, the emitted light is polarized. In addition, a liquid crystal display device is exemplified as other image display devices. Since the liquid crystal display device also has a polarizing plate on the surface, the emitted light is polarized. In the following description, the organic electroluminescent display device will also be referred to as “OLED”. OLED is an abbreviation for “Organic Light Emitting Diode”.

Specifically, the virtual reality display apparatus according to the second embodiment of the present invention can have the same configuration as the virtual reality display apparatus according to the first embodiment shown in FIG. 1, except that the formed product obtained by forming the cholesteric liquid crystal layer (including the optical laminate) according to the second embodiment of the present invention is used as the optical laminate 100.

### EXAMPLES

Hereinafter, the features of the present invention will be described in more detail with reference to Examples. The materials, the used amounts, the proportions, the treatment contents, the treatment procedures, and the like described in Examples can be appropriately changed without departing from the gist of the present invention. In addition, configurations other than the configurations described below can be employed without departing from the gist of the present invention.

### Examples of First Embodiment

### [Production of Coating Liquids R-1 to R-6 for Reflecting Layer]

A composition shown below was stirred and dissolved in a container kept at 70° C. to prepare each of coating liquids R-1 to R-6 for a reflecting layer. Here, R represents a coating liquid containing a rod-like liquid crystal compound.

Coating liquid for reflecting layer (containing
rod-like liquid crystal compound)

| Methyl ethyl ketone | 120.9 | parts by mass |
|---|---|---|
| Cyclohexanone | 21.3 | parts by mass |
| Mixture of rod-like liquid crystal | 100.0 | parts by mass |
| compounds shown below | | |
| Photopolymerization initiator b | 1.00 | parts by mass |
| Chiral agent A shown below | amount described in Table 1 | |
| Surfactant F1 shown below | 0.027 | parts by mass |
| Surfactant F2 shown below | 0.067 | parts by mass |

### Amount of Chiral Agent of Coating Liquids (R-1 to R6) Containing Rod-Like Liquid Crystal Compound

TABLE 1

| Name of coating liquid | Type of chiral agent | Amount of chiral agent (part by mass) |
|---|---|---|
| Liquid R-1 | Chiral agent A | 2.87 |
| Liquid R-2 | Chiral agent A | 3.15 |
| Liquid R-3 | Chiral agent A | 3.46 |
| Liquid R-4 | Chiral agent A | 4.20 |
| Liquid R-5 | Chiral agent A | 3.51 |
| Liquid R-6 | Chiral agent A | 2.90 |

Mixture of rod-like liquid crystal compounds

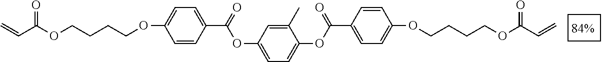 [SMILES: C=CC(=O)OCCCCOc1ccc(C(=O)Oc2ccc(OC(=O)c3ccc(OCCCCOC(=O)C=C)cc3)c(C)c2)cc1]

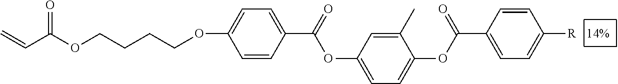

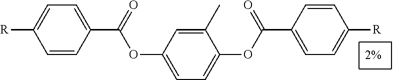

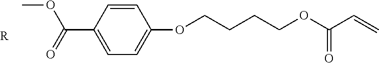

In the above-described mixture, each numerical value denotes the content in units of % by mass. In addition, R is a group bonded through an oxygen atom. Furthermore, an average molar absorption coefficient of the above-described rod-like liquid crystal compound at a wavelength of 300 to 400 nm was 140/mol-cm.

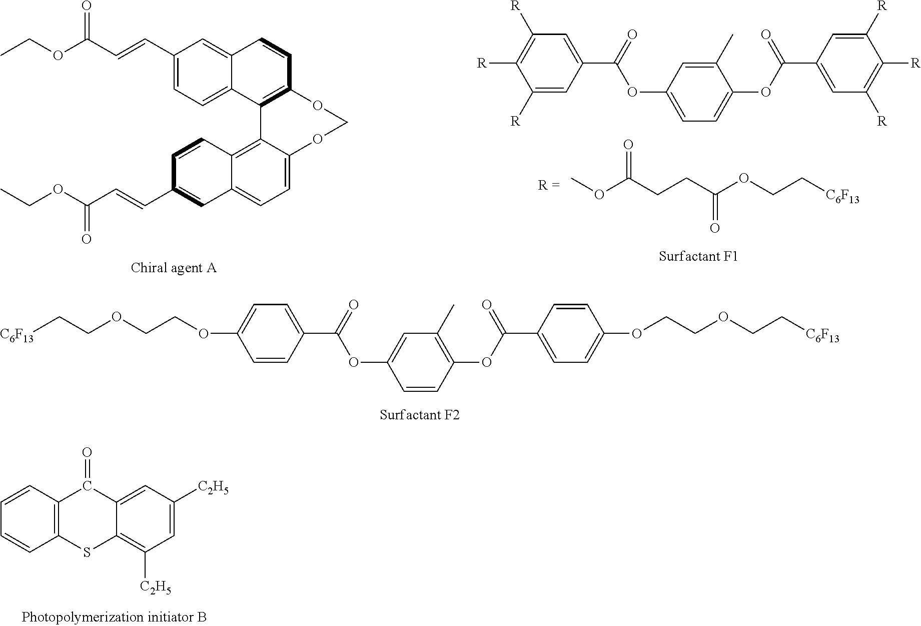

The chiral agent A is a chiral agent in which the helical twisting power (HTP) is reduced by light.

(Coating liquids D-1 to D-7 for Reflecting Layer)

A composition shown below was stirred and dissolved in a container held at 50° C. to prepare coating liquids D-1 to D-7 for a reflecting layer. Here, D represents a coating liquid containing a disk-like liquid crystal compound.

Coating liquid for reflecting layer (containing
disk-like liquid crystal compound)

| Disk-like liquid crystal compound (A) | 80 | parts by mass |
|---|---|---|
| shown below | | |
| Disk-like liquid crystal compound (B) | 20 | parts by mass |
| shown below | | |
| Polymerizable monomer E1 | 10 | parts by mass |
| Surfactant F4 | 0.3 | parts by mass |
| Photopolymerization initiator | 3 | parts by mass |
| (IRGACURE 907 manufactured by | | |
| BASF SE) | | |
| Chiral agent A | amount described in Table 2 | |
| Methyl ethyl ketone | 290 | parts by mass |
| Cyclohexanone | 50 | parts by mass |

### Amount of Chiral Agent of Coating Liquid Containing Disk-Like Liquid Crystal Compound

TABLE 2

| Name of coating liquid | Type of chiral agent | Amount of chiral agent (part by mass) |
|---|---|---|
| Liquid D-1 | Chiral agent A | 3.49 |
| Liquid D-2 | Chiral agent A | 3.83 |
| Liquid D-3 | Chiral agent A | 4.20 |
| Liquid D-4 | Chiral agent A | 5.06 |
| Liquid D-5 | Chiral agent A | 5.47 |
| Liquid D-6 | Chiral agent A | 4.77 |
| Liquid D-7 | Chiral agent A | 3.97 |

Disk-like liquid crystal compound (A) 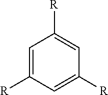 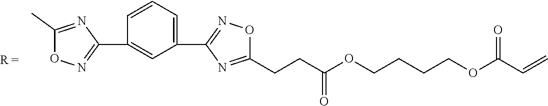 [SMILES: C=CC(=O)OCCCCOC(=O)CCc1nc(-c2cccc(-c3noc(C)n3)c2)no1]
Disk-like liquid crystal compound (B) 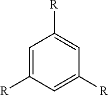 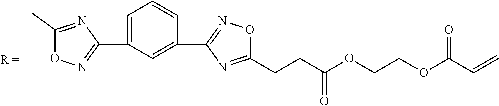 [SMILES: C=CC(=O)OCCOC(=O)CCc1nc(-c2cccc(-c3noc(C)n3)c2)no1]
Polymerizable monomer E1 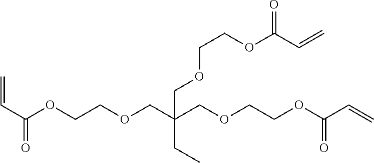 [SMILES: C=CC(=O)OCCOCC(CC)(COCCOC(=O)C=C)COCCOC(=O)C=C]
Surfactant F4 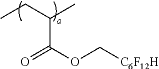 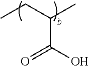
a/b=98/2

### [Production of Optical Film 1]

A polyethylene terephthalate (PET) film (A4100 manufactured by Toyobo Co., Ltd.) having a thickness of 50 m was prepared as a temporary support. The PET film had an easy adhesion layer on one surface.

A surface of the PET film, which was not provided with the easy adhesion layer, was subjected to a rubbing treatment, coated with the coating liquid R-1 for a reflecting layer prepared above using a wire bar coater, dried at 110° C. for 120 seconds, and heat-aged at 100° C. for 1 minute after the solvent was vaporized, thereby obtaining a uniform alignment state. Thereafter, the coating film was irradiated with light from a high pressure mercury lamp through an exposure mask at 40° C. in air with an irradiation amount of 5 mJ/cm², thereby performing photoisomerization. FIG. 5 shows a schematic view of the exposure mask used in this case. A rotationally symmetric exposure mask was used in which the transmittance was high at the center and the transmittance was decreased toward the end part. Thereafter, the surface was irradiated with light using a metal halide lamp at 100° C., an illuminance of 80 mW/cm², and an irradiation amount of 500 mJ/cm² in a low oxygen atmosphere (100 ppm or less), thereby curing the coating liquid to form a red light reflecting layer consisting of a cholesteric liquid crystal layer. The irradiation with light was performed from the side of the cholesteric liquid crystal layer in all cases. Here, the coating thickness was adjusted so that the film thickness of the cured red light reflecting layer was 4.5 km. A patterned cholesteric liquid crystal layer in which the helical pitch of the cholesteric liquid crystalline phase had an in-plane distribution was produced by the photoisomerization using the exposure mask, provided that a central wavelength of a reflection spectrum of the center portion was 701 nm and a central wavelength of a reflection spectrum of the end part was 683 nm.

Next, the surface of the red light reflecting layer was subjected to a corona treatment at a discharge amount of 150 W·min/m², and the surface subjected to the corona treatment was coated with the coating liquid D-2 for a reflecting layer using a wire bar coater. Subsequently, the coating film was dried at 70° C. for 2 minutes and heat-aged at 115° C. for 3 minutes after the solvent was vaporized, thereby obtaining a uniform alignment state. Thereafter, the coating film was irradiated with light from a high pressure mercury lamp through an exposure mask at 40° C. in air with an irradiation amount of 5 mJ/cm², thereby performing photoisomerization. The exposure mask used in this case was the same as the exposure mask used for the first red light reflecting layer. Thereafter, the coating film was heat-aged again at 115° C. for 3 minutes to be a uniform alignment state, and then the surface was irradiated with light using a metal halide lamp at 100° C., an illuminance of 80 mW/cm², and an irradiation amount of 500 mJ/cm² in a low oxygen atmosphere (100 ppm or less), thereby curing the coating film to form a yellow light reflecting layer on the red light reflecting layer. The irradiation with light was performed from the side of the cholesteric liquid crystal layer in all cases. Here, the coating thickness was adjusted so that the film thickness of the cured yellow light reflecting layer was 3.3 km.

Next, the yellow light reflecting layer was coated with the coating liquid R-3 for a reflecting layer prepared above using a wire bar coater, dried at 110° C. for 120 seconds, and heat-aged at 100° C. for 1 minute after the solvent was vaporized, thereby obtaining a uniform alignment state. Thereafter, the coating film was irradiated with light from a high pressure mercury lamp through an exposure mask at 40° C. in air with an irradiation amount of 5 mJ/cm², thereby performing photoisomerization. The exposure mask used in this case was the same as the exposure mask used for the first red light reflecting layer. Thereafter, the surface was irradiated with light using a metal halide lamp at 100° C., an illuminance of 80 mW/cm², and an irradiation amount of 500 mJ/cm² in a low oxygen atmosphere (100 ppm or less), thereby curing the coating liquid to form a green light reflecting layer on the yellow light reflecting layer. The irradiation with light was performed from the side of the cholesteric liquid crystal layer in all cases. Here, the coating thickness was adjusted so that the film thickness of the cured green light reflecting layer was 2.7 m.

Next, the surface of the red light reflecting layer was subjected to a corona treatment at a discharge amount of 150 W·min/m², and the surface subjected to the corona treatment was coated with the coating liquid D-4 for a reflecting layer using a wire bar coater. Subsequently, the coating film was dried at 70° C. for 2 minutes and heat-aged at 115° C. for 3 minutes after the solvent was vaporized, thereby obtaining a uniform alignment state. Thereafter, the coating film was irradiated with light from a high pressure mercury lamp through an exposure mask at 40° C. in air with an irradiation amount of 5 mJ/cm², thereby performing photoisomerization. The exposure mask used in this case was the same as the exposure mask used for the first red light reflecting layer. Thereafter, the coating film was heat-aged again at 115° C. for 3 minutes to be a uniform alignment state, and then the surface was irradiated with light using a metal halide lamp at 100° C., an illuminance of 80 mW/cm², and an irradiation amount of 500 mJ/cm² in a low oxygen atmosphere (100 ppm or less), thereby curing the coating film to form a blue light reflecting layer on the green light reflecting layer. The irradiation with light was performed from the side of the cholesteric liquid crystal layer in all cases. Here, the coating thickness was adjusted so that the film thickness of the cured blue light reflecting layer was 2.5 μm.

In this manner, an optical film 1 was produced.

The coating liquid for a reflecting layer, the amount of the chiral agent, the reflection center wavelength, and the film thickness used for producing the optical film 1 are shown in the following table.

Here, the reflection center wavelength was used to define characteristics of a light reflection film having a reflection band formed of a cholesteric liquid crystalline phase, and referred to the middle point of a spectral band reflected by the film. Specifically, the reflection center wavelength was obtained by calculating the average value of the wavelengths on the short wavelength side and the wavelengths on the long wavelength side which show the half value of the peak reflectivity. A reflection center wavelength (central wavelength of reflected light) was confirmed by producing a film obtained by applying only a single layer. The film thickness was obtained by SEM.

### Reflecting Layer (Cholesteric Liquid Crystal Layer) of Optical Film 1

TABLE 3-1

| | | | Reflection | |
|---|---|---|---|---|
| | Type of | Amount of | center | Film |
| | coating | chiral agent | wavelength | thickness |
| | liquid | (part by mass) | (nm) | (μm) |
| Fourth layer | Liquid D-4 | 4.20 | 480 | 2.5 |
| Third layer | Liquid R-3 | 3.46 | 573 | 2.7 |
| Second layer | Liquid D-2 | 3.15 | 625 | 3.3 |
| First layer | Liquid R-1 | 2.87 | 683 | 4.5 |

### [Production of Optical Film 2]

An optical film 2 was produced using the same production method as the reflective type circular polarizer 1, except that the number of layers was increased to 8, and the coating liquid for a reflecting layer, the amount of the chiral agent, the reflection center wavelength, and the film thickness were changed as shown in the following table.

### Reflecting Layer (Cholesteric Liquid Crystal Layer) of Optical Film 2

TABLE 3-2

| | | | Reflection | |
|---|---|---|---|---|
| | Type of | Amount of | center | Film |
| | coating | chiral agent | wavelength | thickness |
| | liquid | (part by mass) | (nm) | (μm) |
| Eighth layer | Liquid D-4 | 5.06 | 480 | 1.3 |
| Seventh layer | Liquid R-4 | 4.20 | 480 | 1.6 |
| Sixth layer | Liquid D-3 | 4.20 | 573 | 1.5 |
| Fifth layer | Liquid R-3 | 3.46 | 573 | 0.9 |
| Fourth layer | Liquid D-2 | 3.83 | 625 | 1.9 |
| Third layer | Liquid R-2 | 3.15 | 625 | 1.0 |
| Second layer | Liquid D-1 | 3.49 | 683 | 2.3 |
| First layer | Liquid R-1 | 2.87 | 683 | 1.5 |

### [Production of Optical Film 3 and Optical Film 4]

An optical film 3 was produced without performing the isomerization exposure using an exposure mask in a case of producing the reflecting layer (cholesteric liquid crystal layer) in the process of producing the optical film 1.

An optical film 4 was produced without performing the isomerization exposure using an exposure mask in a case of producing the reflecting layer (cholesteric liquid crystal layer) in the process of producing the optical film 2.

### [Production of Optical Film 5]

In an optical film 5, the number of layers of the reflecting layer (cholesteric liquid crystal layer) was increased to 5 layers, and the coating liquid for a reflecting layer and the film thickness were changed as shown in Table 3-3 below. In addition, as a photo-alignment film for aligning the cholesteric liquid crystal, an optical interference layer (positive C-plate layer) produced using a coating liquid for an optical interference layer shown below was used.

### <Coating Liquid PC-1 for Optical Interference Layer>

A composition shown below was stirred and dissolved in a container held at 60° C. to prepare a coating liquids PC-1 for an optical interference layer.

Coating liquid PC-1 for optical interference layer

| | |
|---|---|
| Methyl isobutyl ketone | 3011.0 parts by mass |
| Mixture of rod-like liquid crystal compounds described above | 100.0 parts by mass |
| Photopolymerization initiator C shown below | 5.1 parts by mass |
| Photoacid generator shown below | 3.0 parts by mass |
| Hydrophilic polymer shown below | 2.0 parts by mass |
| Vertical alignment agent shown below | 1.9 parts by mass |
| Viscosity reducing agent shown below | 4.2 parts by mass |
| Material for interlayer photo-alignment film shown below | 8.0 parts by mass |
| Stabilizer shown below | 0.2 parts by mass |

Photopolymerization initiator C 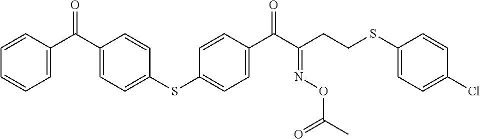 [SMILES: CC(=O)O/N=C(\CCSc1ccc(Cl)cc1)C(=O)c1ccc(Sc2ccc(C(=O)c3ccccc3)cc2)cc1]
Photoacid generator 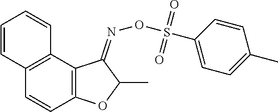 [SMILES: Cc1ccc(S(=O)(=O)O/N=C2/c3c(ccc4ccccc34)OC2C)cc1]
Hydrophilic polymer 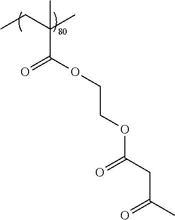 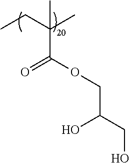
Vertical alignment agent 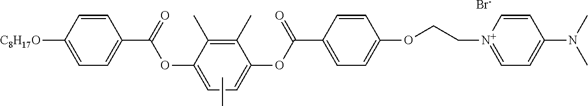
Viscosity reducing agent 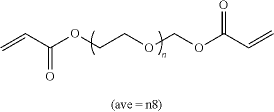
Material for interlayer photo-alignment film 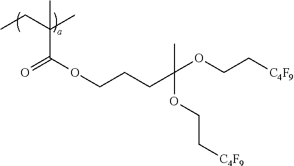 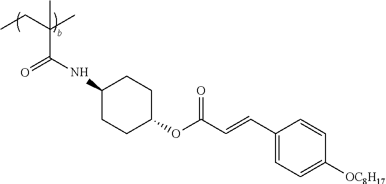 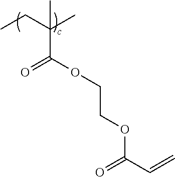
Stabilizer

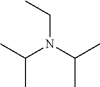

As a support, a triacetyl cellulose film (TAC film (manufactured by FUJIFILM Corporation, TG60)) having a thickness of 60 m was prepared.

The support (TAC film) was coated with the coating liquid PC-1 for an optical interference layer prepared as described above using a wire bar coater, and dried at 80° C. for 60 seconds.

Thereafter, the liquid crystal compound was cured by irradiating the liquid crystal compound with light from an ultraviolet LED lamp (wavelength: 365 nm) with an irradiation amount of 300 mJ/cm² at 78° C. in a low oxygen atmosphere (100 ppm), and at the same time, a cleavage site of the material for an interlayer photo-alignment film was cleaved. Thereafter, the liquid crystal compound was heated at 115° C. for 25 seconds to eliminate a substituent containing a fluorine atom.

As a result, a positive C-plate layer as an optical interference layer, having a cinnamoyl group on the outermost surface and having a film thickness of 80 nm, was formed.

A refractive index nI measured with an interference film thickness meter OPTM (manufactured by Otsuka Electronics Co., Ltd., analyzed by a least squares method) was 1.57. Rth at a wavelength of 550 nm, which was measured with Axoscan (manufactured by Axometrics), was −8 nm.

Next, polarized UV light (wavelength: 313 nm) with an illuminance of 7 mW/cm² and an irradiation amount of 7.9 mJ/cm² was emitted from the positive C-plate side.

The polarized UV light having a wavelength of 313 nm was obtained by transmitting ultraviolet light emitted from a mercury lamp through a band-pass filter having a transmission band at a wavelength of 313 nm and a wire grid polarizing plate.

The coating liquid R-5 for a reflecting layer was applied using a wire bar coater, and dried at 110° C. for 72 seconds. Thereafter, the surface was irradiated with light using a metal halide lamp at 100° C., an illuminance of 80 mW/cm², and an irradiation amount of 500 mJ/cm² in a low oxygen atmosphere (100 ppm or less), thereby curing the coating liquid to form a green light reflecting layer (first light reflecting layer) consisting of a cholesteric liquid crystal layer. The irradiation with light was performed from the side of the cholesteric liquid crystal layer in all cases. Here, the coating thickness was adjusted so that the film thickness of the cured green light reflecting layer was 2.4 m.

Next, the surface of the green light reflecting layer was subjected to a corona treatment at a discharge amount of 150 W·min/m², and the surface subjected to the corona treatment was coated with the coating liquid D-5 for a reflecting layer using a wire bar coater. Subsequently, the coating film was dried at 70° C. for 2 minutes and heat-aged at 115° C. for 3 minutes after the solvent was vaporized, thereby obtaining a uniform alignment state.

Thereafter, the coating film was kept at 45° C. and irradiated with ultraviolet rays (300 mJ/cm²) using a metal halide lamp in a nitrogen atmosphere, thereby curing the coating film to form a blue light reflecting layer (second light reflecting layer) on the green light reflecting layer. The irradiation with light was performed from the side of the cholesteric liquid crystal layer in all cases. Here, the coating thickness was adjusted so that the film thickness of the cured blue light reflecting layer was 1.7 m.

Next, the blue light reflecting layer was coated with the coating liquid D-6 for a reflecting layer using a wire bar coater. Subsequently, the coating film was dried at 70° C. for 2 minutes and heat-aged at 115° C. for 3 minutes after the solvent was vaporized, thereby obtaining a uniform alignment state. Thereafter, the coating film was kept at 45° C. and irradiated with ultraviolet rays (300 mJ/cm²) using a metal halide lamp in a nitrogen atmosphere, thereby curing the coating film to form a second blue light reflecting layer (third light reflecting layer) on the blue light reflecting layer. The irradiation with light was performed from the side of the cholesteric liquid crystal layer in all cases. Here, the coating thickness was adjusted so that the film thickness of the cured blue light reflecting layer was 3.8 μm.

Next, the second blue light reflecting layer was coated with the coating liquid R-6 for a reflecting layer using a wire bar coater and dried at 110° C. for 72 seconds.

Thereafter, the surface was irradiated with light using a metal halide lamp at 100° C., an illuminance of 80 mW/cm², and an irradiation amount of 500 mJ/cm² in a low oxygen atmosphere (100 ppm or less), thereby curing the coating liquid to form a red light reflecting layer (fourth light reflecting layer) on the second blue light reflecting layer. The irradiation with light was performed from the side of the cholesteric liquid crystal layer in all cases. Here, the coating thickness was adjusted so that the film thickness of the cured red light reflecting layer was 4.8 m.

Next, the surface of the red light reflecting layer was subjected to a corona treatment at a discharge amount of 150 W·min/m², and the surface subjected to the corona treatment was coated with the coating liquid D-7 for a reflecting layer using a wire bar coater.

Subsequently, the coating film was dried at 70° C. for 2 minutes and heat-aged at 115° C. for 3 minutes after the solvent was vaporized, thereby obtaining a uniform alignment state.

Thereafter, the coating film was kept at 45° C. and irradiated with ultraviolet rays (300 mJ/cm²) using a metal halide lamp in a nitrogen atmosphere, thereby curing the coating film to form a yellow light reflecting layer (fifth light reflecting layer) on the red light reflecting layer. The irradiation with light was performed from the side of the cholesteric liquid crystal layer in all cases. Here, the coating thickness was adjusted so that the film thickness of the cured yellow light reflecting layer was 3.3 km.

For each of the reflecting layers of the produced optical film 5, the coating liquid for a reflecting layer, the amount of the chiral agent, the reflection center wavelength, and the film thickness were shown in the following table.

### Reflecting Layer (Cholesteric Liquid Crystal Layer) of Optical Film 5

TABLE 3-3

| | | | Reflection | |
|---|---|---|---|---|
| | Type of | Amount of | center | Film |
| | coating | chiral agent | wavelength | thickness |
| | liquid | (part by mass) | (nm) | (μm) |
| Fifth layer | Liquid D-7 | 3.97 | 605 | 3.3 |
| Fourth layer | Liquid R-6 | 2.90 | 675 | 4.8 |
| Third layer | Liquid D-6 | 4.77 | 508 | 3.8 |
| Second layer | Liquid D-5 | 5.47 | 446 | 1.7 |
| First layer | Liquid R-5 | 3.51 | 566 | 2.4 |

### [Preparation of Optical Film 6]

As an optical film 6 used in a forming test, having optical isotropy, a polymethyl methacrylate film (PMMA film) having a film thickness of 50 m was prepared.

### [Forming Method 1]

The optical film 2 was bonded to a PMMA film through a pressure-sensitive adhesive sheet (NCF-D692(5)) manufactured by LINTEC Corporation, a separate film was peeled off from the pressure-sensitive adhesive sheet to expose a pressure-sensitive adhesive surface, and the laminate was set in a forming device.

A forming space in the forming device consisted of a box 1 and a box 2, partitioned by the optical film 1, and a convex meniscus lens LE1076-A (diameter: 2 inches, focal length: 100 mm, curvature radius on the concave side: 65 mm) manufactured by Thorlabs, Inc. was disposed as a mold in the box 1 on the lower side of the optical film 2, with the concave surface facing upward.

In addition, a transparent window was installed on the upper part of the box 2 on the upper side of the optical film 1, and an IR light source for heating the optical film was installed on the outside of the forming device.

Between the IR light source and the optical film 2, a cholesteric liquid crystal layer which reflects infrared rays with wavelengths from 2.2 μm to 3.0 μm at a reflectivity of approximately 50% was cut to match the outer peripheral shape of the mold, and the center portion was cut out in a circular shape with a diameter of 1 inch to obtain a ring-shaped patterned infrared reflecting filter. In this case, the center portion of the patterned infrared reflecting filter was disposed to be located at the center portion of the mold in a case of being viewed from directly above.

Next, each of the inside of box 1 and the inside of box 2 was evacuated to 0.1 atm or less by a vacuum pump.

Next, as a step of heating the optical film 2, infrared rays were emitted, and the optical film 1 was heated until the center portion was heated to 108° C. and the end part heated to 99° C. Since the glass transition temperature Tg of the PMMA film used as the support was 105° C., it was intended that the center portion would be more likely to stretch and the end part would be less likely to stretch during the forming.

Next, as a step of pressing the optical film 2 against the mold to the optical film 2 along a shape of the mold, gas was allowed to flow into the box 2 from a gas cylinder to pressurize the optical film to 300 kPa, and the optical film 2 was pressed against the mold. The optical film 2 was adhered to the mold through the pressure-sensitive adhesive sheet, and used directly as a composite lens 1.

Finally, the optical film was cut by trimming a portion protruding from the lens which served as the mold, thereby obtaining the optical film 2 bonded to the lens, which was formed on a curved surface.

### [Forming Method 2]

The optical film 2 was bonded to a PMMA film through a pressure-sensitive adhesive sheet (NCF-D692(5)) manufactured by LINTEC Corporation, a separate film was peeled off from the pressure-sensitive adhesive sheet to expose a pressure-sensitive adhesive surface, and the laminate was set in a forming device.

A forming space in the forming device consisted of a box 1 and a box 2, partitioned by the optical film 2, and a convex meniscus lens LE1076-A (diameter: 2 inches, focal length: 100 mm, curvature radius on the concave side: 65 mm) manufactured by Thorlabs, Inc. was disposed as a mold in the box 1 on the lower side of the optical film 2 in a state of being expanded with clay around, with the concave surface facing upward. The extension by the clay was such that the curved surface of the concave surface of the lens was extended substantially with the same curvature as the original, and the shape of the mold including the lens and the clay was such that the diameter was 3 inches and the curvature radius of the concave surface was 65 mm.

In addition, a transparent window was installed on the upper part of the box 2 on the upper side of the optical film 2, and an IR light source for heating the optical film 2 was installed on the outside of the forming device.

Next, each of the inside of box 1 and the inside of box 2 was evacuated to 0.1 atm or less by a vacuum pump.

Next, as a step of heating the optical film 2, infrared rays were emitted, and the optical film 2 was heated until the center portion was heated to 108° C. Since the glass transition temperature Tg of the PMMA film used as the support was 105° C., it was intended that the temperature was higher than the glass transition temperature Tg.

Next, as a step of pressing the optical film 2 against the mold to the optical film 2 along a shape of the mold, gas was allowed to flow into the above-described box 2 from a gas cylinder to pressurize the optical film to 300 kPa, and the optical film 2 was pressed against the mold. The optical film 2 was bonded to the lens portion in the mold through the pressure-sensitive adhesive sheet and used as a composite lens 2 as it is, and the clay disposed outside the lens was removed.

Finally, the optical film 2 was cut by trimming a portion protruding from the lens, thereby obtaining the optical film 2 bonded to the lens, which was formed on a curved surface. At this time, the diameter of the cut-out optical film 2 was 67% of the diameter of the mold formed by the lens and the clay.

### [Forming Method 3]

The optical film 2 was bonded to a PMMA film through a pressure-sensitive adhesive sheet (NCF-D692(5)) manufactured by LINTEC Corporation, a separate film was peeled off from the pressure-sensitive adhesive sheet to expose a pressure-sensitive adhesive surface, and the laminate was set in a forming device.

A forming space in the forming device consisted of a box 1 and a box 2, partitioned by the optical film 1, and a convex meniscus lens LE1076-A (diameter: 2 inches, focal length: 100 mm, curvature radius on the concave side: 65 mm) manufactured by Thorlabs, Inc. was disposed as a mold in the box 1 on the lower side of the optical film 2, with the concave surface facing upward.

In addition, a transparent window was installed on the upper part of the box 2 on the upper side of the optical film 2, and an IR light source for heating the optical film was installed on the outside of the forming device.

Next, each of the inside of box 1 and the inside of box 2 was evacuated to 0.1 atm or less by a vacuum pump.

Next, as a step of heating the optical film 2, infrared rays were emitted, and the optical film 2 was heated until the center portion was heated to 108° C.

Next, as a step of pressing the optical film 2 against the mold to the optical film 2 along a shape of the mold, gas was allowed to flow into the box 2 from a gas cylinder to pressurize the optical film to 300 kPa, and the optical film 2 was pressed against the mold. At this time, the pressurization speed until reaching 300 kPa was adjusted such that the temperature of the center portion in the mold immediately after the compression was set to 99° C. Since the glass transition temperature Tg of the PMMA film used as the support was 105° C., it was intended that, while forming, the center portion would be more likely to stretch and the end part would be less likely to stretch during the forming.

The optical film 2 was adhered to the mold through the pressure-sensitive adhesive sheet, and used directly as a composite lens 3.

Finally, the optical film 2 was cut by trimming a portion protruding from the lens which served as the mold, thereby obtaining the optical film 2 bonded to the lens, which was formed on a curved surface.

### [Forming Method 4]

The optical film 2 was bonded to a PMMA film through a pressure-sensitive adhesive sheet (NCF-D692(5)) manufactured by LINTEC Corporation, and a separate film was peeled off from the pressure-sensitive adhesive sheet to expose the adhesive surface.

As a concave mold, a convex meniscus lens LE1076-A (diameter: 2 inches, focal length: 100 mm, curvature radius on the concave side: 65 mm) manufactured by Thorlabs, Inc. was disposed with the concave surface facing upward.

The optical film 2 was disposed on the mold such that the pressure-sensitive adhesive surface was facing downward. As a result, the optical film 2 was constrained by the edge of the concave mold.

Next, a convex mold having a curvature radius of 65 mm was prepared, and the mold was heated in an oven to 120° C.

Next, the vertex of the convex portion of the convex mold was positioned to align with the center portion of the concave mold when viewed from directly above, and the mold was slowly pressed against the optical film 2. As a result, during the forming, the temperature of the center portion first increased, making it more stretchable, and as the pushing of the convex surface progressed, the high-temperature region spread toward the end part.

The optical film 2 was adhered to the mold through the pressure-sensitive adhesive sheet, and used directly as a composite lens 4. Finally, the optical film was cut by trimming a portion protruding from the lens which served as the mold, thereby obtaining the optical film 2 bonded to the lens, which was formed on a curved surface.

The optical films 1, 3, 4, and 5 were formed by the forming method 1 to produce composite lenses 5, 6, 7, and 8, respectively.

### [Production of Polarizing Plate Laminate]

### [Production of Positive C-Plate 1]

A positive C-plate 1 was produced by adjusting the film thickness with reference to the method described in paragraphs 0132 to 0134 of JP2016-053709A. Re of the positive C-plate 1 was 0.2 nm and Rth thereof was −310 nm.

### [Production of Retardation Layer 1]

A retardation layer 1 having reverse dispersibility was produced with reference to the method described in paragraphs 0151 to 0163 of JP2020-084070A. Re of the retardation layer 1 was 146 nm and Rth thereof was 73 nm.

### [Production of Linear Polarizer]

### [Production of Cellulose Acylate Film 1]

### (Production of Core Layer Cellulose Acylate Dope)

The following composition was put into a mixing tank and stirred to dissolve each component, thereby preparing a cellulose acetate solution used as a core layer cellulose acylate dope.

| Core layer cellulose acylate dope | |
|---|---|
| Cellulose acetate having acetyl substitution | 100 parts by mass |
| degree of 2.88 | |
| Polyester compound B described in | 12 parts by mass |
| Examples of JP2015-227955A | |
| Compound F shown below | 2 parts by mass |
| Methylene chloride (first solvent) | 430 parts by mass |
| Methanol (second solvent) | 64 parts by mass |

Compound F

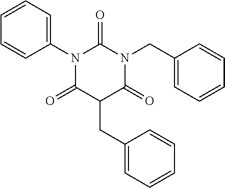 [SMILES: O=C1C(Cc2ccccc2)C(=O)N(c2ccccc2)C(=O)N1Cc1ccccc1]

### (Production of Outer Layer Cellulose Acylate Dope)

10 parts by mass of the following matte agent solution was added to 90 parts by mass of the core layer cellulose acylate dope to prepare a cellulose acetate solution to be used as an outer layer cellulose acylate dope.

Matting agent solution

| | | |
|---|---|---|
| Silica particles having an average particle | 2 | parts by mass |
| diameter of 20 nm (AEROSIL R972, manufactured | | |
| by Nippon Aerosil Co., Ltd.) | | |
| Methylene chloride (first solvent) | 76 | parts by mass |
| Methanol (second solvent) | 11 | parts by mass |
| Core layer cellulose acylate dope described above | 1 | part by mass |

### (Production of Cellulose Acylate Film 1)

The core layer cellulose acylate dope and the outer layer cellulose acylate dope were filtered through filter paper having an average hole diameter of 34 m and a sintered metal filter having an average pore size of 10 m, and three layers which were the core layer cellulose acylate dope and the outer layer cellulose acylate dopes provided on both sides of the core layer cellulose acylate dope were simultaneously cast from a casting port onto a drum at 20° C. (band casting machine).

Next, the film was peeled off in a state where the solvent content was approximately 20% by mass, both ends of the film in the width direction were fixed by tenter clips, and the film was dried while being stretched at a stretching ratio of 1.1 times in the lateral direction.

Thereafter, the film was further dried by being transported between the rolls of the heat treatment device to prepare an optical film having a thickness of 40 m, and the optical film was used as a cellulose acylate film 1. An in-plane retardation of the obtained cellulose acylate film 1 was 0 nm.

### <Formation of Photoalignment Layer PA1>

The cellulose acylate film 1 was continuously coated with a coating liquid S-PA-1 for forming an alignment layer described below with a wire bar. The support on which the coating film was formed was dried with hot air at 140° C. for 120 seconds, and the coating film was irradiated with polarized ultraviolet rays (10 mJ/cm², using an ultra-high pressure mercury lamp) to form a photoalignment layer PA1. A film thickness thereof was 0.3 μm.

| Core layer cellulose acylate dope | |
|---|---|
| Polymer M-PA-1 shown below | 100 parts by mass |
| Acid generator PAG-1 shown below | 5.00 parts by mass |
| Acid generator CPI-110TF shown below | 0.005 parts by mass |
| Xylene | 1220.00 parts by mass |
| Methyl isobutyl ketone | 122.00 parts by mass |

Polymer M-PA-1 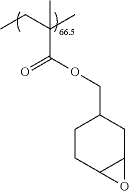 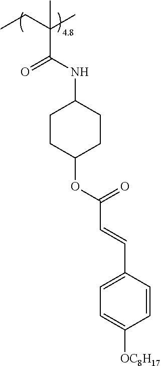 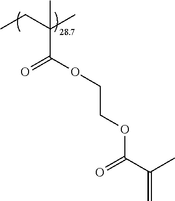
Acid generator PAG-1 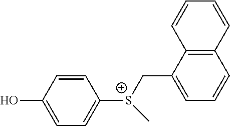 [SMILES: C[S+](Cc1cccc2ccccc12)c1ccc(O)cc1] 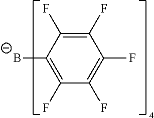
Acid generator CPI-110F

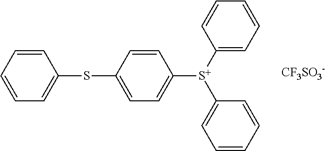

### <Formation of Light Absorption Anisotropic Layer P1>

The obtained photoalignment layer PA1 was continuously coated with the following coating liquid S-P-1 for forming a light absorption anisotropic layer with a wire bar. Next, the coating layer P1 was heated at 140° C. for 30 seconds and cooled to room temperature (23° C.). Next, the coating layer P1 was heated at 90° C. for 60 seconds and cooled to room temperature again. Thereafter, the coating layer P1 was irradiated with an LED lamp (central wavelength of 365 nm) for 2 seconds under an irradiation condition of an illuminance of 200 mW/cm², thereby forming a light absorption anisotropic layer P1 on the photoalignment layer PAL. A film thickness thereof was 1.6 μm.

Composition of coating liquid S-P-1 for forming light absorption anisotropic layer

| | |
|---|---|
| Dichroic substance D-1 shown below | 0.25 parts by mass |
| Dichroic substance D-2 shown below | 0.36 parts by mass |
| Dichroic substance D-3 shown below | 0.59 parts by mass |
| Polymer liquid crystal compound M-P-1 shown below | 2.21 parts by mass |
| Low-molecular-weight liquid crystal compound M-1 | 1.36 parts by mass |
| Polymerization initiator | |
| IRGACURE OXE-02 (manufactured by BASF SE) | 0.200 parts by mass |
| Surfactant F-1 shown below | 0.026 parts by mass |
| Cyclopentanone | 46.00 parts by mass |
| Tetrahydrofuran | 46.00 parts by mass |
| Benzyl alcohol | 3.00 parts by mass |

Dichroic substance D-1 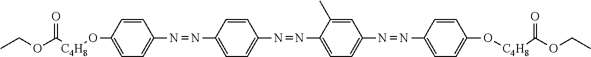
Dichroic substance D-2 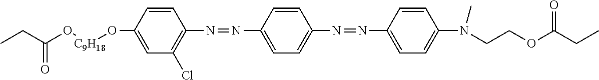
Dichroic substance D-3 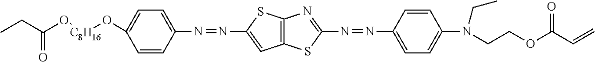
Polymer liquid crystal compound M-P-1 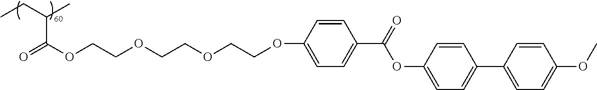 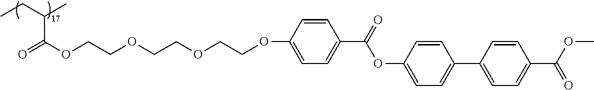 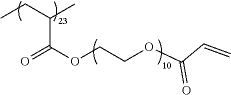
Low-molecular-weight liquid crystal compound M-1 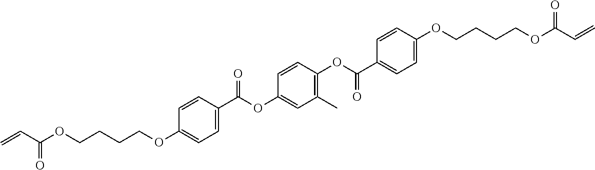 [SMILES: C=CC(=O)OCCCCOc1ccc(C(=O)Oc2ccc(OC(=O)c3ccc(OCCCCOC(=O)C=C)cc3)c(C)c2)cc1]
Surfactant F-1

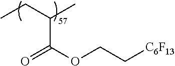

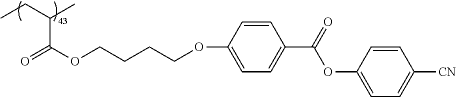

The obtained retardation layer 1 was bonded to the obtained positive C-plate 1 on a side opposite to the support.

Next, the light absorption anisotropic layer P1 was transferred. In this case, the light absorption anisotropic layer P1 was transferred such that a layer on a side opposite to the temporary support was on the positive C-plate 1 side. The temporary support of the light absorption anisotropic layer P1 was peeled off and removed after the transfer.

The transfer of the light absorption anisotropic layer P1 was performed by the following procedure.

(1) A UV adhesive Chemi-seal U2084B (manufactured by ChemiTech Inc., refractive index n after curing: 1.60) was applied onto the positive C-plate on the support side using a wire bar coater such that the thickness was set to 2 m; the light absorption anisotropic layer P1 was laminated thereon with a laminator such that the side opposite to the temporary support was in contact with the UV adhesive.

(2) After nitrogen purging until the oxygen concentration reached 100 ppm or less in a purge box, the light absorption anisotropic layer P1 was cured by being irradiated with ultraviolet rays using a high-pressure mercury lamp from the temporary support side; the illuminance was 25 mW/cm² and the irradiation amount was 1,000 mJ/cm².

(3) Finally, the temporary support of the light absorption anisotropic layer P1 was peeled off.

Here, the retardation layer 1 and the light absorption anisotropic layer P1 were laminated such that the slow axis of the retardation layer 1 and the absorption axis of the light absorption anisotropic layer P1 formed an angle of 45°. Finally, the support of the positive C-plate 1 was peeled off.

In this manner, a polarizing plate laminate was produced. In a case where the produced polarizing plate laminate was irradiated with dextrorotatory circularly polarized light from the positive C-plate side, it was found that substantially all of visible light was absorbed; and in a case where the produced polarizing plate laminate was irradiated with levorotatory circularly polarized light, it was found that substantially all of visible light was transmitted.

### [Production of Optical Laminate 1 and Composite Lens 9]

The optical film 5 and the light absorption anisotropic layer P1 of the produced polarizing plate laminate were bonded to each other in a disposition in which the surface of the optical film 5 on the yellow light reflecting layer (fifth light reflecting layer) side and the surface of the polarizing plate laminate on the side opposite to the optical film 5 faced each other, through a pressure-sensitive adhesive sheet (NCF-D692(5)) manufactured by LINTEC Corporation.

After bonding, a tack film used as the support for the optical film 5 was peeled off to obtain an optical laminate 1 consisting of the cholesteric liquid crystal, the phase difference film, and the light absorption anisotropic layer.

The produced optical laminate 1 was formed by the forming method 1 to produce a composite lens 9.

In this case, the surface of the optical laminate 1 on the optical film 5 side was positioned to face the lens side during the forming.

### [Production of Composite Lenses 11 to 14 Using Optical Film 6]

The optical film 6 was formed by the forming methods 1 to 4 to produce composite lenses 11 to 14.

### [Formation of Half Mirror on Composite Lens]

A convex surface side of the composite lens 1 (convex meniscus lens LE1076-A (diameter: 2 inches, focal length: 100 mm) manufactured by Thorlabs, Inc.; the optical film 2 was bonded to the concave surface side) was subjected to aluminum deposition so that the reflectivity was 40%, thereby obtaining a half mirror. As a result of measuring reflection spectra of the center portion and end part of the composite lens 1 using a spectrophotometer (manufactured by JASCO Corporation, V-550) to which a large integrating sphere device (manufactured by JASCO Corporation, ILV-471) was attached, the deviation of the band of the reflection spectra of the center portion and the end part was 0.8%.

The aluminum evaporation was also performed on the composite lenses 2 to 7 in the same manner.

In the composite lenses 6, 7, and 8 using the optical films 3, 4, and 5, which had not been subjected to photoisomerization, the deviation of the band of the reflection spectrum between the center portion and the end part was 2.8% for each.

### Examples 1 to 8

A virtual reality display apparatus “Huawei VR Glass” (manufactured by Huawei Technologies Co., Ltd.), which was a virtual reality display apparatus for which a reciprocating optical system was employed, was disassembled, and all composite lenses were taken out.

A virtual reality display apparatus of Example 1 was produced by incorporating the composite lens 1 to which the optical film 2 had been bonded into the body instead of the taken-out composite lens, in which the optical absorption anisotropic layer P1 side of the polarizing plate laminate was installed between the composite lens 1 and the eye of the user such that the light absorption anisotropic layer P1 side of the polarizing plate laminate was on the eye side.

In the produced virtual reality display apparatus, a black-and-white checkered pattern was displayed on an image display panel, and ghost visibility was visually evaluated in terms of the following four stages.

### <Evaluation of Ghost>

A: ghost was slightly visible, but not noticeable.
B: weak ghost was visible.
C: slightly strong ghost was visible.
D: strong ghost was visible.

Furthermore, using the composite lenses 2 to 8, virtual reality display apparatuses of Examples 2 to 8 were produced by the same procedure, and the ghost visibility was evaluated. Table 4 shows the forming method and the type of optical film used in each of Examples.

### Example 9

A virtual reality display apparatus “Huawei VR Glass” (manufactured by Huawei Technologies Co., Ltd.), which was a virtual reality display apparatus for which a reciprocating optical system was employed, was disassembled, and all composite lenses were taken out.

The composite lens 9 to which the optical laminate 1 was bonded was incorporated into the body in place of the taken composite lens, thereby producing a virtual reality display apparatus of Example 9.

In the produced virtual reality display apparatus, a black-and-white checkered pattern was displayed on an image display panel, and ghost visibility was visually evaluated in the same manner as described above.

### Examples 11 to 14

Composite lenses 11 to 14 using the optical film 6 were obtained as Examples 11 to 14.

### <Measurement of Phase Difference>

For the composite lenses 1 to 9 of Examples 1 to 9 and the composite lenses 11 to 14 of Examples 11 to 14, a small piece of the optical film at the center portion and the end part was peeled off and taken out from the composite lens, and a phase difference (in-plane retardation) was measured using Axoscan.

The position of the small piece of the end part was sampled at eight points at 45-degree intervals in the azimuthal angle direction from a position 5 mm from the edge of the lens. Among the phase differences measured at the sampled 8 points, the maximum value was defined as the phase difference at the end part of the optical film.

In addition, in Examples 1 to 9 in which the optical film had a cholesteric liquid crystal layer, the evaluation wavelength was set according to the cholesteric liquid crystal layer with the shortest selective central wavelength. The reason why the evaluation wavelength was different between the end part and the center part is that the half-width on the short wavelength side is different between the end part and the center part due to the difference in the stretching ratio between the end part and the center part.

In each of Examples, the composite lens, the forming method, and the cholesteric liquid crystal layer are shown in Table 4 below, the evaluation results of the ghost visibility are shown in Table 5 below, and the measurement results of the phase difference are shown in Table 5 below.

In Examples 11 to 14, the evaluation of the ghost was not performed, and only the measurement of the phase difference was performed.

Table 4. Composite lens, forming method, and cholesteric liquid crystal layer in each of Examples

TABLE 4

| | | | Cholesteric liquid crystalline phase | | |
|---|---|---|---|---|---|
| | Composite | Forming | | Number | Isomerization |
| Example | lens | method | Level | of layers | exposure |
| Example 1 | Composite | Forming | Optical film 2 | 8 | Y |
| | lens 1 | method 1 | | | |
| Example 2 | Composite | Forming | Optical film 2 | 8 | Y |
| | lens 2 | method 2 | | | |
| Example 3 | Composite | Forming | Optical film 2 | 8 | Y |
| | lens 3 | method 3 | | | |
| Example 4 | Composite | Forming | Optical film 2 | 8 | Y |
| | lens 4 | method 4 | | | |
| Example 5 | Composite | Forming | Optical film 1 | 4 | Y |
| | lens 5 | method 1 | | | |
| Example 6 | Composite | Forming | Optical film 3 | 4 | N |
| | lens 6 | method 1 | | | |
| Example 7 | Composite | Forming | Optical film 4 | 8 | N |
| | lens 7 | method 1 | | | |
| Example 8 | Composite | Forming | Optical film 5 | 5 | N |
| | lens 8 | method 1 | | | |
| Example 9 | Composite | Forming | Optical laminate 1 | 5 | N |
| | lens 9 | method 1 | using optical film 5 | | |
| Example 11 | Composite | Forming | Optical film 6 | — | — |
| | lens 11 | method 1 | | | |
| Example 12 | Composite | Forming | Optical film 6 | — | — |
| | lens 12 | method 2 | | | |
| Example 13 | Composite | Forming | Optical film 6 | — | — |
| | lens 13 | method 3 | | | |
| Example 14 | Composite | Forming | Optical film 6 | — | — |
| | lens 14 | method 4 | | | |

TABLE 5

Ghost visibility

| | Center portion of | End part of |
|---|---|---|
| | visual field | visual field |
| Example 1 | A | A |
| Example 2 | A | A |
| Example 3 | A | A |
| Example 4 | A | A |
| Example 5 | A | C |
| Example 6 | B | C |
| Example 7 | B | A |
| Example 8 | A | A |
| Example 9 | A | A |

As shown in Table 5, in the virtual reality display apparatuses of Examples 1 to 4, 8, and 9, the ghost was good over the entire region of visual field. In addition, the change in color of the white portion of the black-and-white checkered pattern was not noticeable.

In Examples 5 and 6, a slightly strong ghost was visually recognized at the end part, but it was within the allowable range. In addition, in Example 6, a weak ghost was visible in the center part of the visual field. In Example 5, the change in color of the white portion of the black-and-white checkered pattern was not noticeable, and in Example 6, the change in color of the white portion of the black-and-white checkered pattern was noticeable. In Example 7, a weak ghost was visually recognized in the center part of the visual field, but was not visually recognized in the end part. In Example 7, the change in color of the white portion of the black-and-white checkered pattern was recognized.

### Table 6. Evaluation of Phase Difference of Each of Examples

TABLE 6

| | | | | | Anisotropy after | | Anisotropy after | |
|---|---|---|---|---|---|---|---|---|
| | | | | | forming (center) | | forming (end part) | |
| | Cholesteric liquid crystalline phase | | | | Evaluation | Phase | Evaluation | Phase |
| | | Number | Isomerization | Forming | wavelength | difference | wavelength | difference |
| Example | Level | of layers | exposure | method | (nm) | (nm) | (nm) | (nm) |
| Example | Optical | 8 | Y | Forming | 410 | 3.0 | 415 | 3.0 |
| 1 | film 2 | | | method 1 | | | | |
| Example | Optical | 8 | Y | Forming | 410 | 3.0 | 415 | 5.0 |
| 2 | film 2 | | | method 2 | | | | |
| Example | Optical | 8 | Y | Forming | 410 | 3.0 | 415 | 8.0 |
| 3 | film 2 | | | method 3 | | | | |
| Example | Optical | 8 | Y | Forming | 410 | 3.0 | 415 | 8.0 |
| 4 | film 2 | | | method 4 | | | | |
| Example | Optical | 4 | Y | Forming | 410 | 3.0 | 415 | 3.0 |
| 5 | film 1 | | | method 1 | | | | |
| Example | Optical | 4 | N | Forming | 410 | 3.0 | 425 | 3.0 |
| 6 | film 3 | | | method 1 | | | | |
| Example | Optical | 8 | N | Forming | 410 | 3.0 | 425 | 3.0 |
| 7 | film 4 | | | method 1 | | | | |
| Example | Optical | 5 | N | Forming | 410 | 3.0 | 425 | 3.0 |
| 8 | film 5 | | | method 1 | | | | |
| Example | Optical | — | — | Forming | 550 | 0.0 | 550 | 1.0 |
| 11 | film 6 | | | method 1 | | | | |
| Example | Optical | — | — | Forming | 550 | 0.0 | 550 | 2.0 |
| 12 | film 6 | | | method 2 | | | | |
| Example | Optical | — | — | Forming | 550 | 0.0 | 550 | 3.0 |
| 13 | film 6 | | | method 3 | | | | |
| Example | Optical | — | — | Forming | 550 | 0.0 | 550 | 3.0 |
| 14 | film 6 | | | method 4 | | | | |

As shown in Table 6, in the optical films 1 to 5 which included the cholesteric liquid crystal layer, formed into the shape of the composite lens by the forming method according to the embodiment of the present invention, both the center and the end part (outer edge portion) had a phase difference, that is, in-plane retardation of less than 2% of the evaluation wavelength after the forming.

In addition, also in the optical film 6 in which the PMMA film formed into the shape of the composite lens was used in the forming method according to the embodiment of the present invention, both the center and the end part (outer edge portion) had a phase difference, that is, in-plane retardation of less than 11 nm after the forming.

As described above, with the forming method according to the embodiment of the present invention, the occurrence of the phase difference of the optical film, that is, the in-plane retardation is suppressed to be low at both the center part and the end part even after the forming is performed.

### Examples of Second Embodiment

### [Production of Coating Liquids R-1 to R-4 for Cholesteric Liquid Crystal Layer]

A composition shown below was stirred and dissolved in a container kept at 70° C. to prepare each of coating liquids R-1 to R-4 for a cholesteric liquid crystal layer. Here, R means a coating liquid containing a rod-like liquid crystal compound. The amount of the chiral agent contained in each coating liquid for a cholesteric liquid crystal layer is shown in Table 7.

Coating liquid R-1 for cholesteric liquid crystal layer

| Methyl ethyl ketone | 120.9 | parts by mass |
|---|---|---|
| Cyclohexanone | 21.3 | parts by mass |
| Mixture of rod-like liquid crystal compounds | 100.0 | parts by mass |
| shown below | | |
| Polymerization initiator LC-1-1 | 3.00 | parts by mass |
| Chiral agent A shown below | shown in Table 7 | |
| Surfactant F1 shown below | 0.027 | parts by mass |
| Surfactant F2 shown below | 0.067 | parts by mass |

### Table 7. Amount of Chiral Agent in Coating Liquid Containing Rod-Like Liquid Crystal Compound

TABLE 7

| Name of coating liquid | Type of chiral agent | Amount of chiral agent (part by mass) |
|---|---|---|
| Liquid R-1 | Chiral agent A | 2.87 |
| Liquid R-2 | Chiral agent A | 3.15 |
| Liquid R-3 | Chiral agent A | 3.46 |
| Liquid R-4 | Chiral agent A | 4.20 |

Mixture of rod-like liquid crystal compounds

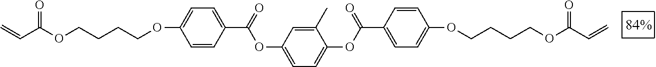 [SMILES: C=CC(=O)OCCCCOc1ccc(C(=O)Oc2ccc(OC(=O)c3ccc(OCCCCOC(=O)C=C)cc3)c(C)c2)cc1]

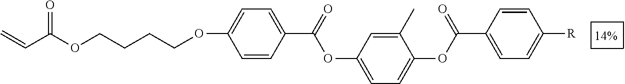

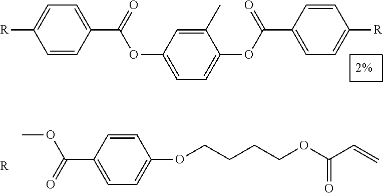

In the above-described mixture, each numerical value denotes the content in units of % by mass. In addition, R is a group bonded through an oxygen atom. Furthermore, an average molar absorption coefficient of the above-described rod-like liquid crystal compound at a wavelength of 300 to 400 nm was 140/mol·cm.

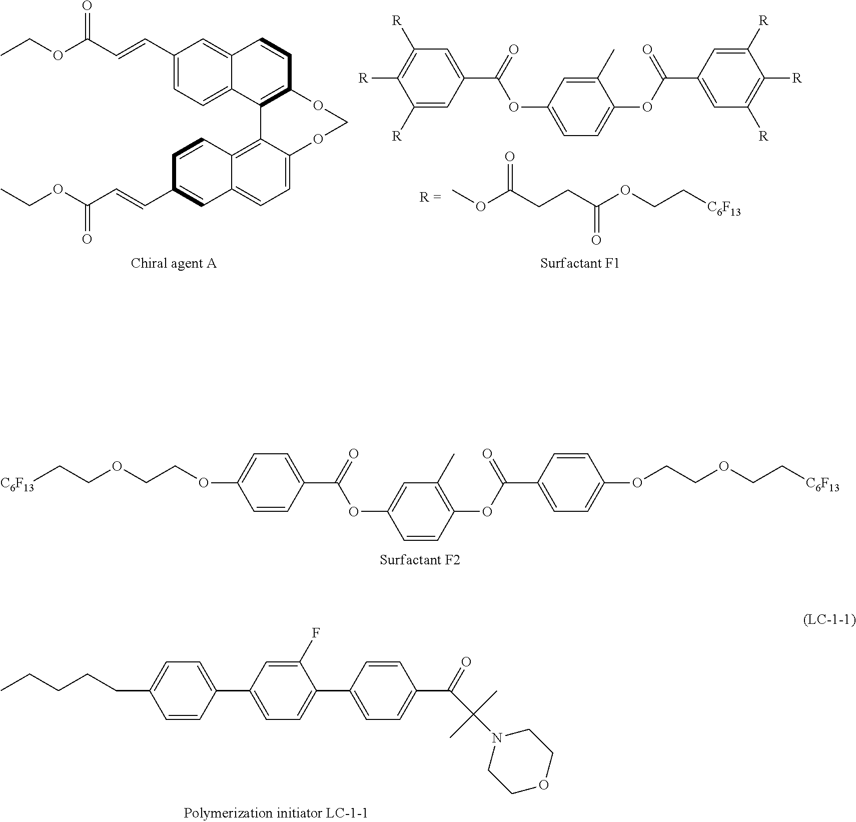

The chiral agent A is a chiral agent in which the helical twisting power (HTP) is reduced by light.

### (Coating Liquids D-1 to D-4 for Cholesteric Liquid Crystal Layer)

A composition shown below was stirred and dissolved in a container held at 50° C. to prepare coating liquids D-1 to D-4 for a cholesteric liquid crystal layer. Here, D means a coating liquid containing a disk-like liquid crystal compound. The amount of the chiral agent contained in each coating liquid for a cholesteric liquid crystal layer is shown in Table 8.

Coating liquid D-1 for cholesteric liquid crystal layer

| Disc-like liquid crystal (A) shown below | 80 | parts by mass |
|---|---|---|
| Disc-like liquid crystal (B) shown below | 20 | parts by mass |
| Polymerizable monomer E1 | 10 | parts by mass |
| Surfactant F4 | 0.3 | parts by mass |
| Polymerization initiator LC-1-1 | 3 | parts by mass |
| Chiral agent A | shown in Table 8 | |
| Methyl ethyl ketone | 290 | parts by mass |
| Cyclohexanone | 50 | parts by mass |

### Table 8. Amount of Chiral Agent in Coating Liquid Containing Disk-Like Liquid Crystal Compound

TABLE 8

| Name of coating liquid | Type of chiral agent | Amount of chiral agent (part by mass) |
|---|---|---|
| Liquid D-1 | Chiral agent A | 3.49 |
| Liquid D-2 | Chiral agent A | 3.83 |
| Liquid D-3 | Chiral agent A | 4.20 |
| Liquid D-4 | Chiral agent A | 5.06 |

disk-like liquid crystal compound (A) 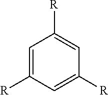 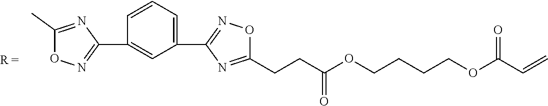 [SMILES: C=CC(=O)OCCCCOC(=O)CCc1nc(-c2cccc(-c3noc(C)n3)c2)no1]
disk-like liquid crystal compound (B) 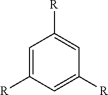 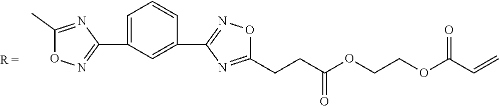 [SMILES: C=CC(=O)OCCOC(=O)CCc1nc(-c2cccc(-c3noc(C)n3)c2)no1]
Polymerizable monomer E1 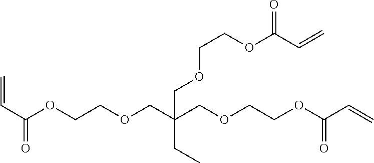 [SMILES: C=CC(=O)OCCOCC(CC)(COCCOC(=O)C=C)COCCOC(=O)C=C]
Surfactant F4 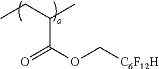 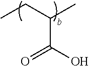
a/b = 98/2

### [Production of Laminate 1]

A polyethylene terephthalate (PET) film (A4100 manufactured by Toyobo Co., Ltd.) having a thickness of 50 m was prepared as a temporary support. The PET film had an easy adhesion layer on one surface.

The surface of the PET film shown above, which did not have the easy adhesion layer, was subjected to a rubbing treatment, and the coating liquid R-1 for a cholesteric liquid crystal layer prepared above was then applied thereto using a wire bar coater, dried at 110° C. for 1 minute to vaporize the solvent, and heat-aged at 100° C. for 1 minute, thereby obtaining a cholesteric liquid crystal film in which a cholesteric liquid crystalline phase in a uniform alignment state was applied onto the support. The cholesteric liquid crystal film was placed on a stage having a rotation mechanism. Thereafter, using, as an ultraviolet (UV) light source, a microwave-powered ultraviolet irradiation device (Light Hammer 10, 240 W/cm, Fusion UV systems GmbH) on which D-bulb having a strong emission spectrum in 350 to 400 nm was mounted, a wire grid polarization filter (ProFlux PPL 02 (high transmittance type), manufactured by Moxtek, Inc) was provided at a position 10 cm distant from the irradiation surface, and a polarized UV light was emitted through an exposure mask in a nitrogen atmosphere while rotating the cholesteric liquid crystal film heated to 80° C. A conceptual diagram of the exposure mask used in this case is shown in FIG. 11.

The exposure mask shown in FIG. 11 and the exposure method using the exposure mask will be described below. The exposure mask was designed such that the polarized UV light was transmitted in a triangular region A symmetrical with respect to the y-axis from the center of the mask, and the transmittance continuously changed from 0% to 100% from the center to the end part along the y-axis. In addition, a length from the center to the side orthogonal to the x-axis and having a triangular shape was set to 1 inch.

While rotating the cholesteric liquid crystal film, UV light with polarization parallel to the y-axis of FIG. 11 was emitted to the cholesteric liquid crystal film through the exposure mask of FIG. 11. The irradiation intensity and the irradiation amount were set such that the center part had an irradiation intensity of 0 mW/cm² and an irradiation amount of 0 mJ/cm², and the end part had an irradiation intensity of 200 mW/cm² and an irradiation amount of 300 mJ/cm². As a result, a slow axis which changes in a concentric circular shape with the rotation center as the center was formed. A conceptual diagram of the formed slow axis is shown in FIG. 12. Thereafter, the cholesteric liquid crystal was further cured under a nitrogen atmosphere (100 ppm or less) at 100° C. by irradiating the cholesteric liquid crystal layer with light from a metal halide lamp such that the illuminance was 80 mW/cm² and the irradiation amount was 500 mJ/cm², thereby forming a red light reflecting layer consisting of a cholesteric liquid crystal layer. The irradiation with light was performed from the side of the cholesteric liquid crystal layer in all cases. In this case, the film thickness of the cured red light reflecting layer was 4.5 km.

Next, the surface of the red light reflecting layer was subjected to a corona treatment at a discharge amount of 150 W·min/m², and the surface subjected to the corona treatment was coated with the coating liquid D-2 for a cholesteric liquid crystal layer using a wire bar coater. Subsequently, the coating film was dried at 100° C. for 2 minutes to vaporize the solvent, and heat-aged at 115° C. for 5 minutes, thereby obtaining a cholesteric liquid crystal film in which a cholesteric liquid crystalline phase in a uniform alignment state was applied onto the support. Thereafter, using the same method as for the red light reflecting layer, polarization UV irradiation through a mask and metal halide lamp UV irradiation were performed, thereby forming a yellow light reflecting layer on the red light reflecting layer. Here, the coating thickness was adjusted so that the film thickness of the cured yellow light reflecting layer was 3.3 μm.

Next, the coating liquid R-3 for a cholesteric liquid crystal layer was applied onto the yellow light reflecting layer using a wire bar coater, dried at 110° C. for 1 minute to vaporize the solvent, and heat-aged at 100° C. for 1 minute, thereby obtaining a cholesteric liquid crystal film in which a cholesteric liquid crystalline phase in a uniform alignment state was applied onto the support. Thereafter, using the same method as for the red light reflecting layer, polarization UV irradiation through a mask and metal halide lamp UV irradiation were performed, thereby forming a green light reflecting layer on the yellow light reflecting layer. Here, the coating thickness was adjusted so that the film thickness of the cured green light reflecting layer was 2.7 μm.

Next, the surface of the green light reflecting layer was subjected to a corona treatment at a discharge amount of 150 W·min/m², and the surface subjected to the corona treatment was coated with the coating liquid D-4 for a cholesteric liquid crystal layer using a wire bar coater. Subsequently, the coating film was dried at 100° C. for 2 minutes to vaporize the solvent, and heat-aged at 115° C. for 5 minutes, thereby obtaining a cholesteric liquid crystal film in which a cholesteric liquid crystalline phase in a uniform alignment state was applied onto the support. Thereafter, using the same method as for the red light reflecting layer, polarization UV irradiation through a mask and metal halide lamp UV irradiation were performed, thereby forming a blue light reflecting layer on the green light reflecting layer. Here, the coating thickness was adjusted so that the film thickness of the cured blue light reflecting layer was 2.5 μm. In this manner, a laminate 1 having a plurality of cholesteric liquid crystal layers was produced. The coating liquid for a cholesteric liquid crystal layer and the film thickness used are shown in Table 9-1.

TABLE 9-1

| | | | Reflection | |
|---|---|---|---|---|
| | Type of | Amount of | center | Film |
| | coating | chiral agent | wavelength | thickness |
| | liquid | (part by mass) | (nm) | (μm) |
| Fourth layer | Liquid D-4 | 4.20 | 480 | 2.5 |
| Third layer | Liquid R-3 | 3.46 | 573 | 2.7 |
| Second layer | Liquid D-2 | 3.15 | 625 | 3.3 |
| First layer | Liquid R-1 | 2.87 | 683 | 4.5 |

### [Production of Laminate 2]

A laminate 2 was produced by the same production method as the laminate 1, except that the number of layers was increased to 8 layers, and the coating liquid for a cholesteric liquid crystal layer and the film thickness were changed as shown in Table 9-2.

TABLE 9-2

| | | | Reflection | |
|---|---|---|---|---|
| | Type of | Amount of | center | Film |
| | coating | chiral agent | wavelength | thickness |
| | liquid | (part by mass) | (nm) | (μm) |
| Eighth layer | Liquid D-4 | 5.06 | 480 | 1.3 |
| Seventh layer | Liquid R-4 | 4.20 | 480 | 1.6 |
| Sixth layer | Liquid D-3 | 4.20 | 573 | 1.5 |
| Fifth layer | Liquid R-3 | 3.46 | 573 | 0.9 |
| Fourth layer | Liquid D-2 | 3.83 | 625 | 1.9 |
| Third layer | Liquid R-2 | 3.15 | 625 | 1.0 |
| Second layer | Liquid D-1 | 3.49 | 683 | 2.3 |
| First layer | Liquid R-1 | 2.87 | 683 | 1.5 |

### [Production of Laminate 3]

A laminate 3 was produced without performing the polarized UV irradiation using the exposure mask, in the process of producing the laminate 1.

### [Production of Laminate 4]

A laminate 4 was produced without performing the polarized UV irradiation using the exposure mask, in the process of producing the laminate 2.

### [Production of Optical Laminate]

The laminate 1 was bonded to a PMMA film through a pressure-sensitive adhesive sheet “NCF-D692(5)” manufactured by LINTEC Corporation, and a PET support was peeled off to obtain an optical laminate 1. Optical laminates 2 to 4 were obtained by the same method as the optical laminate 1, except that the laminates 2 to 4 were used instead of the laminate 1.

### [Evaluation of Phase Difference and Slow Axis]

Using M-2000 UI manufactured by J. A. Woollam Co., Ltd., the slow axis and the phase difference of the optical laminate 1 were measured. The optical laminate 1 had a slow axis which was substantially concentric with the rotation center during the mask exposure. In addition, in a case where the phase difference of the optical laminate 1 at the rotation center during the mask exposure was measured, it was 0 nm. The phase difference of the optical laminate 1 at a position separated by 0.2 inches in the radial direction of the concentric circle from the rotation center during the mask exposure was 2 nm. The phase difference of the optical laminate 1 at a position separated by 0.6 inches in the radial direction of the concentric circle from the rotation center during the mask exposure was 12 nm. The phase difference of the optical laminate 1 at a position separated by 0.8 inches in the radial direction of the concentric circle from the rotation center during the mask exposure was 23 nm.

The results of the evaluation of the optical laminates 2 to 4 in the same manner are shown in Table 10. The optical laminate 1 and the optical laminate 2, which included the cholesteric liquid crystal layer irradiated with polarized UV light through the mask by the above-described method, had different in-plane retardations and substantially concentric slow axes. On the other hand, the optical laminate 3 and the optical laminate 4, which included the cholesteric liquid crystal layer that was not irradiated with polarized UV light, did not have a phase difference.

TABLE 10

| | Distance from rotation center in case | | | | |
|---|---|---|---|---|---|
| | of mask exposure [inch] | | | | |
| | 0 | 0.2 | 0.4 | 0.6 | 0.8 |
| Phase difference of optical | 0 | 2 | 6 | 13 | 25 |
| laminate 1 [nm] | | | | | |
| Phase difference of optical | 0 | 2 | 5 | 11 | 22 |
| laminate 2 [nm] | | | | | |
| Phase difference of optical | 0 | 0 | 0 | 0 | 0 |
| laminate 3 [nm] | | | | | |
| Phase difference of optical | 0 | 0 | 0 | 0 | 0 |
| laminate 4 [nm] | | | | | |

### [Forming Method]

The optical laminate 1 was formed by a vacuum molding method on a concave surface of a convex meniscus lens LE1076-A (diameter: 2 inches, focal length: 100 mm, curvature radius on the concave side: 65 mm) manufactured by Thorlabs, Inc. through a pressure-sensitive adhesive sheet. Finally, the optical laminate 1 was cut by trimming a portion protruding from the lens, thereby obtaining an optical component 1 including a cholesteric liquid crystal layer formed on a curved surface.

An optical component 2 was obtained by the same production method of the optical component 1, except that the optical laminate 2 was used instead of the optical laminate 1.

An optical component 3 was obtained by the same production method of the optical component 1, except that the optical laminate 3 was used instead of the optical laminate 1.

An optical component 4 was obtained by the same production method of the optical component 1, except that the optical laminate 4 was used instead of the optical laminate 1.

### [Production of Polarizing Plate Laminate]

### [Production of Positive C-Plate 1]

A positive C-plate 1 was produced by adjusting the film thickness with reference to the method described in paragraphs 0132 to 0134 of JP2016-053709A. Re of the positive C-plate 1 was 0.2 nm and Rth thereof was −310 nm.

### [Production of Retardation Layer 1]

A retardation layer 1 having reverse dispersibility was produced with reference to the method described in paragraphs 0151 to 0163 of JP2020-084070A. Re of the retardation layer 1 was 146 nm and Rth thereof was 73 nm.

### [Production of Linear Polarizer]

### [Production of Cellulose Acylate Film 1]

### (Production of Core Layer Cellulose Acylate Dope)

The following composition was put into a mixing tank and stirred to dissolve each component, thereby preparing a cellulose acetate solution used as a core layer cellulose acylate dope.

Core layer cellulose acylate dope

| | |
|---|---|
| Cellulose acetate having acetyl substitution | 100 parts by mass |
| degree of 2.88 | |
| Polyester compound B described in Examples of | 12 parts by mass |
| JP2015-227955A | |
| Compound F shown below | 2 parts by mass |
| Methylene chloride (first solvent) | 430 parts by mass |
| Methanol (second solvent) | 64 parts by mass |

Compound F

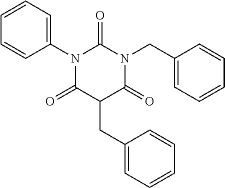 [SMILES: O=C1C(Cc2ccccc2)C(=O)N(c2ccccc2)C(=O)N1Cc1ccccc1]

### (Production of Outer Layer Cellulose Acylate Dope)

10 parts by mass of the following matte agent solution was added to 90 parts by mass of the core layer cellulose acylate dope to prepare a cellulose acetate solution to be used as an outer layer cellulose acylate dope.

Matting agent solution

| | | |
|---|---|---|
| Silica particles with average particle size of 20 nm | 2 | parts by mass |
| (AEROSIL R972, manufactured by Nippon Aerosil | | |
| Co., Ltd.) | | |
| Methylene chloride (first solvent) | 76 | parts by mass |
| Methanol (second solvent) | 11 | parts by mass |
| Core layer cellulose acylate dope described above | 1 | part by mass |

### (Production of Cellulose Acylate Film 1)

The core layer cellulose acylate dope and the outer layer cellulose acylate dope were filtered through filter paper having an average hole diameter of 34 m and a sintered metal filter having an average pore size of 10 m, and three layers which were the core layer cellulose acylate dope and the outer layer cellulose acylate dopes provided on both sides of the core layer cellulose acylate dope were simultaneously cast from a casting port onto a drum at 20° C. (band casting machine).

Next, the film was peeled off in a state where the solvent content was approximately 20% by mass, both ends of the film in the width direction were fixed by tenter clips, and the film was dried while being stretched at a stretching ratio of 1.1 times in the lateral direction.

Thereafter, the film was further dried by being transported between the rolls of the heat treatment device to prepare an optical film having a thickness of 40 m, and the optical film was used as a cellulose acylate film 1. An in-plane retardation of the obtained cellulose acylate film 1 was 0 nm.

### <Formation of Photoalignment Layer PA1>

The cellulose acylate film 1 was continuously coated with a coating liquid S-PA-1 for forming an alignment layer described below with a wire bar. The support on which the coating film was formed was dried with hot air at 140° C. for 120 seconds, and the coating film was irradiated with polarized ultraviolet rays (10 mJ/cm², using an ultra-high pressure mercury lamp) to form a photoalignment layer PA1. A film thickness thereof was 0.3 m.

(Coating liquid S-PA-1 for forming alignment layer)

| | |
|---|---|
| Polymer M-PA-1 shown below | 100.00 parts by mass |
| Acid generator PAG-1 shown below | 5.00 parts by mass |
| Acid generator CPI-110TF shown below | 0.005 parts by mass |
| Xylene | 1220.00 parts by mass |
| Methyl isobutyl ketone | 122.00 parts by mass |

Polymer M-PA-1 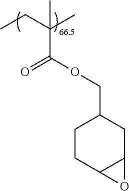 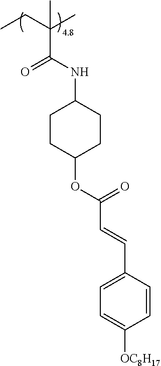 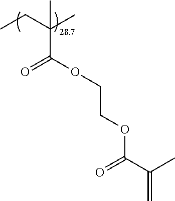
Acid generator PAG-1 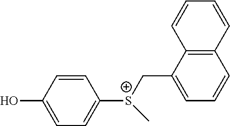 [SMILES: C[S+](Cc1cccc2ccccc12)c1ccc(O)cc1] 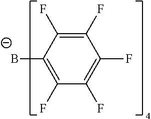
Acid generator CPI-110F

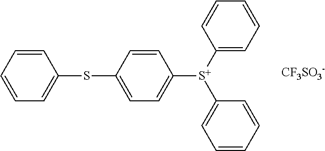

### <Formation of Light Absorption Anisotropic Layer P1>

The obtained photoalignment layer PA1 was continuously coated with the following coating liquid S-P-1 for forming a light absorption anisotropic layer with a wire bar. Next, the coating layer P1 was heated at 140° C. for 30 seconds and cooled to room temperature (23° C.). Next, the coating layer P1 was heated at 90° C. for 60 seconds and cooled to room temperature again. Thereafter, the coating layer P1 was irradiated with an LED lamp (central wavelength of 365 nm) for 2 seconds under an irradiation condition of an illuminance of 200 mW/cm², thereby forming a light absorption anisotropic layer P1 on the photoalignment layer PA1. A film thickness thereof was 1.6 km.

Composition of coating liquid S-P-1 for forming light absorption anisotropic layer

| | |
|---|---|
| Dichroic substance D-1 shown below | 0.25 parts by mass |
| Dichroic substance D-2 shown below | 0.36 parts by mass |
| Dichroic substance D-3 shown below | 0.59 parts by mass |
| Polymer liquid crystal compound M-P-1 shown below | 2.21 parts by mass |
| Low-molecular-weight liquid crystal compound M-1 | 1.36 parts by mass |
| Polymerization initiator | |
| IRGACURE OXE-02 (manufactured by BASF SE) | 0.200 parts by mass |
| Surfactant F-1 shown below | 0.026 parts by mass |
| Cyclopentanone | 46.00 parts by mass |
| Tetrahydrofuran | 46.00 parts by mass |
| Benzyl alcohol | 3.00 parts by mass |

Dichroic substance D-1 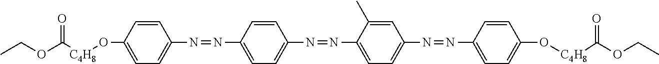
Dichroic substance D-2 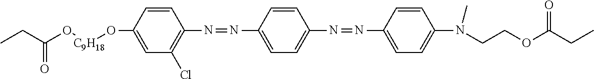
Dichroic substance D-3 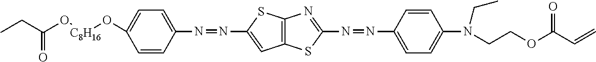
Polymer liquid crystal compound M-P-1 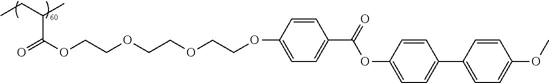 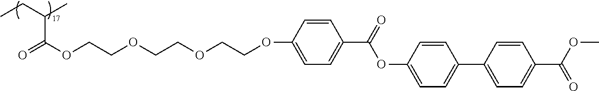 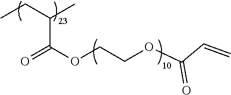
Low-molecular-weight liquid crystal compound M-1 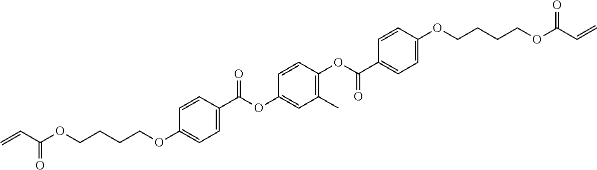 [SMILES: C=CC(=O)OCCCCOc1ccc(C(=O)Oc2ccc(OC(=O)c3ccc(OCCCCOC(=O)C=C)cc3)c(C)c2)cc1]
Surfactant F-1

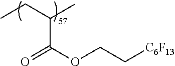

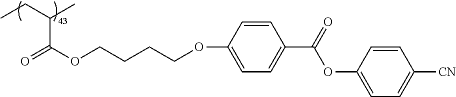

The obtained retardation layer 1 was bonded to the obtained positive C-plate 1 on a side opposite to the support. Next, the light absorption anisotropic layer P1 was transferred. In this case, the light absorption anisotropic layer P1 was transferred such that a layer on a side opposite to the temporary support was on the positive C-plate 1 side. The temporary support of the light absorption anisotropic layer P1 was peeled off and removed after the transfer. The transfer of the light absorption anisotropic layer P1 was performed by the following procedure.

(1) A UV adhesive Chemi-seal U2084B (manufactured by ChemiTech Inc., refractive index n after curing: 1.60) was applied onto the positive C-plate on the support side using a wire bar coater such that the thickness was set to 2 km; the light absorption anisotropic layer P1 was laminated thereon with a laminator such that the side opposite to the temporary support was in contact with the UV adhesive.

(2) After nitrogen purging until the oxygen concentration reached 100 ppm or less in a purge box, the light absorption anisotropic layer P1 was cured by being irradiated with ultraviolet rays using a high-pressure mercury lamp from the temporary support side; the illuminance was 25 mW/cm² and the irradiation amount was 1,000 mJ/cm².

(3) Finally, the temporary support of the light absorption anisotropic layer P1 was peeled off.

Here, the retardation layer 1 and the light absorption anisotropic layer P1 were laminated such that the slow axis of the retardation layer 1 and the absorption axis of the light absorption anisotropic layer P1 formed an angle of 45°. Finally, the support of the positive C-plate 1 was peeled off. In this manner, a polarizing plate laminate was obtained. In a case where the polarizing plate laminate was irradiated with dextrorotatory circularly polarized light from the positive C-plate side, it was found that substantially all of visible light was absorbed; and in a case where the polarizing plate laminate was irradiated with levorotatory circularly polarized light, it was found that substantially all of visible light was transmitted.

### [Formation of Half Mirror on Optical Component]

The convex surface side of the optical component 1 was subjected to aluminum vapor deposition to be a reflectivity of 40%, thereby forming a half mirror. Similarly, aluminum deposition was performed on the optical components 2 to 4.

### Example 2-1

A virtual reality display apparatus “Huawei VR Glass” (manufactured by Huawei Technologies Co., Ltd.), which was a virtual reality display apparatus for which a reciprocating optical system was employed, was disassembled, and all composite lenses were taken out. A virtual reality display apparatus of Example 2-1 was produced by incorporating the optical component 1 instead of the taken-out composite lens, in which the optical absorption anisotropic layer P1 side of the polarizing plate laminate was installed between the optical component 1 and the eye such that the light absorption anisotropic layer P1 side of the polarizing plate laminate was on the eye side.

Furthermore, virtual reality display apparatuses of Example 2-2 and Comparative Examples 2-1 and 2-2 were produced by the same procedure, except that the optical component 1 was replaced with the optical components 2 to 4, respectively.

### <Evaluation of Light Leakage>

In the virtual reality display apparatuses produced in Examples 2-1 and 2-2 and Comparative Examples 2-1 and 2-2, a black-and-white checker pattern was displayed on the image display device, and a degree of light leakage was evaluated by visual observation in the following three stages. In a case where there was the light leakage, double images were visually recognized, and a contrast of the corresponding portion was lowered.
A: double images were hardly visible.
B: double images were slightly visible but not noticeable.
C: clear double images were observed.

The results are shown in Table 11.

### <Evaluation of Display Uniformity>

In the virtual reality display apparatuses produced in Examples 2-1 and 2-2 and Comparative Examples 2-1 and 2-2, a black-and-white checker pattern was displayed on the image display device, and display uniformity was evaluated by visual observation in the following three stages.
A: image was uniformly displayed over the entire surface.
B: part of the image was non-uniformly distorted.
C: large part of the image was distorted.

The results are shown in Table 11.

Table 11. Evaluation result of virtual reality display apparatus of Examples

TABLE 11

| | | Light | Display |
|---|---|---|---|
| | Optical component | leakage | uniformity |
| Example 2-1 | Optical component 1 | A | A |
| Example 2-2 | Optical component 2 | A | A |
| Comparative | Optical component 3 | B | B |
| Example 2-1 | | | |
| Comparative | Optical component 4 | B | B |
| Example 2-2 | | | |

From the above results, it is indicated that the cholesteric liquid crystal layer after the concave surface formation had the slow axis arranged in a concentric circular shape before the concave surface formation eliminated by the concave surface formation, and as a result, the retardation was 10 nm or less, leading to good evaluations of light leakage and display uniformity.

From the above results, the effect of the present invention is clear.

### Explanation of References

31: first light reflecting layer
32: second light reflecting layer
33: third light reflecting layer
34: fourth light reflecting layer
100: optical laminate
101: antireflection layer
102: positive C-plate
103: optical film
104: positive C-plate
105: retardation layer
106: linear polarizer
120: support
124: alignment film
126: cholesteric liquid crystal layer
132: liquid crystal compound
200: lens
300: half mirror
400: circularly polarizing plate (reflective type circular polarizer)
500: image display panel
1000: ray
2000: ray forming ghost

What is claimed is:

1. A forming method of an optical film, comprising:
a heating step of heating an optical film;
a forming step of pressing the optical film against a mold to deform the optical film along a shape of the mold; and
a cutting step of cutting the optical film,
wherein the heating step is a step of heating the optical film by irradiating the optical film with infrared rays, and
an irradiation amount of the infrared rays has a distribution in a plane of the optical film.

2. The forming method according to claim 1,
wherein the mold is a concave surface of a non-developable surface in which a Gaussian curvature is positive, and
in a case where an in-plane position of the optical film is projected onto the mold from a normal direction of a main surface of the optical film, an amount of infrared irradiation to the optical film at a vertex of the concave surface is larger than an amount of infrared irradiation to the optical film at an end part of the concave surface.

3. A forming method of an optical film, comprising:
a heating step of heating an optical film;
a forming step of pressing the optical film against a mold to deform the optical film along a shape of the mold; and
a cutting step of cutting the optical film,
wherein a surface of the mold, which comes into contact with the optical film, is a concave surface of a non-developable surface in which a Gaussian curvature is positive and an outer peripheral shape is an ellipse,
a cutting shape in the cutting step is an ellipse, and
a major axis of an elliptical outer peripheral shape of the optical film before the cutting is larger than 50% and smaller than 95% with respect to a major axis of the elliptical outer peripheral shape of the mold.

4. A forming method of an optical film, comprising:
a heating step of heating an optical film;
a forming step of pressing the optical film against a mold to deform the optical film along a shape of the mold; and
a cutting step of cutting the optical film,
wherein, in the heating step, a region of the optical film, which comes into contact with the mold, is heated at a temperature higher than a glass transition temperature Tg of the optical film, and
in the forming step, immediately after the optical film comes into contact with the mold, the pressing of the optical film against the mold is controlled such that the region of the optical film, which comes into contact with the mold, has a temperature lower than the glass transition temperature Tg.

5. A forming method of an optical film, comprising:
a heating step of heating a mold;
a forming step of pressing the heated mold against an optical film to deform the optical film along a shape of the mold; and
a cutting step of cutting the optical film,
wherein the mold is a convex surface of a non-developable surface in which a Gaussian curvature is positive, and
in the forming step, a vertex of the convex surface of the mold is pressed against a center of the optical film.

6. The forming method according to claim 5,
wherein a cutting shape of the optical film in the cutting step is an ellipse, and
in the forming step, the optical film is pressed against the mold while constraining a position on an elliptical line which is to be the cutting shape.

7. A cholesteric liquid crystal layer,
wherein the cholesteric liquid crystal layer has a phase difference region in which a phase difference increases from a center toward outside, and
in the phase difference region, a direction of a slow axis at one point in the phase difference region and a direction from the center to the one point are orthogonal to each other.

8. An optical laminate comprising:
a plurality of the cholesteric liquid crystal layers according to claim 7.

9. The optical laminate according to claim 8,
wherein the cholesteric liquid crystal layer formed of a rod-like liquid crystal compound and the cholesteric liquid crystal layer formed of a disk-like liquid crystal compound are alternately laminated.

10. A production method of a curved-shaped optically functional layer, comprising:
a cholesteric liquid crystal layer-producing step of producing the cholesteric liquid crystal layer according to claim 7; and
a forming step of forming the cholesteric liquid crystal layer into a curved shape to cancel out a phase difference of the cholesteric liquid crystal layer.

11. The production method of a curved-shaped optically functional layer according to claim 10,
wherein, in the forming step, the cholesteric liquid crystal layer is installed on a forming die having a concave surface-forming surface such that a bottom portion of the concave surface-forming surface and a center of the cholesteric liquid crystal layer coincide with each other, and the cholesteric liquid crystal layer is deformed along the concave surface-forming surface.

12. An optical film having a non-developable surface in which a Gaussian curvature is positive,
wherein the optical film is a cholesteric liquid crystal layer, and
in a case where a wavelength obtained by subtracting 20 nm from a half-value wavelength on a side shorter than a selective reflection center wavelength in the cholesteric liquid crystal layer is defined as an evaluation wavelength of an in-plane retardation, an in-plane retardation A at the evaluation wavelength in a center of the cholesteric liquid crystal layer is less than 2% of the evaluation wavelength, and an in-plane retardation B at the evaluation wavelength in an outer edge portion of the cholesteric liquid crystal layer is less than 2% of the evaluation wavelength.

13. An optical film having a non-developable surface in which a Gaussian curvature is positive,
wherein the optical film has no selective reflection characteristic,
an in-plane retardation A in a center of the optical film at a wavelength of 550 nm is less than 11 nm, and
an in-plane retardation B in an outer edge portion of the optical film at a wavelength of 550 nm is less than 11 nm.

14. The optical film according to claim 12,
wherein an outer peripheral shape is an ellipse.

15. The optical film according to claim 13,
wherein an outer peripheral shape is an ellipse.

16. The optical film according to claim 12,
wherein the cholesteric liquid crystal layer have in-plane different helical pitches.
